(19) United States
(12) Patent Application Publication
(10) Pub. No.: US 2026/0175798 A1
(43) Pub. Date: Jun. 25, 2026

(54) SELF-CANCELLING WIRING HARNESS

(71) Applicant: SAFEFIELDS TECHNOLOGIES LTD, Herzliya (IL)

(72) Inventors: Shaul SHULMAN, Ramat Gan (IL); Vitaly ZLOTNIK, Herzliya (IL); Oded EINAT, Herzliya (IL)

(73) Assignee: SAFEFIELDS TECHNOLOGIES LTD, Herzliya (IL)

(21) Appl. No.: 19/340,653

(22) Filed: Sep. 25, 2025

Related U.S. Application Data
(63) Continuation of application No. PCT/IB2025/055713, filed on Jun. 3, 2025.
(60) Provisional application No. 63/656,218, filed on Jun. 5, 2024.

(51) Int. Cl. B60R 16/02; B60R 16/023; H05K 9/00

(52) U.S. Cl. CPC B60R 16/0215; B60R 16/023; H05K 9/0071; H05K 9/0081; H05K 9/0098

(57) ABSTRACT

A wiring assembly integrated with magnetic field cancellation components is disclosed. The assembly includes a wiring harness comprising a bundle of wires, some of which carry sufficient aggregate current to generate an above-threshold magnetic field within a vehicle cabin. Connectors at wire ends interface with vehicle electrical components. A probe embedded in the harness senses a portion of the aggregate current and transmits a signal to a control unit. The control unit calculates a cancellation current, which is delivered via a dedicated wire integrated into the harness. This cancellation current mitigates at least part of the magnetic field within the cabin, enhancing electromagnetic compatibility and passenger comfort.

### TECHNICAL FIELD

The present disclosure generally relates to the field of magnetic field radiation in passenger vehicles. More specifically, the present disclosure relates to systems, methods, and devices for protecting passengers from magnetic field radiation.

### BACKGROUND

Magnetic field radiation inside electric vehicles (EVs) and hybrid electric vehicles (HEVs) may originate from high and/or low voltage power electronics, electric motors, and/or battery systems. Prolonged exposure to strong electromagnetic fields (EMFs) may raise health concerns, including potential biological effects on passengers. Additionally, higher levels of magnetic radiation may interfere with onboard electronic systems, which may affect vehicle performance and safety. Some regulatory guidelines recommend limiting EMF exposure to ensure passenger well-being and compliance with safety standards. Reducing magnetic field radiation may thus enhance passenger comfort, safeguard health, and maintain the reliability of vehicle electronics.

For example, regulations governing magnetic field exposure in electric vehicles are established to ensure the safety of individuals by limiting their exposure to electromagnetic fields. For instance, the International Commission on Non-Ionizing Radiation Protection (ICNIRP) provides widely referenced guidelines on acceptable exposure levels for low-frequency magnetic fields. Moreover, the precautionary principle recommended by the World Health Organization (WHO) holds that when there is a threat of harm to human health and/or the environment, precautionary measures should be taken, even when scientific evidence remains inconclusive. Since, the International Agency for Research on Cancer (IARC) classifies substances as “possibly carcinogenic to humans” (Group 2B) when there is limited evidence of carcinogenicity in humans but sufficient evidence in animal studies, the precautionary principle advises that scientific uncertainty should not be used as a reason to delay or avoid taking preventative measures, particularly when the potential harm is significant. The IEEE C95.1 standard outlines safety levels for human exposure to electromagnetic fields, considering potential risks associated with EV components. In the European Union, directives addressing electromagnetic compatibility and exposure limits for workers and the general public may also apply to EVs. Similarly, in the United States, the Federal Communications Commission (FCC) regulates electromagnetic emissions to ensure compliance with safety standards. These regulations collectively aim to protect passengers and the public from any adverse effects of electromagnetic fields associated with electric vehicles. The disclosed embodiments may ensure that magnetic field radiation generated during vehicle operation remains within a threshold level defined by one or more of these regulations.

### SUMMARY

Embodiments consistent with the present disclosure provide systems and methods generally relating to protecting vehicle passengers from magnetic field radiation generated by vehicles. The disclosed systems and methods may be implemented using conventional and/or specialized hardware. Some embodiments may involve a combination of conventional and/or specialized hardware and/or software, such as a machine constructed and/or programmed specifically for performing functions associated with the disclosed method steps.

Consistent with disclosed embodiments, systems and methods are provided for protecting vehicle passengers from magnetic field radiation. The embodiments may include a passenger cabin; a wire cable configured to carry electricity during vehicle operation thereby generating a primary magnetic field that, in an absence of cancellation, would radiate into the passenger cabin; a current sensor associated with the wire cable, for sensing current passing through the wire cable; a cancellation wire, running along at least a portion of the wire cable; and an amplifier configured to receive a signal indicative of current running through the wire cable and for generating, within 1500 microseconds of the signal, a cancellation current for application to the cancellation wire, the cancellation current is within 30% of the current passing through the wire cable in order to cause a cancelling magnetic field thereby at least partially eliminating magnetic radiation from the wire cable to the passenger cabin.

Consistent with disclosed embodiments, systems and method are provided for a vehicle wiring assembly having integrated magnetic field cancellation components associated therewith, the vehicle wiring assembly comprising: a vehicle wiring harness including a bundle of wires, at least some of the bundle of wires being aggressor wires configured such that when in use, the aggressor wires carry sufficient aggregate current to cause, in an absence of mitigation, a wiring harness-induced aggressor magnetic field of greater than a threshold level in a region of a passenger cabin of an associated vehicle; a plurality of connectors on ends of the wires in the bundle, the plurality of connectors being configured for connecting at least some of the wires in the bundle to electrical components of the vehicle; a current sensing probe integrated with the vehicle wiring harness, the current sensing probe being associated with the bundle of wires in a manner enabling the current sensing probe, when in use, to sense at least a portion of the aggregate current, the current sensing probe having an output wire configured for electrical connection to an electronic control unit for determining a cancellation current sufficient to mitigate causation of at least a portion of the wiring harness-induced aggressor magnetic field in the region of the passenger cabin of the vehicle; and at least one dedicated wire integrated with and running along the vehicle wiring harness, the at least one dedicated wire being configured for electrical connection to the electronic control unit via at least one of the plurality of connectors, to receive the determined cancellation current, and to thereby mitigate causation of at least the portion of the wiring harness-induced aggressor magnetic field in the region of the passenger cabin of the vehicle.

Consistent with disclosed embodiments, systems and methods are provided for powering a cancelling field in a passenger cabin of a vehicle, the system comprising: an AC aggressor loop configured to generate an aggressor magnetic field in the passenger cabin of the vehicle; an AC cancellation loop configured to generate a cancellation magnetic field at least partially cancelling the aggressor magnetic field; and an amplifier for supplying alternating current to power the AC cancellation loop, wherein the amplifier is electrically isolated from an electrical ground associated with the vehicle, to thereby reduce generation of non-cancelling magnetic field radiation.

Consistent with disclosed embodiments, systems and methods are provided for a juvenile car seat, comprising: a main body; a first side wing extending from a right side of the main body; a second side wing extending from a left side of the main body; a headrest area extending from a top portion of the main body between upper portions of the first side wing and the second side wing, wherein the main body, the first side wing, the second side wing, and the headrest area form a child-holding concavity; and magnetic field shielding material associated with the child-holding concavity in a manner for rerouting magnetic field radiation away from the child-holding concavity.

### BRIEF DESCRIPTION OF THE DRAWINGS

FIG. 1 Illustrates an exemplary schematic diagram of a computing device, consistent with some disclosed embodiments.

FIG. 2A illustrates an exemplary schematic a top-view diagram of an electrified passenger vehicle, consistent with some disclosed embodiments.

FIG. 2B illustrates the exemplary schematic side-view diagram of the electrified passenger vehicle of FIG. 2A, consistent with some disclosed embodiments.

FIG. 3 illustrates an exemplary schematic top-view diagram of a hybrid passenger vehicle, consistent with some disclosed embodiments.

FIG. 4 illustrates an exemplary system for protecting vehicle passengers from magnetic field radiation, consistent with some disclosed embodiments.

FIG. 5 illustrates different current sensors, consistent with some disclosed embodiments.

FIG. 6 illustrates another exemplary system for protecting vehicle passengers from magnetic field radiation, consistent with some disclosed embodiments.

FIG. 7 illustrates an exemplary vehicle wiring assembly having integrated magnetic field cancellation components associated therewith, consistent with some disclosed embodiments.

FIG. 8 illustrates another exemplary vehicle wiring assembly having integrated magnetic field cancellation components associated therewith, consistent with some disclosed embodiments.

FIG. 9 illustrates a wiring harness fastened to a body of the vehicle of FIG. 2, consistent with some disclosed embodiments.

FIG. 10 illustrates a three-phase electrical wiring, consistent with some disclosed embodiments.

FIG. 11 illustrates an exemplary system for powering a cancelling field in a passenger cabin of a vehicle, consistent with some disclosed embodiments.

FIG. 12 illustrates another exemplary system for powering a cancelling field in a passenger cabin of a vehicle, consistent with some disclosed embodiments.

FIG. 13 illustrates a further exemplary system for powering a cancelling field in a passenger cabin of a vehicle using an isolation transformer, consistent with some disclosed embodiments.

FIG. 14 illustrates an additional exemplary system for powering a cancelling field in a passenger cabin of a vehicle including a plurality of wire turns, consistent with some disclosed embodiments

FIG. 15 illustrates an exemplary cancellation system for a vehicle wiring assembly, consistent with some disclosed embodiments.

FIG. 16 illustrating an exemplary juvenile car seat, consistent with some disclosed embodiments.

FIGS. 17A-17B illustrate front and side views of another exemplary juvenile car seat, consistent with some disclosed embodiments.

FIG. 18 illustrates an exploded view of another exemplary juvenile car seat, consistent with some disclosed embodiments.

FIG. 19 illustrating another exemplary juvenile car seat, consistent with some disclosed embodiments.

FIG. 20 illustrates an exemplary detachable base for supporting a juvenile car seat, consistent with some disclose embodiments.

FIG. 21 illustrating another exemplary juvenile car seat 2200, consistent with some disclosed embodiments.

### DETAILED DESCRIPTION

Throughout, this disclosure mentions “disclosed embodiments,” which refer to examples of inventive ideas, concepts, and/or manifestations described herein. Many related and unrelated embodiments are described throughout this disclosure. The fact that some “disclosed embodiments” are described as exhibiting a feature or characteristic does not mean that other disclosed embodiments necessarily lack that feature or characteristic.

This disclosure employs open-ended permissive language, indicating for example, that some embodiments “may” employ, involve, or include specific features. The use of the term “may” and other open-ended terminology is intended to indicate that although not every embodiment may employ the specific disclosed feature, at least one embodiment employs the specific disclosed feature.

The terms, generally, substantially, or approximately as used in this disclosure should be interpreted to encompass commonly understood design, machining, and/or manufacturing tolerances. For example, equidistant may refer to the same distance within +/−1%, +/−2%, or within +/−5%. Substantially and/or approximately transverse may refer to transverse within +/−1%, +/−2%, +/−5%, +/−10%, or +/−15%.

The following detailed description refers to the accompanying drawings. Wherever possible, the same reference numbers are used in the drawings and the following description to refer to the same or similar parts. While several illustrative embodiments are described herein, modifications, adaptations and other implementations are possible. For example, substitutions, additions, or modifications may be made to the components illustrated in the drawings, and the illustrative methods described herein may be modified by substituting, reordering, removing, or adding steps to the disclosed methods. Accordingly, the following detailed description is not limited to the specific embodiments and examples, but is inclusive of general principles described herein and illustrated in the figures in addition to the general principles encompassed by the appended claims

Some embodiments involve a computing device. A computing device as used herein may include any electrical component or group of electrical components capable of processing data by performing calculations, executing instructions, or running software programs. For example, a computing device may include at least one processor. Such a computing device may include a smartphone, a tablet, a smartwatch, a personal digital assistant, a desktop computer, a laptop computer, an loT device, a dedicated terminal, a smart, and/or any other electronic device that enables computation, instruction execution, or running software programs. In some embodiments, a computing device may include at least one processor, at least one memory, a transceiver, and an input/output unit, all interconnected via one more buses. In some embodiments, a computing device may include a communications device capable of exchanging data using a wired and/or wireless communications network.

At least one processor may constitute any physical device or group of devices having electric circuitry that performs a logic operation on an input or inputs. For example, the at least one processor may include one or more integrated circuits (IC), including application-specific integrated circuit (ASIC), microchips, microcontrollers, microprocessors, all or part of a central processing unit (CPU), graphics processing unit (GPU), digital signal processor (DSP), field-programmable gate array (FPGA), server, virtual server, or other circuits suitable for executing instructions or performing logic operations. The instructions executed by at least one processor may, for example, be pre-loaded into a memory integrated with or embedded into the controller or may be stored in a separate memory. The memory may include a Random Access Memory (RAM), a Read-Only Memory (ROM), a hard disk, an optical disk, a magnetic medium, a flash memory, other permanent, fixed, or volatile memory, or any other mechanism capable of storing instructions. In some embodiments, the at least one processor may include more than one processor. Each processor may have a similar construction, or the processors may be of differing constructions that are electrically connected or disconnected from each other. For example, the processors may be separate circuits or integrated in a single circuit. When more than one processor is used, the processors may be configured to operate independently or collaboratively and may be co-located or located remotely from each other. The processors may be coupled electrically, magnetically, optically, acoustically, mechanically or by other means that permit them to interact. In some embodiments, the at least one processor may include a remote processing unit (e.g., a “cloud computing” resource) accessible via a communications network. The at least one memory may include a Random Access Memory (RAM), a Read-Only Memory (ROM), a hard disk, an optical disk, a magnetic medium, a flash memory, other permanent, fixed, or volatile memory, or any other mechanism capable of storing instructions. Such a memory may be pre-loaded with instructions for execution by at least one processor. In some embodiments, the at least one memory may include a remote storage (e.g., “cloud” storage) accessible via a communications network.

A processor may be configured to perform calculations and computations, such as arithmetic and/or logical operations to execute software instructions, control and run processes, and store, manipulate, and delete data from memory. An example of a processor may include a microprocessor manufactured by Intel™. A processor may include a single core or multiple core processors executing parallel processes simultaneously. It is appreciated that other types of processor arrangements could be implemented to provide the capabilities disclosed herein.

At least one processor may include a single processor, or multiple processors communicatively linked to each other and capable of performing computations in a cooperative manner, such as to collectively perform a single task by dividing the task into subtasks and distributing the subtasks among the multiple processors, e.g., using a load balancer. In some embodiments, at least one processor may include multiple processors communicatively linked over a communications network (e.g., a local and/or remote communications network including wired and/or wireless communications links). The multiple linked processors may be configured to collectively perform computations in a distributed manner (e.g., as known in the art of distributed computing).

A non-transitory computer-readable storage medium refers to any type of physical memory on which information or data readable by at least one processor can be stored. Examples include Random Access Memory (RAM), Read-Only Memory (ROM), volatile memory, nonvolatile memory, hard drives, CD ROMs, DVDs, flash drives, disks, any other optical data storage medium, any physical medium with patterns of holes, a PROM, an EPROM, a FLASH-EPROM or any other flash memory, NVRAM, a cache, a register, any other memory chip or cartridge, and networked versions of the same. The terms “memory” and “computer-readable storage medium” may refer to multiple structures, such as a plurality of memories or computer-readable storage mediums located locally (e.g., in physical proximity to at least one processor and connected via a local communications link) or at a remote location (e.g., accessible to at least one processor via a communications network). Additionally, one or more computer-readable storage mediums can be utilized in implementing a computer-implemented method. Accordingly, the term computer-readable storage medium should be understood to include tangible items and exclude carrier waves and transient signals.

A transmitter may include an electronic device for sending signals and/or data over distance. A transmitter may encode information to a format suitable for transmission through a medium. A transmitter may send information as electromagnetic radiation (e.g., radio and/or optical waves and/or pulses), electric signals, magnetic signals, audio signals, mechanical vibrations, ultrasound signals, and/or any other type of signal. Some examples of transmitters may include Bluetooth and/or Wi-Fi antennas, and/or optical transmitters. In some embodiments, a sensor may be configured with a transmitter to transmit signals encoding sensed data to at least one processor. In some embodiments, a computing device (e.g., a mobile communications device) may include at least one transmitter.

A display may include an output device for visually presenting information, allowing users to interact with and/or view data, applications, and/or multimedia content. For example, a display may include a monitor and/or screen that converts digital signals into images, text, and/or videos by activating one or more pixels or voxels. A display may include, for example, a light-emitting diode (LED) display, an organic light-emitting diode (OLED) display, a liquid-crystal display (LCD), a dot-matrix display, a plasma display, a screen, a touch screen, a light indicator, a light source, or any other device configured to provide visual or optical output. A display may include a two dimensional display or a three-dimensional display (e.g., associated with a wearable display).

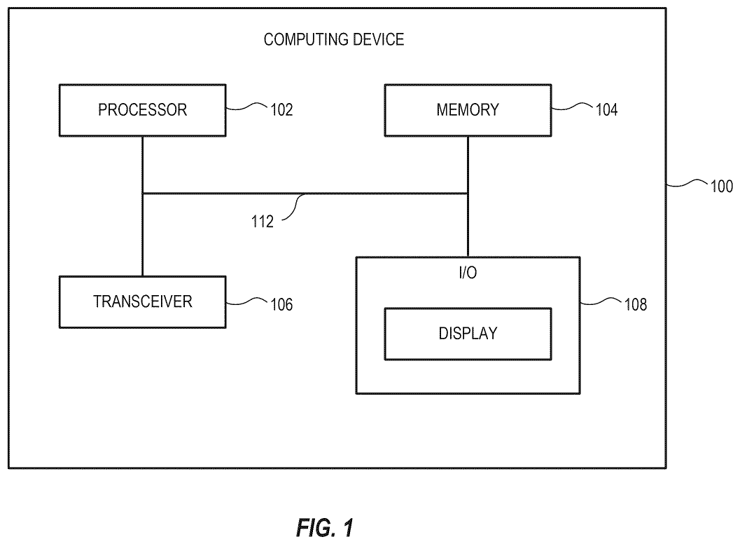

By way of a non-limiting example, reference is made to FIG. 1 illustrating an exemplary schematic diagram of a computing device 100, consistent with some disclosed embodiments. Computing device 100 may include at least one processor 102, at least one memory 104 (e.g., a non-transitory computer readable medium), a transceiver 106, and an input/output (I/O) unit 108. At least one processor 102, at least one memory 104, transceiver 106, and input/output unit 108 may be interconnected via a bus 112. In some embodiments, input/output unit 108 may include a display 110. Display 110 may include one or more touch sensitive surfaces, permitting computing device 100 to receive inputs from a user, and present outputs to a user.

A signal may refer to information encoded for transmission via a physical medium. Examples of signals may include signals in the electromagnetic radiation spectrum (e.g., AM or FM radio, Wi-Fi, Bluetooth, radar, visible light, lidar, IR, Zigbee, Z-wave, and/or GPS signals), audio and/or ultrasonic signals, electrical signals (e.g., voltage, current, or electrical charge signals), electronic signals (e.g., as digital data), tactile signals (e.g., touch), and/or any other type of information encoded for transmission between two or more entities via a physical medium.

Consistent with the present disclosure, some disclosed embodiments involve a network. A network (e.g., a communications network) may include any type of physical or wireless computer networking arrangement used to exchange data. Such a network may include one or more of a digital communications network, an analog communication network, and/or any other communications network configured to convey data. For example, a network may be the Internet, a private data network, a virtual private network using a public network, a Wi-Fi network, a LAN or WAN network, a combination of one or more of the forgoing, and/or other suitable connections that may enable information exchange among various components of the system. In some embodiments, a network may include one or more physical links used to exchange data, such as Ethernet, coaxial cables, twisted pair cables, fiber optics, or any other suitable physical medium for exchanging data. A network may also include a public switched telephone network (“PSTN”) and/or a wireless cellular network. A network may be a secured network or unsecured network. In other embodiments, one or more components of the system may communicate directly through a dedicated communication network. Direct communications may use any suitable technologies, including, for example, BLUETOOTH™, BLUETOOTH LE™ (BLE), Wi-Fi, near field communications (NFC), or other suitable communication methods that provide a medium for exchanging data and/or information between separate entities. An automotive communication network may permit transmission of data between various vehicle systems, enabling such systems to operate in a seamless manner. An automotive network may include one or more electronic control units (ECUs), for controlling specific functions (e.g., an engine, braking, and/or airbags) and one or more communication buses serving a pathways for data transmission between ECUs and additional electronic components of a vehicle. Communication protocols that may be used in an automotive communication network may include a Controller Area Network (CAN), a Local Interconnect Network (LIN), a Media-Oriented Systems Transport (MOST), an automotive Ethernet, and/or a K-line.

A mobile communications device (e.g., a mobile computing device) refers to a portable computing device capable of transmitting and receiving information to and from other devices and/or networks. Mobile communications devices may, for example, use cellular or other wireless and/or wired networks to transmit information such as voice and/or other data. For example, such transmissions may be in the form of voice calls, text messages, internet access, and application usage. Mobile communications devices come in various forms, such as smartphones, tablets, laptop computers, IoT devices, wearable electronics (such as smart watches, smart rings, fitness trackers, smart glasses, smart clothing, smart jewelry, smart headphones, wearable digital assistants), and portable wireless hotspots. Depending on configuration and intended use, they may include features such as a touchscreen interface, a built-in camera, Wi-Fi, NFC, and/or Bluetooth connectivity, and GPS navigation. In some embodiments, computing device and/or a mobile communications device may be integrated within a passenger vehicle, e.g., for providing navigation and/or control functionalities.

Broadly, a sensor is a device that detects and responds to changes or conditions in its environment. A sensor may refer to a device that outputs an electronic signal in response to detecting, sensing, or measuring a physical phenomenon. A sensor may convert a measurement of a physical phenomenon to a medium (e.g., an electronic medium) for receipt by at least one processor. A sensor may include one or more of a mechanical sensor, an optical sensor, a voltage and/or current sensor, a resistive sensor, a capacitive sensor, a motion sensor, a touch-sensitive sensor, a temperature sensor, a piezoelectric sensor, an ultrasound sensor, an audio sensor (e.g., a microphone), a Hall sensor, a thermocouple sensor, photoelectric sensor, a photoelectric encoder, a pressure sensor, and/or any other type of sensor that may be used to detect position, motion, displacement, vibrations, velocity, acceleration, and/or any other measurable property. In some embodiments, a motion sensor may include an inertial measuring unit (e.g., including one or more of a compass, accelerometer, and/or gyroscope), a positioning sensor (e.g., an indoor and/or outdoor positioning sensor), an encoder sensor, a potentiometer, a load cell, a laser displacement sensor, an inductive proximity sensor and/or any other device capable of outputting a signal indicative of physical movement.

Current (e.g., electricity) refers a flow of electrons through a conducting medium, and may be measured in Amperes (Amps, or A). Two ends of a conducting medium may be associated with a different in electric potential, and current may flow from the end associated with the higher potential to the end associated with the lower potential. According to some conventions, the direction of a current flow may be defined as a flow of negatively charged particles from a source associated with a negative charge to a destination associated with a positive charge. According to other conventions, the direction of a current flow may be defined as originating from a positively charged source and flowing to a negatively charged destination.

A current sensor refers to a device that either directly or indirectly detects and/or measures the flow of electric current through a conductor. A current sensor may detect a flow of electrons flowing through a wire cable and convert the detected flow to a quantifiable output, such as a measurement in Amps (A) and/or Volts (V). Some examples of a current sensor may include a shunt resistor and/or copper trace, a current transformer, a fluxgate sensor, a magneto-resistive (MR) (e.g., including Anisotropic Magneto-Resistance or AMR, Giant Magneto-Resistance or GMR, Tunnel Magneto-Resistance or TMR, and/or Colossal Magneto-Resistance or CMR) sensor, and/or a fiber optic current sensor. In some embodiments, a current sensor may include an analog current sensor that may output a continuous representation of a measured current and may avoid use of an analog-to-digital and/or digital-to-analog converter. Examples, of an analog current sensor may include a shunt resistor that may be positioned in series with a wire cable and may measure current as an associated voltage differential across the resistor, a Hall effect sensor that may measure a magnetic field generated by a current and output an associated voltage, and a current transformer which may measure an AC current using electromagnetic induction. In some embodiments, a current sensor may include a digital sensor that may require an analog-to-digital converter to provide a sensed signal to a processor for analysis. Thus, during vehicle operation, a current sensor may detect a level of current flowing through one or more wire cables of a vehicle. The level of current may be indicative of a magnetic field generated by the current flowing in the wire. A current sensor may measure current directly, and/or by sensing an associated voltage and/or an associated magnetic field (e.g., via induction). For example, a sensor may include a magnetic core for sensing a magnetic field generated by a current flowing through a wire. The magnetic core may include a solid core (e.g., a single piece) or a split core. A sensor having a split core may be clamped around a conducting wire to permit sensing of a magnetic field generated by a current passing through the conducting wire. The current may be determined based on the sensed magnetic field. Some example of sensors that may be used to sense an indication of current may include a Hall sensor, an inductance sensor, a field probe, a Rogowski coil, and/or a current transformer. Some examples of current sensors may include a Hall sensor, an inductance sensor, a field probe, a Rogowski coil, and/or a current transformer.

A wire (e.g., a conducting wire) refers to one or more elongated strands, filaments, or rods made of a conducting material for conveying electricity and/or signals. Such conducting materials may include copper, aluminum, gold, silver, bras, zinc, nickel, iron, and alloys and/or combinations thereof. When an electric current flows through a wire, the moving charges of the electric current may generate a magnetic field due to properties of electromagnetism. A magnetic field generated by a current-carrying wire may include magnetic field lines shaped as concentric circles around the wire. The direction of the magnetic field may be perpendicular to the wire and the current flowing therethrough (e.g., in accordance with the right-hand rule). The strength of the magnetic field may be proportional to the magnitude of the current flowing through the wire. When a wire is coiled into a solenoid, the magnetic fields of each individual loop may combine to produce a stronger, more concentrated magnetic field, than a magnetic field produced by a single wire loop similar.

A voltage is a measure of electrical potential difference between two points. It may represent the force that drives electric charge to flow. A voltage may be associated with a tension between two points to reduce and/or eliminate an electrical potential difference therebetween. For example, the tension may be reduced by a current flowing from one point associated with a higher voltage level to another point associated with a lower voltage level point.

Broadly speaking, power refers to the rate at which work is performed or energy is transferred from one form to another. Power (e.g., electric power) may refer to a rate at which electrical energy may be transferred by an electric circuit. Electric power may be measured in watts (e.g., Kilowatts, or Megawatts) and may refer to a rate of electrical energy transferred by an electric circuit. Power may be calculated from a known voltage and/or current level (e.g., watts=volts×amps). Electric power may be generated by an energy generator, such as an internal combustion engine and/or by an external energy source (e.g., connected to an electrical grid) for storing in one or more batteries. Additionally or alternatively, an electric motor of an electric and/or hybrid vehicle may operate as a generator during braking. Kinetic energy released during braking may be harnessed and converted to electric energy for storage on one or more batteries.

Power signal refers to an electrical signal that carries energy or power. These signals are typically intended to deliver energy to a load, such as powering devices, systems, or equipment. Power signals generally differ from other types of signals, like communication signals, because they are designed to transmit energy rather than just information. A power signal refers to a rate at which electrical energy is transferred. An aggregate power signal refers to a rate at which a combined level of electrical energy may be transferred, e.g., to an electric motor.

Direct current (DC) refers to the flow of electric charge in a single, consistent direction. Unlike alternating current (AC), which periodically reverses direction, DC maintains a steady and unidirectional flow. In other words, direct current (DC) (e.g., a DC power signal) refers to a one-directional flow of electric charge. DC power may be used to operate a processor or controller. An example of DC power may include power produced by an electrochemical cell (e.g., a battery) or power stored in a capacitor. DC current may be used in a vehicle for powering lights (e.g., headlights and/or interior lights), a climate control system, a sensor system, an infotainment system, a navigation system, dashboard instruments, windows, locks, accessories, at least one processor and/, and/or any other electronically driven system in a vehicle. A DC current flowing through a wire may generate a steady magnetic field having a fixed direction and magnitude. A specific magnetic field generated by a specific DC current may be cancelled by generating a cancellation DC current having a similar magnitude and opposite direction to the specific DC current. The cancellation DC current may generate a cancellation magnetic field having a similar magnitude and opposite direction to the specific magnetic field, such that introducing the cancellation magnetic field into the same region as the specific magnetic field may result in substantially reduced magnetic field radiation in the region. During braking, an electric motor may operate as a generator for converting kinetic energy into DC power for recharging a vehicle battery.

Alternating current (AC) refers to the flow of electric charge that periodically reverses direction. For example, alternating current (AC) (e.g., an AC power signal) may refer to a bi-directional flow of electrical charge exhibiting a periodic change in direction. An AC current flow may change between positive and negative due to the positive or negative flow of electrons, producing a sinusoidal AC wave form. AC current may be used for powering rotating devices, such as a vehicle motor for causing one or more wheels of a vehicle to turn. AC current may additionally be used for powering one or more fans, air conditioners, and/or any other system requiring AC power in a vehicle. An AC current flowing through a wire may generate an oscillating magnetic field that changes direction at a frequency corresponding to the frequency of the AC current such that a sinusoidal wave form of a magnetic field generated by an AC current corresponds to a sinusoidal wave form of the AC current. In some instances, an oscillating magnetic field (e.g., generated by an AC current) may induce an additional current in a conducting material exposed thereto. An oscillating magnetic field generated by an AC current may be cancelled by producing a cancellation current having a similar magnitude, and/or frequency, and phase shifted by 180 degrees, i.e., flowing in an opposite direction. The cancellation AC current may generate an oscillating cancelling magnetic field having a similar magnitude, frequency, phase, and opposite direction to the oscillating magnetic field, such that when combined in a common space with the magnetic field may cancel or at least reduce the magnetic field. An AC signal may be sinusoidal, square, triangular, and/or any other alternating waveform.

A three-phase signal may refer to a signal distributed as three signals, each signal at a phase shift of 120 degrees from the other signals such that peaks and valleys of the three signals do not align. The three signals may be offset from each other by one-third of each cycle such that the waveform produced by each phase may be offset from one-third of a cycle produced by the other two phases. A three-phase signal may allow for efficient stepping up and stepping down of high voltages and/or currents for power transmission.

An inverter (e.g., a power inverter) may refer to a device or circuitry that converts a direct current (DC) signal to an AC signal (e.g., a DC-to-AC converter). An inverter may convert a DC signal to produce a square wave, a sine wave, a modified sine wave, a pulsed sine wave, a pulse width modulated wave (PWM) depending on the circuit design of the inverter. An inverter may convert DC power stored in a battery to AC power for causing a vehicle motor to spin. An inverter may include one or more transistors, capacitors, inductors, oscillators, transformers for switching a polarity of a DC input signal back and forth to produce an AC output signal. Some inverters may additionally include a PWM (Pulse Width Modulated Wave), one or more filters, and/or control circuitry to cause produce an AC output having a smooth sine wave shape.

An alternator may refer to a device or circuitry for converting mechanical energy (e.g., produced by in internal combustion engine) to an AC signal. An alternator may include a rotating portion (e.g., a rotor) and a stationary portion (e.g., a stator). The rotor may be associated with conductive windings and the stator may be associated with one or more magnets (or the reverse), such that when the rotor rotates relative to the stator due to a rotational mechanical force produced by the engine, the magnets induce an AC current, in the conductive windings.

A rectifier may refer to a device or circuitry that converts an alternating current (AC) to a direct current (DC) signal (e.g., an AC-to-DC converter). A rectifier may convert an AC signal outputted by an alternator and/or an inverter to a DC signal (e.g., for storing in one or more batteries). In some embodiments, an inverter may operate as a rectifier when power flows in the opposite direction during regenerative braking.

A direct current source refers to a supply of direct current. Some non-limiting examples of a direct current source may include a battery, a capacitor, a fuel cell and/or a solar panel. A direct current source for generating a cancellation magnetic field may include a battery for powering a vehicle and/or a different direct current source, electrically isolated from a battery for powering a vehicle.

An amplifier refers to an electronic device for increasing a magnitude of a signal. An amplifier may receive an input signal and power from a power supply. The amplifier may use power from the power supply to produce an output signal that is stronger than the input signal, where signal strength may be measured as a voltage (Volts), a current (A), and/or power (Watts). A gain of an amplifier may indicate an amount of amplification provided by the amplifier and may be measured as a ratio between the input signal and the output signal. An amplifier may include one or more transistors, feedback loops, and/or biasing circuits. The transistors (e.g., a Bipolar Junction Transistor, or BJT and/or a MOSFET) may amplify a weaker input signal to produce a stronger output signal. The feedback loop may permit controlling an output current to match a specific level, e.g., indicated by the signal. The biasing circuit may ensure that the amplifier operates within a linear region to avoid signal distortion. In some embodiments, an amplifier may include an operational amplifier (e.g., an Op-Amp) having a feedback circuit for stability and for controlling gain. In some embodiments, an amplifier may include a linear amplifier for maintaining linear proportionality between signal strength of an output signal and signal strength of an input signal. For instance, a linear amplifier may amplify a current without substantially introducing distortions, such that a waveform of an output current may substantially match a waveform of an input current (e.g., having substantially the same frequency and/or phase) while increasing the amplitude of the output current relative to the input current. However, amplifiers (e.g., including linear amplifiers) may introduce a phase shift between an input current and an output current due to one or more latencies introduced during amplification. For instance, a variable gain amplifier may change a phase of an output current relative to an input current as a gain of the amplifier is varied, and each stage of a multi-stage amplifier may introduce a latency, resulting in a cumulative phase shift between an input current and an output current. In addition, feeding a high frequency current to an amplifier may introduce a phase shift in an output current. An amplifier may be associated with one or more classes, such as class A, B, and/or AB (e.g., linear) amplifiers, class C, D, E, and/or F (e.g., switching) amplifiers, class H (e.g., variable voltage) amplifiers, and/or any other type of amplifier.

A capacitor may refer to an electronic component configured to store electrostatic energy in an electric field by storing electric charge on two opposing surfaces (e.g., conducting plates) separated by an insulator (e.g., a dielectric medium). Applying an electric potential difference (e.g., a voltage) across the plates of a capacitor, may cause an electric field to develop across the dielectric medium, causing a net positive charge to accumulate on one plate and net negative charge to accumulate on the opposing plate, allowing for storage of electrical energy as a potential difference between the two plates. The plates of a capacitor may be connected to other circuit components (e.g., via contacts of the capacitor) allowing for integration of one or more capacitors into an electronic circuit. In some embodiments, a capacitor may function as a source of electrical energy (e.g., similar to a battery). However, a capacitor may be differentiated from a battery because a capacitor may lack a chemical reaction to receive, store and generate electrical energy.

A battery (e.g., a battery pack) may refer to an electrical device configured to convert chemical energy into electrical energy or vice versa. A battery may include one or more cells, each cell containing electrodes and an electrolyte. When the electrodes are connected to an external circuit, a chemical reaction may occur in the electrolyte, creating a flow of electrons, which generates an electric current. The amount of electrical energy that can be stored in a battery may be determined by the capacity (e.g., measured in amp-hours, Ah, or milliampere-hours, mAh). A battery of an electric vehicle may be recharged by plugging the battery into an electric outlet associated with a power source, such as an electrical grid. A battery of a hybrid vehicle may be recharged by plugging in the battery to a power source, through regenerative braking and/or by drawing power from an internal combustion engine.

A vehicle refers to a machine for automated transportation. A vehicle may refer to a means of transportation used to carry people, goods, or materials from one place to another. It may operate on land, water, or air, and encompasses a wide range of designs and functions. A vehicle may include a vehicle chassis, a frame, one or more axels, gears, a plurality of wheels, and one or more electric components (e.g., at least one power source including an engine and/or one or more batteries, a motor, an inverter, a transformer, one or more wires and/or cables, and/or any other electric components). The vehicle power source may supply power the motor, causing the motor to spin. The motor may be mechanically coupled to the one or more axels, enabling transfer of rotational motion of the motor to the one or more axels. One or more gears interfacing between the motor and an axel may enable control of the rotational speed of the axel relative to the rotational speed of the motor (e.g., measured in revolutions per minutes, or rpm). The one or more axels may be mechanically coupled to a plurality of wheels, enabling transfer of rotational motion from the one or more axels to the plurality of wheels, causing the vehicle to move.

In some embodiments, a vehicle may include at least one computing device for controlling the operation of the vehicle, however, this is not required. A vehicle may be powered, at least partially, using electricity. Some vehicles may be powered exclusively using an internal combustion engine. Some vehicles, e.g., hybrid vehicles, may operate using a combination of an internal combustion engine and electric power stored in a battery, such that during some time periods, one motor may be powered by the internal combustion engine during and at other time periods, another motor may be powered by the battery. Some vehicles may be fully electric vehicles and may be powered exclusively using energy stored in a battery. The frame of a vehicle may enclose a passenger cabin. A vehicle chassis may support the frame from above, and one or more electric components from below, to the front, and/or from behind. The vehicle chassis and frame may be made of strong, durable materials such as steel and/or aluminum (e.g., conductive material). A vehicle may include a floorboard, a front panel, and/or a rear panel separating one or more electric components supported by the chassis from the passenger compartment enclosed by the frame. The vehicle floorboard, the front panel, and/or the rear panel may include one or more composite and/or plastic panels (e.g., undertrays). In some instances, a vehicle floor may additionally include one or more vinyl and/or rubber mats and/or carpeting.

A chassis of a vehicle refers to a load bearing underpart of a vehicle providing the vehicle with structural support. A chassis of a vehicle may support a body (e.g., frame) of the vehicle enclosing the passenger cabin. The chassis may be made of metal such as steel (e.g., carbon steel), aluminum and/or alloys thereof, and/or other strong, low weight materials. A metallic chassis may include electrically conductive materials and thus may conduct electricity. In other words, a chassis in electrical contact with one or more current carrying wires (e.g., a wire cable) may form a portion of an electrically conducting loop in a vehicle through which a current may pass and generate a magnetic field. In some embodiments, a chassis may function as a return path for a current flowing during vehicle operation. For example, a battery may include a positive terminal, and a chassis may serve as a ground and/or negative terminal such that during vehicle operation, current may flow from the battery to the chassis (e.g., via a load such as an infotainment system, lights, fans, portions of a climate control system, a seat heater, and/or any other load of a vehicle). In some embodiments, a portion of a wire cable may extend through a chassis of a vehicle without having electrically contacting therewith. For example, the wire may include an insulating sheath that insulates it from the walls of the opening(s) in the chassis, and thus the chassis may not be included in a conducting loop associated with the wire cable

A passenger cabin refers to a region and/or space (e.g., a compartment) enclosed within a vehicle for accommodating one or more passengers. A passenger cabin may be enclosed by a frame supported atop a chassis, and/or a cabin roof from above, a floorboard from below, and a plurality of walls from the sides. At least some of the walls may include doors to permit entry and exit from the vehicle, and/or windows. The cabin floor (e.g., the floorboard) and/or front and/or rear walls may separate the passenger cabin from electric components of the vehicle. A passenger cabin may include one or more seats for accommodating one or more passengers therein (e.g., two adjacent seats aligned in a front row for seating a driver and a passenger, and two or more adjacent seats aligned in a back row and optionally one or more seats in an intermediate between the front row and the back row).

A vehicle passenger refers to an individual travelling and/or commuting on a vehicle or a transportation machine, such as an automobile, van, sports utility vehicle (SUV), truck, tractor, bus, and/or any other machine for transporting individuals.

A magnetic field is a region of space where magnetic forces can be detected. A magnetic field may refer to a distribution of a magnetic force in space and may be measured in Tesla (T) or Gauss. A magnetic field may include a vector field describing a magnitude (e.g., intensity) and direction of a magnetic force in a vicinity of a magnet, an electric current, and/or an electric field. A magnetic field may describe magnetic influence on one or more electric particles (e.g., charges), and may cause charged particles to deflect (e.g., move). For instance, such motion may be used to cause a motor to spin. Thus, a magnetic field may be described as a force having a strength (e.g., intensity) and direction. Causing the force to meet with an equal and opposite force may result in cancellation such that the net force may be zero. In other words, a first magnetic field propagating within a space may be cancelled by introducing a second magnetic field in the space having the same intensity but opposite direction. A magnetic field may be generated by a current flowing through a wire.

The intensity of the magnetic field may be proportional to the amount of charge flowing through the wire, such that increasing/decreasing the current in the wire increases/decreases the magnetic field. The direction of the magnetic field may depend on the direction of the current flowing through the wire. In other words, causing a current to flow through a wire in a first direction may generate a magnetic field having a corresponding first direction. Reversing the direction of the current flowing through the wire may reverse the direction of the magnetic field. A first magnetic field generated by a first current flowing through a first wire may be cancelled by a second magnetic field generated by a second current flowing through a second wire in an opposite direction to the first current and having the same magnitude.

Electrically controlled and/or powered components and/or features of a vehicle may include one or more of at least one internal combustion engine, motor, an alternator, an inverter, a rectifier, a battery, a transformer, a capacitor, and/or an inductor. Additionally or alternatively, an electrically controlled component of a vehicle may include one or more of an (e.g., regenerative) braking system, a steering system, a windshield wiper system, an airbag system, a climate control system, an infotainment system, a navigation system, a system for opening, closing, locking, and/or unlocking one or more vehicle doors and/or windows, one or more internal and/or external lights, a seat adjustment system (e.g., a seat height and/or tilt, and/or a seat heater, and/or seat cooler), one or more sensors (e.g., a camera, a microphone, radar, lidar, and/or ultrasound sensor, one or more magnetic field and/or electromagnetic field sensors, current and/or voltage sensors, an olfactory sensor, and/or any other type of sensor), and/or any other electrically controlled system for operating a vehicle. Additionally or alternatively, an electrically controlled component of a vehicle may include one or more conductive wires and/or cables and/or any other load consuming electrical power in a vehicle

Magnetic field radiation refers to energy emitted by one or more varying magnetic fields and may be independent of an accompanying electric field. Sources of magnetic field radiation may include a current flowing through a wire, an electric motor, a transformer, an inverter, a battery, a permanent magnet, and/or any other source of a magnetic field. Magnetic field radiation may penetrate through substances such as plastic, composite, vinyl, rubber, wood, and/or other magnetic permeable materials. For example, a first magnetic field generated by a current-carrying cable under the vehicle chassis may permeate through a floorboard and radiate into the passenger cabin, a second magnetic field generated by a motor located at the front of the vehicle may permeate through the front panel and enter the cabin, and a third magnetic field generated by a battery located by the trunk may permeate through the rear wall and/or seats and radiate into the cabin.

The term “aggressor” (e.g., an aggressor magnetic field, an aggressor current, an aggressor wire) as used herein denotes an association with something potentially damaging, harmful, hazardous, and/or unsafe. An aggressor magnetic field refers to a magnetic field (as described above) that is potentially harmful and/or unsafe for humans, e.g., by exceeding a level considered safe for humans. An aggressor magnetic field may be generated (e.g., inadvertently) due to vehicle operation. For example, one or more electrical components for operating a vehicle (e.g., a motor, a battery, a wire cable, an inverter, a rectifier, a transformer, a capacitor, and inductor, and/or any other electrical component) may generate a magnetic field during vehicle operation that may be harmful to passengers.

Protecting vehicle passengers from magnetic field radiation refers to safeguarding individuals inside the vehicle from potential adverse effects caused by magnetic field radiation. This may involve reducing, minimizing, or eliminating exposure to magnetic field radiation for individuals present within the vehicle. One or more electric components of a vehicle (e.g., a motor, inverter, transformer, battery, and/or wire cable) may generate a magnetic field that may permeate into a passenger compartment of the vehicle, exposing individuals inside the passenger compartment to magnetic field radiation. To protect individuals from the adverse effects of magnetic field radiation, disclosed embodiments aim to reduce or neutralize the generated magnetic field. For example, disclosed embodiments may cause magnetic field radiation associated with vehicle operation to remain below a threshold level associated with one or more health-related regulations.

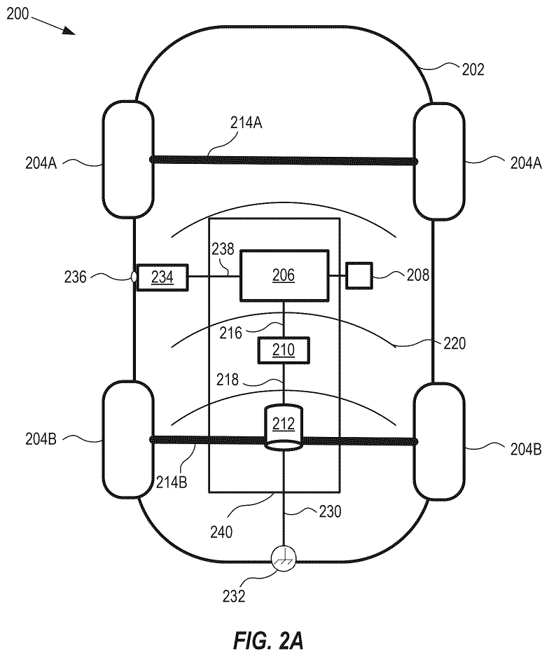

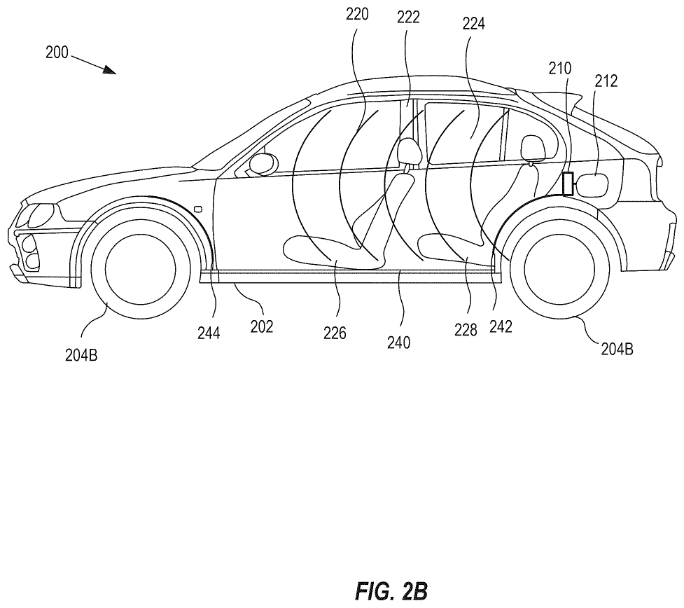

By way of a non-limiting example, reference is made to FIG. 2A illustrating an exemplary schematic diagram of an at least partially electrified passenger vehicle 200 from a top-view, consistent with some disclosed embodiments. Vehicle 200 may include a chassis 202, a plurality of wheels 204 (e.g., front wheels 204A and rear wheels 204B), a battery pack 206 including at least one battery, a controller 208, at least one inverter 210, at least one motor 212, a front axle 214A and a rear axle 214B, a rectifier 234, and a plug 236. Vehicle 200 may be an electric vehicle (EV) powered only using electrical energy supplied by battery pack 206. Plug 236 may be adapted to connect to an external electric power source, such as an electrical grid supplying AC current. When vehicle 200 is not operating and is connected to the external electric power source, rectifier 234 may receive an AC current from the external electric power source via plug 236. Rectifier 234 may convert the AC current to a DC current and supply the DC current to battery pack 206 via a wire cable 238 for storage. Battery pack 206 may be electrically connected to at least one inverter 210 via a wire cable 216. At least one inverter 210 may be electrically connected to at least one motor 212 via a wire cable 218. In the exemplary embodiment shown, at least one motor 212 may be mechanically coupled to rear axle 214B. During vehicle operation, battery pack 206 may supply DC current to at least one inverter 210 via wire cable 216. At least one inverter 210 may convert the DC current to an AC current and provide the AC current to at least one motor 212 via wire cable 218, causing at least one motor 212 to spin. This may cause rear axle 214B and rear wheels 204B to spin. Battery 206 may be connected to a ground via a wire cable 230. In some embodiments, the ground may be a chassis ground 232, associated with chassis 202.

It may be noted that vehicle 200 is illustrated for exemplary purposes only and does not limit this disclosure to a specific implementation. For instance, the arrangement of inverter 210 and motor 212 within vehicle 200 is illustrated for exemplary purposes only and does not limit the disclosure to any particular implementation. In another implementation, inverter 210 and motor 212 may be electromechanically coupled to front axle 214A instead of to rear axle 214B via one or more additional wire cables (e.g., vehicle 200 may be a front-wheel drive vehicle instead of a rear-wheel drive vehicle). In some embodiments, vehicle 200 may include a plurality of inverters and motors, such as a front inverter and a front motor electromechanically coupled to front axle 214A and a rear inverter and a rear motor electromechanically coupled to rear axle 214B (e.g., for an all-wheel drive vehicle) using a plurality of front and rear wire cables. In some embodiments, each wheel of vehicle 200 may be electromechanically coupled to a dedicated inverter and/or motor. Moreover, vehicle 200 may include additional motors and and/or wire cables for operating one or more doors, windows, locks, cameras, lights, climate control systems, information systems, and/or any other electrically operated function of vehicle 200, each of which may generate one or more magnetic fields.

One or more of battery pack 206, wire cable 216, wire cable 218, inverter 210, and motor 212 may generate a primary magnetic field 220 during vehicle operation (e.g., while current flows through wire cables 216 and 218). For example, in an exemplary vehicle 200, battery pack 206 provides direct current (DC) which is transmitted through wire cable 216 to inverter 210. Inverter 210 converts the DC to AC and supplies it to motor 212 through wire cable 218 for driving motor 212. Within motor 212, the AC flows through windings, creating a time-varying magnetic field. This magnetic field interacts with a rotor of motor 212 to produce torque, ultimately driving wheels 204B of vehicle. Primary magnetic field 220 may be generated, at least partially, by the coordinated operation of the above-described components.

By way of a non-limiting example, reference is made to FIG. 2B illustrating an exemplary schematic diagram of vehicle 200 in a side-view, consistent with some disclosed embodiments. Chassis 202 of vehicle 200 may support a frame 222 enclosing a passenger cabin 224. Passenger cabin 224 may include one or more front seats 226 and/or rear seats 228. Absent magnetic field cancellation and/or shielding, at least a portion of primary magnetic field 220 may radiate into a passenger cabin 224 during vehicle operation, exposing any passengers therein to the magnetic field. Magnetic field cancellation refers to the process of reducing or eliminating the effects of a magnetic field (e.g., primary magnetic field 220) by superimposing another magnetic field that opposes it. When these opposing fields overlap, their forces cancel each other out, effectively reducing or eliminating the overall magnetic effect.

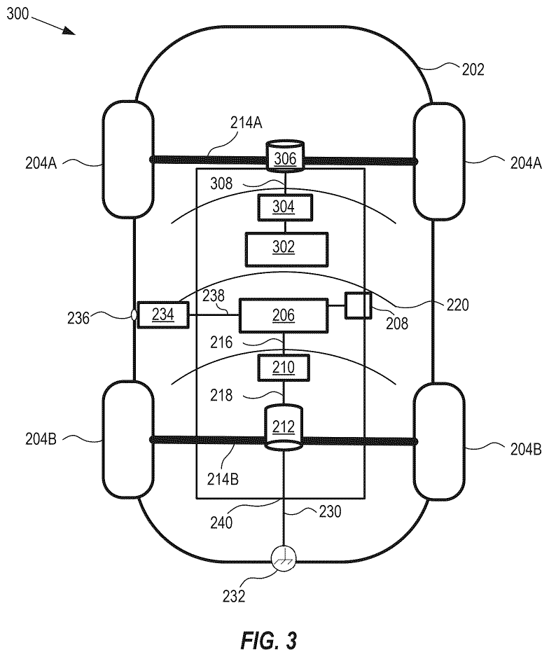

By way of a non-limiting example, reference is made to FIG. 3 illustrating an exemplary schematic diagram of a hybrid passenger vehicle 300 in a top-view, consistent with some disclosed embodiments. Hybrid passenger vehicle 300 may be substantially similar to electric vehicle 200 with the noted addition of an internal combustion engine 302 electromechanically connected to an alternator 304 and a motor 306. For instance, a side-view of hybrid vehicle 300 may be substantially similar to the side-view of electric vehicle 200 shown in FIG. 2B. Internal combustion engine 302 may burn fuel to generate mechanical motion which may be transferred to alternator 304 for conversion to an AC current. Alternator 304 may deliver the AC current to motor 306 via a wire cable 308, causing motor 306 to turn. The spinning motion of motor 306 may cause front axle 214A and front wheels 204A to spin. During some time periods, hybrid passenger vehicle 300 may be powered using internal combustion engine 302 and motor 306. During other time periods, hybrid passenger vehicle 300 may be powered by electric motor 212 using energy stored in battery 206. In some embodiments, battery pack 206 of hybrid vehicle 300 may receive electrical charge from a braking system (not shown) and/or from internal combustion engine 302. In some such embodiments, vehicle 300 may not include plug 236.

As with electric vehicle 200, the arrangement of inverter 210, motor 212, internal combustion engine 302 and motor 306 within vehicle 300 is but an exemplary implementation and does not limit the disclosure to any particular implementation. For instance, internal combustion engine 302 may be associated with rear-axle 214B and rear wheels 204B, and electric motor 212 may be associated with front-axle 214A and front wheels 204A, Alternatively, internal combustion engine 302 and battery 206 may both power rear wheels 204B (e.g., rear-wheel drive), front wheels 204A (e.g., front-wheel drive) and/or both rear wheels 204B and front wheels 204A (e.g., all-wheel drive). Similarly, vehicle 300 may include additional motors and and/or wire cables for operating one or more doors, windows, locks, cameras, lights, climate control systems, infotainment systems, and/or any other electrically operated function of vehicle 300, each of which may generate one or more magnetic fields.

A threshold level and/or value refers to a baseline, limit, and/or boundary (e.g., floor or ceiling). A threshold level may be used as a guideline and/or standard. An upper threshold may be used as a standard to mitigate phenomena exceeding the upper threshold, and a lower threshold may be used to mitigate phenomena falling below the lower threshold. A threshold level may be associated with one or more safety standards and/or regulations. A threshold level may be associated with one or more standards, recommendations, and/or guidelines of the International Commission on Non-Ionizing Radiation Protection (ICNIRP) providing scientific advice and guidance on the health and environmental effects of non-ionizing radiation (NIR) and recommended limits to exposure of radiofrequency electromagnetic fields (RF).

A control unit refers to a device and/or component(s) for regulating, monitoring, and/or adjusting an output signal to meet one or more criteria. A control unit may receive one or more input signals and use the input signals to produce an output signal. At least one of the input signals may be received from a sensor, such as a current sensor, a magnetic field sensor, and/or an electromagnetic field sensor. In some embodiments a control unit may be synonymous with at least one processor. In some embodiments, a control unit may include an amplifier. The amplifier may be connected to a power supply. The power supply may provide a supply current, and the amplifier may adjust the supply current as a function of a signal received from a sensor to produce an output current. The output current may have attributes (e.g., amplitude, frequency, phase, and/or direction) corresponding and/or proportional to a current indicated by the signal received from the sensor. In some embodiments, a control unit may include a feedback loop to ensure that an output signal is within range of a targeted output signal. For example, a control unit may include a Proportional-Integral-Derivative (PID) controller to continuously control and/or adjust an output signal by comparing a desired output (e.g., a setpoint value) to the current indicated in the signal received from the sensor until the output signal substantially matches the setpoint value within a tolerance range. In some embodiments, a control unit may include at least one processor, however this is not required.

By way of example, a control unit may receive a signal from a current sensor indicating an (e.g., aggregate) aggressor current flowing through one or more aggressor wires associated with vehicle operation. The aggressor current may generate a potentially harmful aggressor magnetic field capable of radiating into a passenger cabin of a vehicle. Based on the received signal, the control unit may output a cancellation current to a cancellation wire for generating a cancelling magnetic field capable of at least reducing the aggressor magnetic field, e.g., to maintain any remaining aggressor magnetic field in the passenger cabin below a threshold value. In some embodiments, the control unit may output a cancellation current having substantially similar attributes (e.g., one or more of an amplitude, frequency, and/or phase) as the aggressor current but opposite in direction, such that the cancelling magnetic field is substantially equal and opposite to the aggressor magnetic field. In some embodiments, a control unit may output a cancellation current having an amplitude proportional (e.g., as a factor of N, 1/N, M/N) to an amplitude of an aggressor current indicated by the signal received from the sensor, e.g., to account for one or more loops in a cancellation wire carrying the cancellation current and/or one or more loops in the one or more aggressor wires, such that a cancelling magnetic field may be substantially similar and opposite an the aggressor magnetic field.

Determining refers to arriving at a conclusive outcome. It may include, for example, undertaking an equality comparison to check whether two values are the same or are in a predetermined range. For example, the check may involve an equality operator like == in many languages (e.g., Python, JavaScript, C++). If the values are the same, the comparison evaluates to true; otherwise, it evaluates to false. Determining may additionally or alternatively include making a measurement, comparison, estimation, and/or calculation to arrive at a conclusive outcome.

Detecting refers to sensing, perceiving, discovering, recognizing, and/or identifying. Detecting may include identifying, recognizing, and/or discovering something by monitoring for patterns, signals, and/or anomalies that indicate certain events and/or conditions. Detection may be performed by a sensor, a receiver (e.g., a port and/or an antenna), and/or at least one processor and may involve sensing a change in state from one time period to a subsequent time period.

Transmitting (e.g., signals) refers to conveying a signal over a distance. Transmitting may be performed on a wired channel (e.g., a twisted pair cable, a coaxial cable, and/or a fiber optic cable) and/or using a wireless channel (e.g., Wi-Fi, Bluetooth, satellite, and/or cellular). The signal may include information encoded in an electronic and/or electromagnetic signal, and/or electric power for driving one or more electrical components.

Receiving (e.g., signals) refers to obtaining, acquiring, and/or otherwise gaining access to a signal over a distance. Receiving may be performed on a wired and/or wireless channel. The signal may include information encoded in an electronic and/or electromagnetic signal, and/or electric power for driving one or more electrical components.

Ferromagnetic shielding material may include substances capable of redirecting and/or containing magnetic fields. Such materials may have high magnetic permeability, allowing the materials to attract and channel magnetic field lines effectively. Some examples of ferromagnetic shielding materials include: Mu-Metal, Permalloy, soft iron, silicon steel, silicon steel GO (Grain Oriented), silicon steel NGO (Non Grain Oriented), electrical steel, transformer steel, ferrites, and/or Metglas. Mu-Metal refers to a nickel-iron alloy with high permeability. Permalloys refer to a group of nickel-iron alloys with high magnetic permeability. Soft Iron refers to low-carbon iron with high permeability and low coercivity. Silicon steel refers to a steel alloy containing silicon to reduce eddy currents. Ferrites refer to ceramic compounds composed of iron oxide mixed with other metals. Metglas (Amorphous Metal Alloys) refers to ultra-thin, high-permeability materials.

Some disclosed embodiments involve a system for protecting vehicle passengers in a passenger cabin from magnetic field radiation, as described elsewhere herein). During vehicle operation, absent magnetic field cancellation and/or reduction (or magnetic field attenuation), one or more magnetic fields generated by electrical components of the vehicle may permeate into the passenger cabin, e.g., through any of a cabin floorboard, a front, and/or rear panel, and spread throughout the passenger cabin occupied by one or more passengers. For example, in some EVs, the battery pack is located beneath or behind passenger seats, and the motor and inverter are positioned close to the vehicle's body. The magnetic fields generated by these components during vehicle operation can permeate the passenger cabin due to the proximity of these components to the cabin and expose passengers to magnetic and/or electromagnetic radiation.

Some disclosed embodiments involve a wire cable configured to carry electricity during vehicle operation. A wire cable includes one or more wires or electric conductors, as described elsewhere herein. Each wire of a cable may be completely flexible along its entire length, partially flexible along some portions of its length, or completely inflexible, depending on implementation. In some embodiments, one or more wires of a cable may be coated with an insulating layer and may be bundled together within a protective sheath covering the wire cable. In some embodiments, a wire cable may include any conductive material in contact with one or more current-carrying wires. For example, a wire cable may include one or more metallic and/or other conducting portions of a vehicle frame and/or any other conducting portion (e.g., an electrically conductive bar) in the vehicle. In some embodiments, a wire cable may include a bundle of wires (e.g., a low voltage, medium voltage, and/or high voltage) within wiring harness (as described elsewhere herein).

In some disclosed embodiments, a portion of the wire cable extends through a chassis of the vehicle. A chassis of a vehicle refers to a load bearing support or underpart of a vehicle providing the vehicle with structural support. A chassis of a vehicle may support a body (e.g., frame) of the vehicle enclosing the passenger cabin. The chassis may be made of metal such as steel (e.g., carbon steel), aluminum and/or alloys thereof, and/or other strong, low weight materials. A metallic chassis may include electrically conductive materials and thus may conduct electricity. In other words, a chassis in electrical contact with one or more current carrying wires (e.g., a wire cable) may form a portion of an electrically conducting loop in a vehicle through which a current may pass and generate a magnetic field. A portion of a wire cable extending through a chassis of a vehicle may thus include a cable routed in proximity to the chassis, and/or a chassis forming part of a current path in a vehicle. In some embodiments, a chassis may function as a return path for a current flowing during vehicle operation, e.g., for lower voltage systems (e.g., 12V), such as for powering one or more lights, and/or an infotainment and/or sound system. For example, a battery may include a positive terminal, and a chassis may serve as a ground and/or negative terminal such that during vehicle operation, current may flow from the battery to the chassis (e.g., via a load such as a climate control system, lights, infotainment system, and any other load of a vehicle). In some embodiments, a portion of a wire cable may extend through a chassis of a vehicle without having electrically contacting therewith. For example, the wire may include an insulating sheath that insulates it from the walls of the opening(s) in the chassis, and thus the chassis may not be included in a conducting loop associated with the wire cable.

Vehicle operation refers to a functioning and/or working of a vehicle and may involve delivery of electric power from a power source to a motor. Vehicle operation may require current to flow to and/or through one or more electrically controlled and/or powered components and/or features of a vehicle, as described elsewhere herein. During vehicle operation refers to a period of time when a vehicle charges or runs. For example, in an electric or hybrid electric vehicle, vehicle operation may encompass time periods during which a motor of a vehicle receives electric power from a power source. This may include a power source internal to the vehicle, e.g., for causing a motor to spin for propelling the vehicle while one or more gears are engaged, this may cause a motor to spin, and/or while a vehicle is stationary (e.g., while stopped in traffic or otherwise idling when the gears are disengaged). In some embodiments, vehicle operation may include a time period during which a vehicle receives (e.g., AC power) from an external power source, such as an electrical grid for charging a battery using a rectifier. Thus, vehicle operation may be associated with generation of one or more magnetic fields by electrical components of the vehicle. Absent cancellation, the generated magnetic field may permeate into the passenger cabin.

In some disclosed embodiments, the wire cable connects an inverter to a motor. Examples of an inverter are described elsewhere herein. For example, in a hybrid and/or electric vehicle, a DC power supply such as a battery pack, may deliver a DC current to an inverter, which may convert the DC current to an AC current. A wire cable may deliver the AC current outputted from the inverter to a motor. The AC current may cause the motor to spin, e.g., at a frequency dependent on the frequency of the AC current and/or one or more gears, causing the wheels of the car to turn.

In some disclosed embodiments, the wire cable connects a rectifier to a battery (as described elsewhere herein). In other words, one end of a wire cable may be electrically coupled to a rectifier and an opposite end of the wire cable may be electrically coupled to a battery. For instance, a rectifier may receive an AC signal (e.g., from an onboard generator, an external AC power source such as a charging station, an inverter, the vehicle's alternator, or another source of AC), convert the AC signal to a DC signal, and output the DC signal. The DC signal may flow via the wire cable to a battery and stored as DC electrical energy for subsequent use in powering the vehicle.

By way of a non-limiting example, in FIG. 2B, vehicle 200 may include a passenger cabin 224 supported by frame 222. Passenger cabin 224 may include at least one front seat 226 and at least one rear seat 228 for transporting one or more passengers inside passenger cabin 224 during vehicle operation. By way of another non-limiting example, in FIG. 2A and FIG. 3, one or more of wire cables 216, 218, 230, and/or 238 of electric vehicle 200 and/or hybrid vehicle 300 may carry electricity during vehicle operation. In some embodiments, a portion of a wire cable of electric vehicle 200 and/or hybrid vehicle 300 may extend through chassis 202, e.g., to supply current for powering one or more lights, fans, climate control system, and/or an infotainment system of vehicle 200 (e.g., lower voltage systems such as up to 12V).

Some disclosed embodiments involve generating a primary magnetic field that, in an absence of cancellation, would radiate into the passenger cabin. Generating a primary magnetic field refers to producing and/or inducing a magnetic field (e.g., due to vehicle operation). For example, vehicle operation may include one or more of rotation of a motor, operation of a battery and/or an inverter, and/or a current running through a wire cable, which may produce a magnetic field. Vehicle operation may include any state of a vehicle associated with a flow of electric current through one or more wires, cables, and/or components of the vehicle. This may include periods during which the vehicle is moving, idling (e.g., stationary), and/or charging. A magnetic field generated as a result vehicle operation may be referred to herein as a primary magnetic field, e.g., to distinguish this magnetic field from the Earth's magnetic field, another external magnetic field unassociated with vehicle operation, and/or a cancelling magnetic field generated to at least partially eliminate (e.g., attenuate, reduce, mitigate) the primary magnetic field. Cancellation of a magnetic field may include at least partially annulling, eliminating, and/or otherwise significantly reducing a magnetic field. For instance, cancellation of a magnetic field may result in a negligible magnetic field, and/or a magnetic field below a threshold level (e.g., associated with one or more regulations and/or standards). Absence of cancellation refers to a non-existence, deficiency, and/or lack of elimination and/or significant reduction of a magnetic field. Cancellation of a magnetic field may eliminate or at least significantly reduce a magnetic field generated by vehicle operation, whereas absence of cancellation may result a magnetic field radiating into a passenger cabin exposing passengers therein to magnetic radiation above a threshold level. To radiate refers to spread, permeate, propagate, and/or to become distributed. A primary magnetic field that “would radiate into a passenger cabin” refers to a potential and/or capability of spreading and/or propagating within a passenger compartment of a vehicle, thereby exposing any individuals located within the passenger compartment to magnetic radiation. For instance, turning on an electric and/or hybrid vehicle may cause current to flow through one or more wire cables. This may generate a magnetic field. Absent a system and/or apparatus to cancel and/or block the generated magnetic field, that magnetic field would otherwise radiate into the passenger cabin such that a strength of the magnetic field inside the passenger cabin may be above a threshold level.

Some disclosed embodiments involve a current sensor associated with the wire cable, for sensing current passing through the wire cable. A current sensor is a device that either directly or indirectly detects and/or measures the flow of electric current through a conductor. A current sensor may be electrically connected and/or in proximity to a wire cable for detecting and/or measuring an electric current flowing through the wire cable. A current sensor may detect a flow of electrons flowing through a wire cable and convert the detected flow to a quantifiable output, such as a measurement in Amps (A) and/or Volts (V). Some examples of a current sensor may include a shunt resistor and/or copper trace, a current transformer, a fluxgate sensor, a magneto-resistive (MR) sensor, and/or a fiber optic current sensor. In some embodiments, a current sensor may include an analog current sensor that may output a continuous representation of a measured current and may avoid use of an analog-to-digital and/or digital-to-analog converter. Examples, of an analog current sensor may include a shunt resistor that may be positioned in series with a wire cable and may measure current as an associated voltage differential across the resistor, a Hall effect sensor that may measure a magnetic field generated by a current and output an associated voltage, and a current transformer which may measure an AC current using electromagnetic induction. In some embodiments, a current sensor may include a digital sensor that may require an analog-to-digital converter to provide a sensed signal to a processor for analysis. Thus, during vehicle operation, a current sensor may detect a level of current flowing through one or more wire cables of a vehicle. The level of current may be indicative of a magnetic field generated by the current flowing in the wire.

In some disclosed embodiments, a current sensor includes a current clamp. A current clamp (e.g., a clamp meter and/or current probe) refers to an electrical device with jaws that open and close to permit clamping around an electrical conductor (e.g., a wire). This may permit measuring of a current passing through the wire without breaking the circuit and/or without making physical contact with the electrical conductor. For instance, a current clamp may measure a current by sensing a magnetic field surrounding a conducting wire, without making direct physical contact with the conducting wire. In some disclosed embodiments, the current sensor is one of a Hall sensor, an inductance sensor, a field probe, or a Rogowski coil. A Hall sensor refers to a device for measuring strength and/or direction of a magnetic field by utilizing the Hall effect. The Hall effect refers to generation of a voltage (e.g., the Hall voltage) due to placement of a current-carrying conductor in a magnetic field. An inductance sensor (e.g., an inductive proximity sensor) refers to a device for detecting presence of metallic objects using electromagnetic induction in absence of physical contact (e.g., without touching the metallic objects). An inductance sensor may sense an oscillating magnetic field produced by a conducting coil. The magnetic field may induce eddy currents in nearby metallic objects which may affect internal oscillating circuitry of the inductance sensor. A field probe refers to a device for measuring a strength (e.g., magnitude) and/or direction of electromagnetic fields in proximity to a source thereof. A Rogowski coil refers to a toroidal (e.g., donut-shaped) coil of wire for measuring alternating current (AC) and/or current pulses. A Rogowski coil may include a toroidal winding of conductive wire wrapped around a hollow tube made of insulating material (e.g., plastic or rubber). In some disclosed embodiments, the current sensor includes a current transformer. When a current-carrying conductor is placed inside the tube, the changing magnetic field may induce a voltage in the coil, which may be proportional to the current, permitting measurement of the current. In some disclosed embodiments, a current sensor may include a current transformer. A current transformer may include a primary coil and a secondary coil separated by a core. An AC current in the primary coil may produce an alternating magnetic field in the core, which may induce an AC current in the secondary coil. In some embodiments, the primary coil may include a single wire turn, and the secondary coil may include a plurality of wire turns (e.g., for a step-down transformer) such that a higher current in the primary coil induces a smaller current in the secondary coil. The smaller current in the secondary coil may be measure using a sensor, and the larger current in the primary coil may be determined based on the smaller current flowing in the secondary coil (e.g., the larger current may be larger than the smaller current by a factor corresponding to the number of turns in the secondary coil). In some embodiments, a primary coil of a current transformer corresponds to a wire cable configured to carry electricity during vehicle operation, and a secondary coil of the current transformer may be associated with a sensor for measuring an indication of current.

By way of a non-limiting example, in FIGS. 2A-2B and FIG. 3, one or more of wire cables 216, 218, 230, and/or 238 may generate primary magnetic field 220 that, in an absence of cancellation, would radiate into passenger cabin 224. For instance, the current may be used to operate motor 212, and/or one or more additional features of electrical vehicle 200 and/or hybrid vehicle 300 (e.g., a climate control system, one or more lights, a control for a window, mirror, and/or camera, a door lock, a motor for opening and/or closing a door, an information system, and/or any other electrically operated feature).

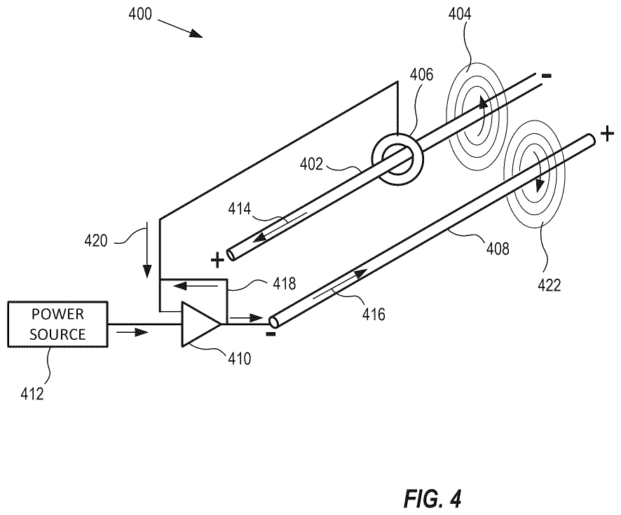

By way of another non-limiting example, reference is made to FIG. 4 illustrating an exemplary system 400 for protecting vehicle passengers from magnetic field radiation, consistent with some disclosed embodiments. System 400 includes a wire cable 402 for carrying electricity (e.g., a current 414) during vehicle operation. Wire cable 402 may correspond to any of wire cables 216, 218, 230, and/or 238 of FIG. 2A or FIG. 3. Current 414 may be used to charge battery 206, to operate motor 212, and/or to perform any other electrically-driven function associated with the operation of vehicle 200 and/or 300. In absence of cancellation, current 414 flowing through wire cable 402 may generate a primary magnetic field 404 that may radiate into passenger cabin 224 (see FIG. 2B). Primary magnetic field 404 may correspond to primary magnetic field 220 of any of FIGS. 2A-2B, and/or FIG. 3. Primary magnetic field 404 may flow in a first direction (e.g., counterclockwise) corresponding to the direction of current 414. System 400 may include a current sensor 406 associated with wire cable 402. Current sensor 406 may sense current passing through wire cable 402. In some embodiments, current sensor 406 may include only analog components and may output an analog signal. In some embodiments, current sensor 406 may include one or more digital components and an analog-to-digital converter and may output a digital signal for reception by a processor and/or controller.

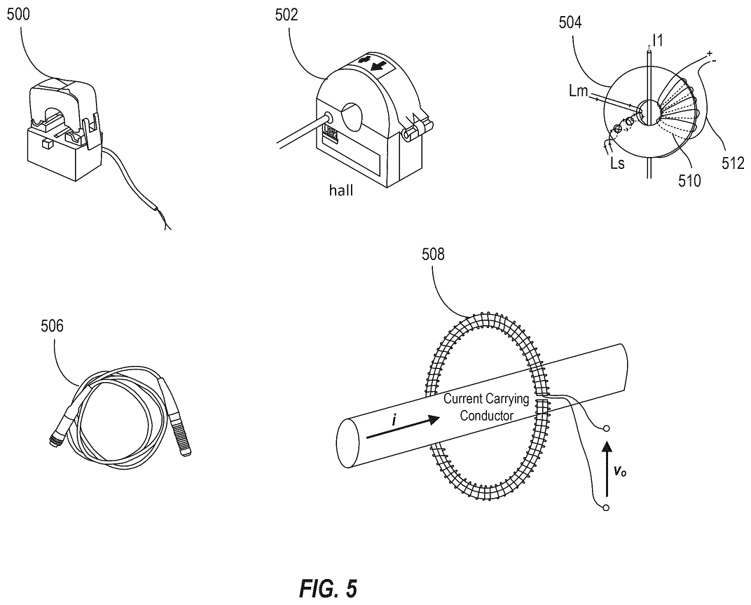

By way of another non-limiting example, reference is made to FIG. 5 illustrating a variety of differing current sensors, consistent with some disclosed embodiments. In some disclosed embodiments, current sensor 406 of FIG. 4 may include a current clamp 500. In some disclosed embodiments, current sensor 406 is one of a Hall sensor 502, an inductance sensor 504, a field probe 506, or a Rogowski coil 508.

Some disclosed embodiments involve at least one cancellation wire, running along at least a portion of the wire cable. A cancellation wire refers to at least one elongated conducting strand, rod, or other conductor for conveying electricity and/or signals for the purpose of cancelling (e.g., substantially reducing) a primary magnetic field. In some embodiments, a cancellation wire may be unassociated with and/or independent of vehicle operation. In other words, a vehicle may operate electromechanically according to an electromotive design using a plurality of vehicle wires and/or cables, in absence of a cancellation wire. The cancellation wire (or wires) may be inserted into the vehicle, as a separate wire (or wires from) the one or more vehicle wires and/or cables used for vehicle operation, such that the electromechanical operation of the vehicle may be unaffected by and/or immune (e.g., neutral) to the addition of the cancellation wire. In other words, one or more cancellation wires may be unrelated to an operation of a vehicle. The purpose for inserting the one or more cancellation wires may be to generate a cancelling magnetic field having similar but opposing characteristics to a primary magnetic field generated by the electromechanical operation of the vehicle, such that combining the cancelling magnetic field with the primary magnetic field results in a substantial reduction or elimination of the primary magnetic field. For example, cancelling a magnetic (and/or electromagnetic) field may involve reducing the magnetic (and/or electromagnetic) field by at least at least 50%, at least 55%, 60%, at least 65%, at least 70%, at least 75%, at least 80%, at least 85%, and/or at least 90%, such that less than half of the magnetic (and/or electromagnetic) field remains. In some embodiments, a plurality of cancelling wires may be associated with a single aggressor wire and/or cable. For example, a combined cancellation current of the plurality of cancelling wires may together generate an aggregate cancelling magnetic field for at least partially cancelling an aggressor (e.g., primary) magnetic field generated by the single aggressor wire and/or cable.

Running along at least a portion of a wire cable refers to either being physically positioned close to and extending in a same general direction of; aligned with; abutting; and/or adjacent to, at least a section of the wire cable. For instance, one or more cancellation wires may have substantially similar path or paths as at least a portion of a wire cable of a vehicle (e.g., an aggressor wire as described elsewhere herein). In some embodiments, one or more cancellation wires may be overlayed on at least a portion of a wire cable. Alignment of one or more cancellation wires along at least a portion of a wire cable may cause a cancelling magnetic field generated by a cancellation current in the cancellation wire to have a similar amplitude, and opposing direction to a primary (e.g., aggressor) magnetic field generated by current flowing through the wire cable, and may radiate in a substantially similar region as the primary magnetic field.

Some disclosed embodiments involve an amplifier configured to receive a signal indicative of current running through the wire cable. A signal may be understood as described elsewhere herein. A signal may include an analog signal, a digital signal, and/or a combination of a digital signal and an analog signal. A signal indicative of current refers to a measurable or observable output that conveys information and/or suggests the presence, occurrence, or characteristics of current. It serves as a representation or indicates the presence or magnitude (or another characteristic of) the current. For example, a voltage signal and/or magnetic field signal are indicative of current flow and may correspond to the magnitude and/or direction of that current. Current running through a wire cable may refer to a flow of electric charge through a wire cable, as described above. The current may include a DC current and/or an AC current and may be used for operating a vehicle, as described elsewhere herein. An amplifier refers to an electronic device for increasing a magnitude of a signal. An amplifier may receive an input signal and power from a power supply. The amplifier may use power from the power supply to produce an output signal that is stronger than the input signal, where signal strength may be measured as a voltage (Volts), a current (A), and/or power (Watts). A gain of an amplifier may indicate an amount of amplification provided by the amplifier and may be measured as a ratio between the input signal and the output signal. An amplifier may include one or more transistors, feedback loops, and/or biasing circuits. The transistors (e.g., a Bipolar Junction Transistor, or BJT and/or a MOSFET) may amplify a weaker input signal to produce a stronger output signal. The feedback loop may permit controlling an output current to match a specific level, e.g., indicated by the signal. The biasing circuit may ensure that the amplifier operates within a linear region to avoid signal distortion. In some embodiments, an amplifier may include an operational amplifier (e.g., an Op-Amp) having a feedback circuit for stability and for controlling gain. In some embodiments, an amplifier may include a linear amplifier for maintaining linear proportionality between signal strength of an output signal and signal strength of an input signal. For instance, a linear amplifier may amplify a current without substantially introducing distortions, such that a waveform of an output current may substantially match a waveform of an input current (e.g., having substantially the same frequency and/or phase) while increasing the amplitude of the output current relative to the input current. However, amplifiers (e.g., including linear amplifiers) may introduce a phase shift between an input current and an output current due to one or more latencies introduced during amplification. For instance, a variable gain amplifier may change a phase of an output current relative to an input current as a gain of the amplifier is varied, and each stage of a multi-stage amplifier may introduce a latency, resulting in a cumulative phase shift between an input current and an output current. In addition, feeding a high frequency current to an amplifier may introduce a phase shift in an output current.

A response time of an amplifier may refer to time taken for an output current of the amplifier to reach and/or stabilize at a specified level after a change in an input current. A response time may include a setting time which refers to the time taken for an output current to settle within a certain tolerance (e.g., +/−0.1%) of a targeted output value after a step change in an input current, and a rise time which refers to the time taken for the output current to transition from a lower level to a high level (e.g., from 10% to 90% of the final value) after a step change in the input current. A slew rate of an amplifier may refer to the maximum rate at which an output current may change in response to a change in an input current and may limit a response time of an amplifier. An amplifier configured to receive a signal indicative of current running through a wire cable refers to an amplifier electrically connected to the wire cable via a wired and/or wireless connection enabling the amplifier to receive information relating to characteristics of the current running through the wire. Such characteristics may include an amplitude (e.g., measured in Volts, Amps, and/or Watts), a frequency (e.g., measure in cycles per second, or Hz), a phase (e.g., measured in seconds, degrees, or radians), a direction, and/or any other characteristic of a current running through a wire cable. In some embodiments, an amplifier may receive signals indicative of current running through a wire cable and/or corresponding voltage continuously over time, permitting the amplifier to continually vary an output signal in response to receiving a continually varying input signal.

For example, an amplifier may use a signal indicative of a current to produce a matching current. The amplifier may receive the signal via a first input and may receive power and/or an input current via a second input. The amplifier may increase the amplitude of the input current based on a current level indicated in the signal to produce a matching output current (e.g., having an amplitude substantially matching the amplitude indicated by the signal). However, at first, the output current may not match the current indicated in the signal, requiring the amplifier to perform one or more adjustments and/or corrections based on feedback received via a feedback circuit feeding the current outputted by the amplifier back into the amplifier. This may require several iterations, which may introduce latency until the current outputted by the amplifier matches the current level of the signal within a threshold level. Some amplifiers may include a processor to produce an output signal, requiring analog-to-digital and digital-to-analog converters Thes may increase the latency and/or response time of the amplifier. Thus, in some embodiments, an amplifier for producing a cancellation current may include only analog components and may thus lack analog-to-digital and digital-to-analog converters to shorten the response time.

Some disclosed embodiments involve generating, within 1500 microseconds of the signal, a cancellation current for application to the cancellation wire. A cancellation current refers to a current capable of generating a cancelling magnetic field for cancelling or at least significantly reducing another (e.g., a primary) magnetic field. For instance, a cancelling magnetic field may reduce the strength (e.g., magnitude and/or amplitude) of a primary magnetic field by at least 50%, at least 60%, at least 65%, at least 70%, at least 75%, at least 80%, at least 85%, or at least 90%. In some embodiments, attributes of a cancellation current may be substantially similar and opposite to attributes of a current flowing through a wire cable generating a primary magnetic field. For example, a cancellation current may have a substantially similar magnitude (e.g., amplitude), frequency, and/or phase as a current flowing through a wire cable for vehicle operation but may flow in an opposite direction. Outputting a cancellation current that does not match the current indicated by the signal may lead to ineffective cancellation, e.g., due to a mismatch in amplitude. For example, if the amplitude of the cancelling magnetic field is too small, an insufficient amount of the primary magnetic field may be cancelled, leaving an above-threshold residual primary (e.g., aggressor) magnetic field in the passenger cabin. If the amplitude of the cancelling magnetic field is too large, cancellation may cause an undesired residual cancellation magnetic field in the passenger cabin. For instance, an amplifier generating a cancellation current may be tuned to operate within a linear operation region. This may permit generation of a cancelling magnetic field having similar magnitude, frequency, and/or phase as a primary magnetic field, and an opposite direction to the primary magnetic field (e.g., if lines of a primary magnetic field point from north to south, lines of a cancelling magnetic field may point from south to north, and the reverse). Additionally or alternatively, an amplifier may be arranged with a feedback loop to continually adjust and/or correct an output cancellation current to match the current flowing in the wire cable and indicated in the signal received from the current sensor. In some embodiments, the amplifier may include a Proportional-Integral-Derivative (PID) controller for continuous control and automatic adjustment. The PID controller may continually and automatically compare a desired output value (e.g., a setpoint value corresponding to the current indicated in the signal received from the current sensor) to the actual current outputted by the amplifier. Any difference between the output value and the setpoint value may be an error value, or e (t). The amplifier may continually adjust the outputted cancellation current until the error value is substantially zero (e.g., below a threshold value).

In some disclosed embodiments, the term “within”, as used herein, may refer to inside a time window corresponding to a time delay (lag) between an aggressor current and a cancelation current, e.g., corresponding to a phase shift for periodic signals, independent of a response time for an amplifier and/or an associated control unit. Some disclosed embodiments involve generating a cancellation current for application to the cancellation wire within 15,000 microseconds, within 150 microseconds, or within 15 microseconds of receiving a signal indicative of current flowing through a wire cable. For example, a control unit and/or an amplifier may have response times of at most 15,000 microseconds, at most 1500 microseconds, at most 150 microseconds, or at most 15 microseconds. Additionally or alternatively, a phase difference between an AC cancellation current and an AC aggressor current may be at most 15,000 microseconds, at most 1500 microseconds, at most 150 microseconds, or at most 15 microseconds.

Generating a cancellation current for application to the cancellation wire refers to delivering, outputting, and/or otherwise supplying a cancellation current to the cancellation loop running along at least a portion of the wire cable to cause generation of a cancelling magnetic field for cancelling a primary magnetic field generated by current flowing through the wire cable. For instance, an amplifier may draw power from a power supply and may receive a signal indicating attributes (e.g., amplitude, frequency, direction, and/or phase) of a current flowing through a wire cable for vehicle operation. A current source (e.g., from the same or different power supply) may feed an input current to the amplifier for producing a cancellation current as an output. The amplifier may use at least the amplitude indicated by the received signal to amplify the input current such that the amplitude of the cancellation current outputted by the amplifier corresponds to the amplitude of the current flowing through the wire cable for vehicle operation. In some embodiments, the amplifier may use a feedback circuit to output a cancellation current matching the amplitude indicated in the received signal. The amplifier may output the cancellation current to the cancellation wire to flow in a direction opposite to the current flowing through the wire cable for vehicle operation. In some embodiments, an amplifier may operate using only analog circuit components. The amplifier may receive an analog input current and/or an analog signal indicative of a current flowing through a wire cable. The amplifier may amplify the analog input current to output an analog cancellation current substantially matching the current flowing through a wire cable using solely analog circuit components, e.g., absent an analog-to-digital and/or digital-to-analog conversion operations and/or computation by a digital processor. In other words, disclosed embodiments may include circuitry that operates exclusively within the analog domain to minimize latency and optimize real-time signal processing by eliminating the need for analog-to-digital and digital-to-analog conversions.

Generating within 1500 microseconds (μs) refers to producing and/or outputting within and/or at most 1.5 milliseconds (ms) (e.g., at or less than 0.0015 seconds). In some embodiments, an amplifier may generate a cancellation current within 1500 microseconds due to operating exclusively in the analog domain, by avoiding analog-to-digital and digital-to-analog conversions and/or computations by a digital processor. The closer a cancelling magnetic field corresponds to a primary magnetic field, the more effective the cancelling magnetic field may cancel the primary magnetic field in the passenger cabin. This may be due to a closer alignment of substantially equal but opposing magnetic field lines of the cancelling magnetic field and the primary magnetic field. However, latencies introduced by an amplifier having a slower response time (e.g., generating a cancellation current after more than 1500 microseconds) may cause a mismatch between the cancellation current and the current flowing through the wire cable, which may cause a corresponding mismatch between the cancelling magnetic field and the primary magnetic field. Such a mismatch (e.g., in amplitude, phase, and/or frequency) may lead to ineffective cancellation of the primary magnetic field, which may lead to a residual magnetic field remaining in the passenger cabin at an above-threshold level. This mismatch may be due to several reasons.

In some disclosed embodiments, in use, the current is continuously varying and the amplifier is configured to generate a continuously varying cancellation current. Current continuously varying in use refers to a changing current at least during a portion of the vehicle operation. In some embodiments, the continuously varying current may perpetually vary during vehicle operation. Such changes may be due to oscillations of the current if the current is an AC current and/or changes in an amount of current drawn to operate the vehicle. Thus, a first reason for a mismatch between a cancellation current outputted by an amplifier generating a cancelling magnetic field and a current flowing through a wire cable generating a primary magnetic field may be due to continuous variations in the current flowing through the wire cable over time due to changes in vehicle operation. For example, braking, accelerating, turning on/off an air conditioner and/or vehicle lights, driving uphill/downhill, increasing/decreasing a weight transported by the vehicle, operating a vehicle at differing speed ranges associated with differing efficiencies, operating a motor to open/close a window or a door, or to adjust a mirror, changing of gears, switching between an internal combustion engine and a battery in a hybrid vehicle, and/or any other variation associated with electric and/or hybrid vehicle operation may cause a corresponding variation in the current flowing through the wire cable. Such operational variations may cause variations in one or more of an amplitude (e.g., magnitude), frequency, phase, and/or direction of the current over time, causing corresponding variations in the associated primary magnetic field radiating into the passenger cabin over time. A response time of greater than 1500 microseconds from when such a change in current is sensed until an amplifier outputs (e.g., generates) a cancellation current matching the changed current may result in a corresponding mismatch between the associated cancelling magnetic field and primary magnetic field in the passenger cabin for at least 1500 microseconds. This may lead to an above-threshold residual magnetic field remaining in the passenger cabin for at least 1500 microseconds, which may be detrimental to the health of a passenger located therein.

A second reason for a mismatch between a cancellation current outputted by an amplifier generating a cancelling magnetic field and a current flowing through a wire cable generating a primary magnetic field may be due to a phase difference between an oscillating cancelling magnetic field and an oscillating primary magnetic field. If current flowing through a wire cable for vehicle operation is an AC current, the primary magnetic field may oscillate at a frequency corresponding to the frequency of the AC current. Effective cancellation may require that a cancellation current have the same or similar frequency and/or phase to permit peaks and valleys of an oscillating cancelling magnetic field generated by the cancellation current to substantially align with peaks and valleys of the oscillating primary magnetic field. A response time for an amplifier within 15,000 microseconds, 1500 microseconds within 150 microseconds, or within 15 microseconds, may lead to a sufficiently close alignment between the peaks and valleys, due to a matching frequency and relatively small phase shift therebetween, such that a residual magnetic field permeating into the passenger cabin after cancellation is below a threshold level. Conversely, a longer response time for an amplifier (e.g., if the amplifier is associated with a digital processor) and exceeding 15,000 microseconds, 1500 microseconds within 150 microseconds, or within 15 microseconds may lead to a misalignment between the peaks and valleys, due to a mismatch in the respective frequencies, and/or relatively large phase shift therebetween, such that a residual magnetic field permeating into the passenger cabin after cancellation is above the threshold level. Disclosed embodiments may thus include an amplifier having a sufficiently fast response time (e.g., within 15,000 microseconds, 1500 microseconds within 150 microseconds, or within 15 microseconds,) to cause any residual magnetic field permeating into the passenger cabin due to a mismatch between the cancelling magnetic field and the primary magnetic field to remain below a threshold level over time. For example, if a current for operating a vehicle component has a frequency of 1 kHz, a period cycle for the current may be 1000 microseconds. A response time for an amplifier within 100 microseconds, within 50 microseconds, or within 10 microseconds may result in a sufficiently small phase shift between a cancelling magnetic field and a primary (e.g., aggressor) magnetic field to maintain substantial alignment between the associated peaks and valleys to permit effective cancellation. An amplifier configured to generate a continuously varying cancellation refers to an amplifier wired to regularly (e.g., at regular intervals), continually and/or constantly receive a signal indicative of a continually varying current flowing in a wire cable, continually and/or constantly receive an input current and power for amplifying the input current to continually and/or constantly produce an output cancellation current matching the current flowing in the wire cable, as indicated by the received signal. This may additionally include the amplifier being arranged to continually and/or constantly receive feedback associated with the outputted cancellation current to permit continual adjustment of one or more amplification stages until the outputted cancellation current matches the current flowing through the wire cable, e.g., within a tolerance threshold. For instance, the amplifier may generate a cancellation current throughout an entire period during which a vehicle operates.

In some disclosed embodiments, the amplifier is set to produce a current matching the signal indicative of current running through the wire cable. A current matching a signal indicative of current running through a wire cable refers to a current having at least a substantially similar and/or equivalent amplitude as the amplitude attribute represented in the signal (e.g., the match being sufficient to reduce a radiation to below an acceptable threshold). For example, if an amplitude of an AC current flowing through a wire cable for vehicle operation is 100 A, an amplifier may receive a signal indicating the amplitude as 100 A. The amplifier may use the amplitude to produce an AC cancellation current having an amplitude of substantially 100 A (e.g., within a tolerance threshold). An amplifier set to produce a current matching a signal refers to an amplifier tuned, adjusted, calibrated, and/or connected in a manner to produce an output current having an amplitude substantially equivalent to an amplitude indicated in the signal. For example, an amplifier may include a feedback loop, such as a negative feedback loop for stabilizing gain and ensures accurate control of an output current. In some embodiments, a feedback loop of an amplifier may include a current-sensing resistor for regulating the output current and/or a biasing circuit to maintain the amplifier within a linear operating range. Producing a cancellation current matching the signal indicative of current running through the wire cable may result in a similar matching between a cancelling magnetic field and a primary magnetic field in a passenger cabin of a vehicle. Consequently, lines of the cancelling magnetic field current may be oriented in an opposite direction to lines of the primary magnetic field, while having substantially similar magnitude, frequency, phase, and/or spatial distribution. This may result in an at least partial cancellation of the primary magnetic field in the passenger cabin generated due to vehicle operation.

By way of a non-limiting example, in FIG. 4, system 400 may include a cancellation wire 408 running along at least a portion of wire cable 402. System 400 may include an amplifier 410 arranged to receive a signal 420 from sensor 406 indicative of current running through wire cable 402. For example, an input of amplifier 410 may be electrically connected to an output of current sensor 406 and/or may receive a signal wirelessly via one or more antenna. Signal 420 may indicate any of a voltage in V, a current in A, magnetic flux, a magnetic field, and/or any other indication of a current flowing through a wire cable. Amplifier 410 may additionally receive power from a power source 412. In some embodiments, amplifier 410 may receive an input current from power source 412 for amplifying based on the signal received from current sensor 406. Amplifier 410 may generate within 1500 microseconds from receiving signal 420 from current sensor 406, a cancellation current 416 for applying to cancellation wire 408. In some embodiments, amplifier 410 may include a feedback loop 418 to ensure that cancellation current 416 outputted by amplifier 410 substantially matches current 414 as indicated by signal 420 received from current sensor 406. In some embodiments, to ensure a response time within 1500 microseconds, amplifier 410 may be based wholly on analog technology that is cable of outputting cancellation current 416 in absence of analog-to-digital and/or digital-to-analog conversion. Cancellation wire 408 may be aligned substantially parallel to wire cable 402. Amplifier 410 may apply cancellation current 416 to flow in cancellation wire 408 in a direction opposite to the direction of current 414 flowing in wire cable 402. In some embodiments, in use, current 414 may be continuously varying, and cancellation current 416 generated by amplifier 410 may be continuously varying. For example, current 414 and cancellation current 416 may be AC currents that oscillate over time according to a frequency. Additionally or alternatively, current 414 and cancellation current 416 may vary as operation of vehicle 200 and/or vehicle 300 varies, e.g., due to acceleration, deceleration, and/or operation of one or more vehicular electrical systems (e.g., infotainment systems, climate control systems, lights, and/or one or more motors for operating mirrors and/or cameras). In some embodiments, amplifier 410 may be set to produce cancellation current 416 to match signal 420 indicative of current 414 running through wire cable 402. For instance, if current 414 is 60 A, signal 420 may indicate 60 A, and amplifier 410 may generate cancellation current 416 at 60 A to match signal 420, e.g., within a tolerance level.

In some disclosed embodiments, the cancellation wire includes a plurality of wire turns, and the amplifier is set to produce a current inversely proportional to the number of wire turns. A cancellation wire including a plurality of wire turns refers to a coiled, twisted, and/or solenoid shaped wire having multiple windings and/or loops arranged in a helical and/or cylindrical shape. A straight (e.g., non-coiled) wire carrying a specific current may generate a magnetic field around itself, with field lines forming circles around the wire. When a wire carrying the same specific current includes a plurality of wire turns, each turn or loop of the wire may produce its own magnetic field. The magnetic fields from each turn may interact by adding and/or summing up to produce an aggregate magnetic field that may be stronger than the magnetic field carried by the straight wire, despite both the coiled wire and the straight wire carrying the same specific current. Thus, a wire arranged in a plurality of wire turns may permit increasing a strength of a magnetic field without having to increase a current flowing through the wire. For instance, keeping a current constant, doubling a number of turns in a coil may approximately double the strength of the magnetic field. Similarly, a wire coil having N turns may increase the strength of the magnetic field by a factor of approximately N relative to a straight wire carrying the same current. The direction of a magnetic field produced by a wire coil may be determined using the ‘right hand rule’, i.e., curling the fingers of the right hand in the direction of the current flow through the coil will cause the thumb to point in the direction of the resultant magnetic field. Some arrangements for a plurality of wire turns may include a solenoid coil, a Helmholtz coil, a toroidal coil, and pancake coil.

Inversely proportional refers to a generally reciprocal relationship. Thus, a quantity inversely proportional to N may be 1/N (e.g., 1 divided by N). A current inversely proportional to the number of wire turns refers to a current having an amplitude that is reciprocal to the number of loops in a wire coil. Thus, if a first current is 100 A, a second current inversely proportional to N wire turns in a cancellation wire may be 100/N A. An amplifier set to produce a current inversely proportional to the number of wire turns refers to refers to an amplifier tuned, adjusted, and/or connected in a manner to produce an output current having an amplitude corresponding to a reciprocal of the number of wire turns. For example, an amplifier may include a feedback loop and/or a current-sensing resistor as described above, to produce an output current having an amplitude inversely proportional to the number of wire turns. For instance, if an amplitude of an AC current flowing through a wire cable for vehicle operation is 100 A, and a cancellation wire includes N turns, an amplifier receiving a signal indicating the amplitude of 100 A may produce an AC cancellation current having an amplitude of substantially 100/N A (e.g., within a tolerance threshold). The magnitude of a cancelling magnetic field generated by the 100/N A cancellation current may substantially match the magnitude of a primary magnetic field generated by the 100 Amp AC current. In this manner, the amplifier may output a substantially smaller current (e.g., by a factor of N) to generate a cancelling magnetic field capable of cancelling the primary magnetic field.

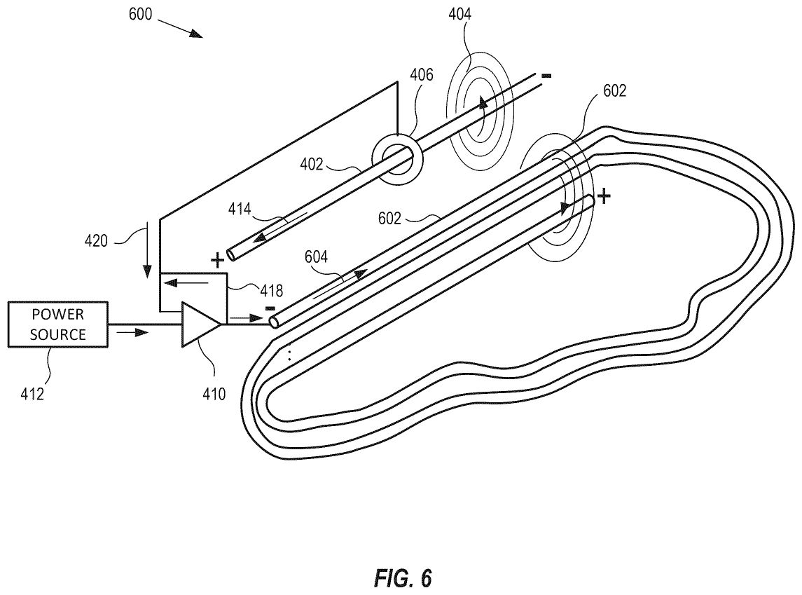

By way of a non-limiting example, reference is made to FIG. 6 illustrating another exemplary system 600 for protecting vehicle passengers from magnetic field radiation, consistent with some disclosed embodiments. System 600 is substantially similar to system 400 with the noted difference of a cancellation wire 602 having a plurality of wire turns. For instance, cancellation wire 602 may include multiple loops. Amplifier 410 may be set to produce a cancellation current 604 inversely proportional to the number of wire turns. For instance, if current 414 is 100 A, and cancellation wire 602 includes 100 wire turns, amplifier 410 may output 1 A to cancellation wire 602 as cancellation current 604. Each wire turn of cancellation wire 602 may generate a magnetic field, that may be combined (e.g., additively) such that the 100 wire turns of cancellation wire 602 may generate from the 1 A cancellation current a cancellation magnetic field substantially equal and opposite to primary magnetic field 404 generated by current 414. Although cancellation wire 602 is shown having only three wire turns, this is for illustrative purposes only, and cancellation wire may have any number of wire turns.

In some disclosed embodiments, the cancellation current is within 30% of the current passing through the wire cable in order to cause a cancelling magnetic field. Current passing through the wire cable refers to a flow of electric charge through the wire cable. To cause a cancelling magnetic field refers to generate and/or produce a magnetic field, that when combined with a different magnetic field at least partially eliminates the different magnetic field, resulting in a reduction in intensity (e.g., amplitude) of the different magnetic field. A cancellation current is within 30% of the current passing through the wire cable refers to a cancellation current outputted by an amplifier having an amplitude ranging between at least 70% and at most 130% of the amplitude of the current passing through the wire cable. For example, if the current passing through the wire cable is 1 A, the cancellation current may be between 0.7 A and 1.3 A. As noted, an amplifier may not produce a cancellation current that exactly matches a current flowing through the wire cable due to latencies, non-linear distortions, and/or additional factors contributing to a mismatch between the cancellation current and the current flowing through the wire cable. Disclosed embodiments for cancelling a magnetic field in a passenger cabin may tolerate some variability between the cancellation current and the current flowing through the wire cable. The tolerated variability may permit the cancellation current to be below or above the current flowing through the wire cable within a defined range of 30%. Permitting the cancellation current to be within 30% of the current passing through the wire cable may result in a cancelling magnetic field that is within 30% of the primary magnetic field. This may result in sufficient cancelation of the primary magnetic field such that any residual magnetic field propagating in the passenger cabin after cancellation remains below a threshold level. In some embodiments, the cancellation current is within any of 10%, 15%, 20%, 25%, 30%, 35%, 40%, 50%, 60%, 70%, or 80% of the current flowing through the wire cable. In some embodiments, any period of time during which the cancellation current may vary by more than 30% of the current flowing through the wire cable may be less than a regulatory time threshold. For instance, the regulatory time threshold may be associated with a permitted level of human exposure to magnetic and/or electromagnetic radiation. In some embodiments, the variation of the cancellation current from the current passing through the wire cable may vary over time, e.g., the cancellation current may vary within 5%, 10%, 15%, 20%, or 25% of the current in the wire cable at different time periods. However, overall the variation between the cancellation current and the current passing through the wire cable may remain within 30%. Some disclosed embodiments involve at least partially eliminating magnetic radiation from the wire cable to the passenger cabin. This may refer to reducing and/or diminishing an amplitude of a magnetic field surrounding a wire cable, such that any residual magnetic field surrounding the wire cable after the elimination that may permeate into the passenger cabin is below a threshold value.

By way of a non-limiting example, in FIG. 4, cancellation current 416 may be within 30% of current 414 passing through wire cable 402 in order to cause a cancelling magnetic field 422. Cancelling magnetic field 422 may thus have a magnitude within 30% of a magnitude of primary magnetic field 404 but may have field lines pointing in an opposite direction to the field lines of primary magnetic field 404. For instance, if cancelling magnetic field 422 is 30% less than primary magnetic field 404, a residual magnetic field that may remain to permeate into passenger cabin 224 after cancellation may be 30% of primary magnetic field 404 (e.g., cancelling magnetic field 422 may only cancel 70% of primary magnetic field 404). Conversely, if cancelling magnetic field 422 is 30% greater than primary magnetic field 404, a residual magnetic field that may remain to permeate into passenger cabin 224 after cancellation may be also 30% of primary magnetic field 404 (e.g., cancelling magnetic field 422 may cancel 100% of primary magnetic field 404, but another 30% of cancelling magnetic field 422 may remain and may permeate into passenger cabin 224). In some embodiments, cancellation current 416 may be within 10%, 15%, 20%, 25%, 30%, 35%, or 40% of current 414 passing through wire cable 402 in order to cause cancelling magnetic field 422.

Some disclosed embodiments involve ferromagnetic shielding material between the wire cable and the passenger cabin for attenuating the primary magnetic field radiating from the wire cable. Ferromagnetic shielding material may include substances capable of redirecting and/or containing magnetic fields. Such materials may have high magnetic permeability, allowing the materials to attract and channel magnetic field lines effectively. Some examples of ferromagnetic shielding materials include: Mu-Metal, Permalloy, soft iron, silicon steel, silicon steel GO (Grain Oriented), silicon steel NGO (Non Grain Oriented), electrical steel, transformer steel, ferrites, and/or Metglas. Mu-Metal refers to a nickel-iron alloy with high permeability. Permalloys refer to a group of nickel-iron alloys with high magnetic permeability. Soft Iron refers to low-carbon iron with high permeability and low coercivity. Silicon steel refers to a steel alloy containing silicon to reduce eddy currents. Ferrites refer to ceramic compounds composed of iron oxide mixed with other metals. Metglas (Amorphous Metal Alloys) refers to ultra-thin, high-permeability materials. Attenuating a primary magnetic field radiating from the wire cable refers to suppressing, deflecting, blocking, and/or otherwise weakening a magnetic field spreading from a wire cable due to a current passing through. Ferromagnetic shielding material between the wire cable and the passenger cabin refers to a layer of ferromagnetic material interposed between the wire cable and the passenger cabin to block and/or otherwise prevent at least some of a magnetic field radiating from the wire cable from penetrating into the passenger cabin. For example, the ferromagnetic shielding may absorb and/or deflect some of the magnetic field radiating from the wire cable. The ferromagnetic shielding may further reduce any residual magnetic radiation remaining after cancellation by the cancellation current. For example, if cancellation by a cancellation current reduces a primary magnetic field by 75%, leaving a residual magnetic field of 0.25 times the primary magnetic field, ferromagnetic shielding blocking 70% of the residual magnetic field may result in a remaining magnetic field radiating into the passenger cabin to be 17.5% times the primary magnetic field generated by the current flowing through the wire cable. In some embodiments, ferromagnetic shielding between the wire cable and the passenger cabin may compensate for one or more mismatches between the cancellation magnetic field and the primary magnetic field described above, to ensure that magnetic field radiation inside the passenger cabin remains below a threshold value. In some embodiments, cancellation if a primary magnetic field using a cancellation current flowing through a cancellation wire may permit maintaining magnetic radiation within the passenger cabin below a threshold value using less ferromagnetic shielding than would be possible absent the cancellation current flowing the cancellation wire. Use of less ferromagnetic shielding may reduce the weight of a vehicle, which may improve fuel efficiency while complying with regulations associated with magnetic field radiation within a passenger vehicle.

In some disclosed embodiments, the primary magnetic field is an electromagnetic field. Magnetic field radiation refers to the emission of varying magnetic fields, e.g., generated by an electric current flowing through a conductor. Magnetic field radiation may be more significant at lower frequencies (e.g., 50/60 Hz). Magnetic fields follow an inverse cube law proportional to one divided by the distance cubed (∝1/r³) and thus may decay rapidly with distance. When an AC flows at higher frequencies (e.g., suitable for radio transmission), the changing magnetic and electric fields may become coupled, and may form propagating electromagnetic waves. Electromagnetic waves may consist of perpendicular electric and magnetic fields traveling together at the speed of light, and may include radio, microwave, and optical signals. Thus, magnetic field radiation may be a relatively localized effect experienced at lower frequencies, whereas electromagnetic field radiation may be a propagating phenomenon occurring when electric and magnetic fields interact dynamically at higher frequencies. Rapid changes in current (e.g., due to a rapid change in the operation of a vehicle due to sudden braking, acceleration, deceleration, overheating) may cause one or more circuits to rapidly switch on/off. Such sudden changes may produce electromagnetic radiation as well. In addition, one or more mismatches in impedance, such as at the ends of one or more wire cables, at the connectors and/or terminators) may cause reflection of at least some electrical energy flowing through the wire cable, leading to standing electromagnetic waves and electromagnetic radiation. Generating, within 1500 microseconds, a cancellation current that substantially matches a current flowing through the wire cable for vehicle operation may permit generation of a canceling electromagnetic field substantially matching but opposite to an electromagnetic field generated by the current flowing in the wire cable. This may lead to substantial cancellation of the electromagnetic field, thereby preventing electromagnetic radiation from entering the passenger cabin.

By way of a non-limiting example, in FIG. 2A and FIG. 3, vehicle 200 and vehicle 300 may include ferromagnetic shielding material 240 between one or more of wire cables 216, 218, 238, and/or 230 and passenger cabin 224. Ferromagnetic shielding material 240 may attenuate primary magnetic field 220 from radiating from one or more of wire cables 216, 218, 238, and/or 230. By way of another non-limiting example, in FIG. 2B, vehicle 200 may include ferromagnetic shielding 240 between chassis 202 and passenger cabin 224. Vehicle may include additional a rear ferromagnetic shielding 242 between inverter 210 and motor 212 and passenger cabin 224 and/or a front ferromagnetic shielding 244 (e.g., when inverter 210 and motor 212 are located at the front of vehicle 200). Referring to FIG. 4, In some embodiments, primary magnetic field 404 may include an electromagnetic field, as described earlier. For instance, sudden acceleration, deceleration, and/or braking and/or overheating of vehicles 200 and/or 300, may cause a sudden change in an (e.g., AC) current flowing through any of wire cables 216, 218, 230, and 238 which may lead to electromagnetic radiation. Amplifier 410 may receive an indication of the sudden change in current 414 and produce, within 1500 microseconds of the change, cancellation current 416 substantially similar to, and flowing in an opposite direction to current 414. In other words, the sudden change in current 414 may lead to a similar sudden change in cancellation current 416. Consequently, cancellation current 416 may generate cancelling magnetic field 422 which may include a cancelling electromagnetic field capable of cancelling and/or significantly reducing the electromagnetic field included in magnetic field 404.

A wiring harness of a vehicle may generate a magnetic and/or electromagnetic field that may radiate into a passenger cabin during vehicle operation, potentially exposing vehicle passengers to harmful radiation. Embodiments are disclosed for a vehicle wiring assembly including magnetic field cancellation components for at least partially cancelling a magnetic field generated by a wiring harness, to thereby mitigate and/or reduce exposure of vehicle passengers to harmful magnetic and/or electromagnetic radiation during vehicle operation.

Some disclosed embodiments involve a vehicle wiring assembly having integrated magnetic field cancellation components associated therewith. A vehicle wiring assembly refers to an arrangement and/or collection of conductive filaments, cables, and/or wires for providing electrical power and/or control signals to one or more electrical components of a vehicle. Integrated refers to incorporated, built-in, fitted and/or included within something. A magnetic field cancellation component refers to an element and/or device capable of facilitating cancellation and/or reduction of an aggressor magnetic field caused by vehicle operation. For example, magnetic field cancellation components may include one or more conducting wires for carrying a cancellation current to generate a cancellation magnetic and/or electromagnetic field, one or more sensors for measuring indications associated with an aggressor magnetic and/or electromagnetic field (as described elsewhere herein), an amplifier, a feedback loop, a cancellation current source, a controller (e.g., a control unit) and/or any other component facilitating in cancelling an aggressor magnetic and/or electromagnetic field in a passenger cabin of a vehicle.

Some disclosed embodiments involve a vehicle wiring harness including a bundle of wires. A vehicle wiring harness (e.g., a cable loom) refers to a set of wires bundled together for supplying power and/or control signals to a plurality of electrical components in a vehicle. A vehicle wiring harness may replace multiple individual loose wires in a vehicle by bunding a plurality of individual wires together, for example by braiding multiple wires, and/or using electrical tape, a strap, a cable tie, a conduit, tube, sleeve, and/or other covering. Bundling a plurality of individual wires within a vehicle wiring harness may improve reliability, safety, and/or ease of installation and/or maintenance of one or more electrical systems in a vehicle, and may facilitate in protecting the wires from heat, vibration, moisture, and/or abrasion. A vehicle wiring harness may be arranged to run under a floor of a vehicle (e.g., an under-floor wire harness) and/or through a vehicle body (e.g., a body harness), on either side of a vehicle chassis and/or frame, and may extend into a vehicle trunk. At least some wires of a vehicle wiring harness may connect at first ends thereof to a current, voltage, and/or power supply (e.g., via one or more charging ports) and at second ends thereof to a plurality of electrical vehicle components. Wires in a vehicle wiring harness may be used to transmit and/or receive electrical power in association with operating one or more lights, sensors (e.g., temperature, voltage, current, power, magnetic and/or electromagnetic field sensors, cameras, ultrasound, lidar, and/or radar sensors), dashboard instruments, an infotainment system, a climate control system, power steering, (e.g., regenerative) braking, locks, windows, doors, motors, batteries, inverters, capacitors, inductors, transformers, alternators, engines, and/or any other component of a vehicle associated with a flow of electric current. In some embodiments, a vehicle may include a plurality of vehicle wiring harnesses, such as separate wiring harnesses for one or more of a motor, a battery pack, a vehicle fast charger, and/or a regenerative braking system, each associated with differing current and/or voltage level. In some instances, all control of an electrical vehicle may be communicated through one or more vehicle wiring harnesses (e.g., replacing hydraulic and/or mechanical linkages). A vehicle wiring harness may be configured to carry higher current and/or voltages (e.g., corresponding to tens or hundreds of kilowatts) and may handle higher temperatures (e.g., up to 125° C. or 150° C.) and/or temperatures rises, lower voltage ranges (e.g., up to 48V for powering one or more vehicle lights, locks, an infotainment system, dashboard instruments, one or more sensors and/or cameras, processors), intermediate current and/or voltages, and/or any combination of higher, lower, and/or intermediate currents and/or voltages. In some embodiments, a vehicle may include a plurality of wiring harnesses, each dedicated and/or rated for differing ranges of voltages and/or currents. A bundle of wires refers to a collection, sheaf, and/or package of conductive wires (as described elsewhere herein) included in a vehicle wiring harness. Each wire in a bundle may be encased in an insulating coating and/or sheathing, and may be color coded based on use, current and/or voltage rating, type, and/or application. A bundle of wires may be used to deliver power and/or control signals to a plurality of electrical components in a vehicle. In some embodiments, each wire in a bundle may be associated with a different electrical component of a vehicle. In some embodiments, some wires in a bundle of wires may be associated with the same electrical component. For example, a first wire in a bundle may deliver control signals to a vehicle component (e.g., a climate control system) and a second wire in the bundle may deliver electrical power to the vehicle component.

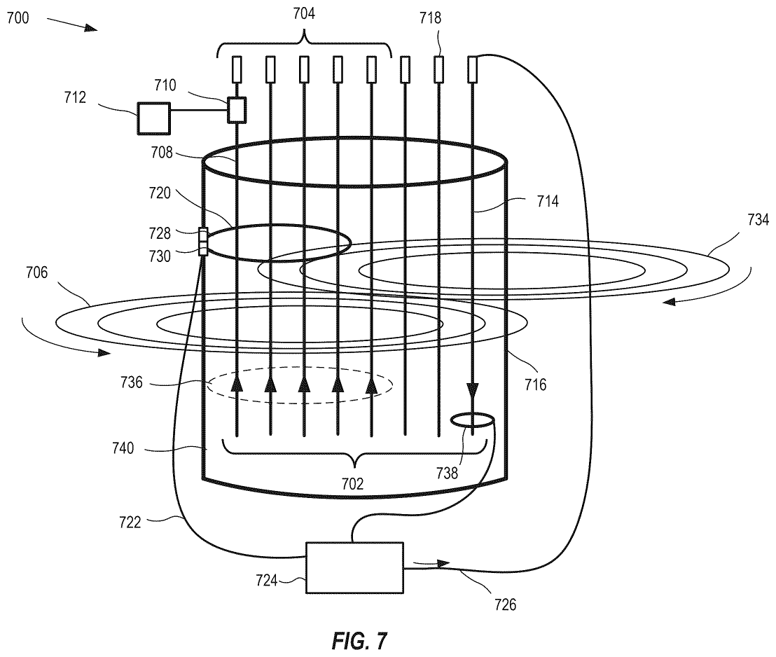

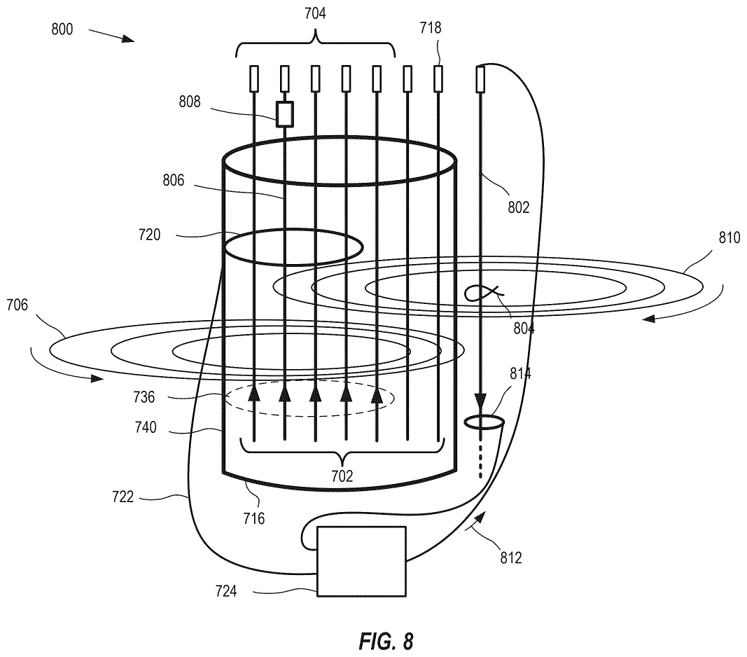

By way of a non-limiting example, reference is made to FIG. 7 illustrating a vehicle wiring assembly 700 having integrated magnetic field cancellation components, consistent with some disclosed embodiments. Vehicle wiring assembly 700 may include a vehicle wiring harness 740 including a bundle of wires 702, and at least one dedicated wire 714 included within bundle of wires 702. By way of a non-limiting example, reference is made to FIG. 8 illustrating vehicle wiring assembly 800 having integrated magnetic field cancellation components, consistent with some disclosed embodiments. Vehicle wiring assembly 800 may include vehicle wiring harness 740 including bundle of wires 702, and a dedicated wire 802 external (e.g., in addition) to bundle of wires 702 of vehicle wiring harness 740. For example, dedicated wire 802 may be fastened to vehicle wiring harness 740 using one or more fasteners 804.

In some embodiments, at least some wires of bundle of wires 702 may include wires for carrying AC current. at least some wires of bundle of wires 702 may include wires for carrying DC current, and at least some wires of bundle of wires 702 may include wires for carrying AC or DC current. In some embodiments, bundle of wires 702 may be rated for a specific voltage and/or current range. For instance, bundle of wires 702 may be rated for higher voltage ranges, such as up to 400V, up to 800V, up to 1200V, or more than 1200V, e.g., associated with a vehicle motor (e.g., motor 212 in FIG. 2), a battery pack (e.g., battery pack 206) and/or additional electrical components associated with higher voltages and/or higher currents (e.g., one or more inverters, rectifiers, capacitors, and/or inductors). Alternatively, bundle of wires 702 may be rated for lower voltage ranges, e.g., up to 48V for powering one or more vehicle lights, locks, an infotainment system, dashboard instruments, one or more sensors and/or cameras, processors, and/or any other lower voltage device and/or accessory in a vehicle. In some embodiments, some wires in bundle of wires 702 may be rated for higher voltages and/or currents and some wires in bundle of wires 702 may be rated for lower voltages and/or currents.

Some disclosed embodiments involve fasteners for securing the wiring harness to a body of the vehicle at predefined locations associated with the region of the passenger cabin of the vehicle. A fastener refers to a device for joining, connecting, affixing, and/or attaching two objects together. Securing may include binding, tying, and/or tethering, e.g., to prevent misalignment and/or displacement. A body of a vehicle may include a one or more of chassis, a frame, a door, a panel (e.g., a hood, a fender, a trunk), a roof, a floor, and/or any other structural element of a vehicle. Fasteners for securing a wiring harness to a body of a vehicle may include one or more clamps, clips, tape, tie wraps, string, wires, cables, and/or any other device capable of fastening a wiring harness to a body of a vehicle. Predefined locations associated with a region of a passenger cabin of a vehicle refers to locations, e.g., determined in advance, and corresponding to a location in the passenger cabin. For example, fasteners may secure a wiring harness to a vehicle chassis under a passenger seat, a floor space, and/or a trunk of a vehicle potentially exposing vehicle passengers to an aggressor magnetic field.

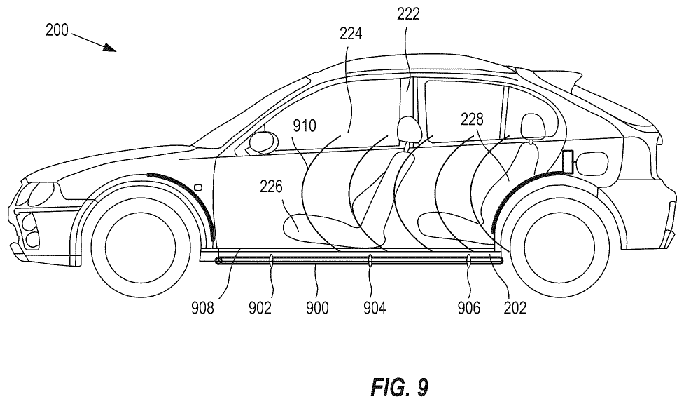

By way of a non-limiting example, reference is made to FIG. 9 illustrating a wiring harness 900 fastened to a body of vehicle 200 of FIG. 2, consistent with some disclosed embodiments. Wiring harness 900 may correspond to wiring harness 740 of FIGS. 7 and 8, respectively. Vehicle 200 may include a body 908, which may include one or more of chassis 202, frame 222, and/or any other structural part of vehicle 200. Fasteners 902, 904, and 906 may secure wiring harness 900 to body 908 of vehicle 200 at predefined locations associated with a region of passenger cabin 224 of vehicle 200. For example, fastener 902 may secure wiring harness 900 to chassis 202 at a first location under a footrest region by front seat 226, fastener 904 may secure wiring harness 900 to chassis 202 at a second location beneath front seat 226, and fastener 906 may secure wiring harness 900 to chassis 202 at a third location beneath rear seat 228. The securing of wiring harness 900 to chassis 202 below passenger cabin 224 may permit an aggressor magnetic field 910 generated by current flowing through one or more wires of wiring harness 900 to permeate into passenger cabin 224 and potentially expose passengers (e.g., sitting in front seat 226 and/or rear seat 228) to an aggressor magnetic field.

In some disclosed embodiments, at least some of the bundle of wires are aggressor wires configured such that when in use, the aggressor wires carry sufficient aggregate current to cause, in an absence of mitigation, a wiring harness-induced aggressor magnetic field of greater than a threshold level in a region of a passenger cabin of an associated vehicle. An aggressor wire refers to a conductive filament, cable, and/or wire delegated and/or designated to carry a current associated with operating one or more electrical components of a vehicle. Current flowing through the aggressor wire during vehicle operation may generate an aggressor magnetic field (potentially harmful and/or unsafe for humans, as described elsewhere herein). When in use refers to while current is flowing. For example, during vehicle operation, current may flow through one or more wires to operate one or more electrically controlled features. The flow of current through the one or more wires may generate a magnetic (and/or electromagnetic) field as a side effect. To carry (e.g., current) refers to conduct, convey, and/or transmit. An aggregate current is potentially harmful and/or unsafe for humans. An aggressor current may include a cumulative, combined, and/or collective current. An aggregate current may include a sum of currents and/or net current flowing in a plurality of individual wires, such as a bundle of wires included in a wiring harness. In some embodiments, an aggregate current may refer only to a net aggressor current flowing through a plurality of aggressor wires in a bundle of wires of a wiring harness (e.g., absent one or more cancellation currents flowing through one or more dedicated wires). In some embodiments, an aggregate current may only (e.g., exclusively) include current flowing through a single wire in association with a single (e.g., exclusive) electrical component. In some embodiments, an aggregate current may include a plurality of currents flowing through a plurality of wires for operating a plurality of different electrically operated components, and/or for operating a single electrically operated component. For example, an aggregate current may include a first current (e.g., a first power signal) for powering a first electrical component and a second current (e.g., a second power signal) for powering a second electrical component. In some embodiments an aggregate current may include a net current flowing through one or more aggressor wires and through one or more wires dedicated for carrying a cancellation current. A wiring harness-induced aggressor magnetic field refers to an aggressor magnetic field generated by an aggregate current flowing through one or more wires in a bundle of wires of a wire harness. A wiring harness-induced aggressor magnetic field may include a net and/or total aggressor magnetic field generated by a net and/or total current flowing through at least one wire included in a bundle of wires in the wiring harness. In some embodiments, a wiring harness-induces aggressor magnetic field only includes aggressor magnetic field components generated by current flowing through a plurality of aggressor wires in a bundle of wires of a wiring harness (e.g., absent any cancelling magnetic field components generated by one or more cancellation currents flowing through one or more dedicated wires). A threshold level may be understood as described elsewhere herein. A wiring harness-induced aggressor magnetic field of greater than a threshold level refers to an aggressor magnetic field generated by an aggregate (e.g., aggressor) current flowing through a wiring harness that exceeds and/or surpasses a threshold level. For example, the threshold level may be associated with a level of magnetic radiation considered safe for human exposure, such that human exposure to a wiring harness-induced aggressor magnetic field greater than the threshold level may pose a risk to human health. A region of a passenger cabin of a vehicle refers to an area, zone, and/or space inside the passenger cabin of the vehicle (as described elsewhere herein) where human passengers may reside. Mitigation and/or mitigating refers to reducing, relieving, and/or alleviating severity of one or more risks and/or harms. Mitigation and/or mitigating may include preventing, thwarting, and/or reducing something potentially harmful. Absence of mitigation refers to a lack and/or deficiency of mitigation. For example, absence of mitigation may include omission and/or lack of actions and/or operations for cancelling an aggressor magnetic field, leading to potential exposure to one or more associated risks and/or harms. Sufficient refers to adequate, and/or capable of meeting one or more levels and/or thresholds. To cause refers to making something happen or bringing about a result, either directly or indirectly. For example, causing may involve triggering, leading to, resulting in, producing, inducing, actuating, initiating, and/or generating. It is to be noted that “sufficient to cause” does not necessarily mean that an aggressor field ever exists in the vehicle, rather, “sufficient to cause” may be understood to mean that in the absence of mitigation, an above-threshold aggressor magnetic field may exist. For instance, to determine whether the aggressor wires carry sufficient aggregate current to cause an above threshold aggressor magnetic field in a passenger cabin of a vehicle, the cancellation circuit may be deactivated during a test, and the magnetic field in the cabin may be sensed using a magnetometer and/or a gaussmeter. Thus, absent a mechanism and/or method to maintain an aggressor magnetic field induced by a wiring harness below a threshold level, current (e.g., an aggregate aggressor current) flowing through a wiring harness may expose vehicle passengers to potentially hazardous levels of magnetic and/or electromagnetic radiation. Conversely, providing a mechanism and/or method to mitigate an aggressor magnetic field generated by a (e.g., an aggregate aggressor) current flowing through wiring harness from exceeding a threshold level may prevent vehicle passengers from being exposed to potentially hazardous levels of magnetic and/or electromagnetic radiation.

In some disclosed embodiments, the threshold level is associated with a basic restriction of a recognized guideline. A basic restriction refers to a fundamental limit associated with one or more established health effects, and may include a baseline, standard, and/or benchmark. A basic restriction may be associated with one or more bodily harms caused by exposure to an above threshold level magnetic and/or electromagnetic field. A basic restriction may be associated with field intensity and/or exposure time. For instance, longer exposure times may be permitted for lower field intensities, whereas higher field intensities may require shorter exposure times to remain with a reference level of a recognized guideline. A recognized guideline refers to an accepted standard and/or recommendation. A recognized guideline may be associated with a governing and/or regulatory body, and may be based on one or more studies and/or measurements. By way of example only, ICNIRP 1998, ICNIRP 2010, IEEE C95.1-2019, and/or EU Directive 2013/35/EU, published guidelines for electromagnetic radiation exposure. A recognized guideline may have consensus among a majority of experts. In some disclosed embodiments, the threshold level is associated with a reference level of a recognized guideline. A reference level associated with a recognized guideline refers to a limit for ensuring compliance with a basic restriction. A reference level may be based on a basic restriction such that compliance with a reference level may ensure compliance with a basic restriction. For example, a threshold level may be associated with one or more guidelines published by the International Commission on Non-Ionized Radiation Protection (ICNIRP) for limiting exposure to time-varying electric, magnetic, and electromagnetic fields. In some disclosed embodiment, the threshold level is 1 mG. One milli Gauss refers to one thousandth of a Gauss. Thus, exposure to magnetic radiation cause by current flowing through a wiring harness may be limited to one thousandth of a Gauss (e.g., for a given time period).

By way of a non-limiting example, in FIGS. 7 and 8, at least some wires of bundle of wires 702 may be aggressor wires 704. When in use, aggressor wires 704 may carry sufficient aggregate current 736 to cause, in an absence of mitigation, a wiring harness-induced aggressor magnetic field 706. For example, aggressor wires 704 may be associated with one or more of battery pack 206, inverter 210, motor 212, alternator 304, and/or motor 306 shown in FIG. 2 and FIG. 3. In some embodiments, aggressor wires 704 may be associated with one or more of wire cable 216, wire cable 218, and/or wire cable 308. Additionally or alternatively, aggressor wires 704 may be associated with one or more of an infotainment system, lights, climate control system, power steering system, braking system, doors, windows, locks, windshield wipers, sensors, and/or any other electronically controlled features of vehicle 200.

By way of another non-limiting example, in FIG. 9, when in use, aggressor wires 704 included in wiring harness 900 (corresponding to wiring harness 740) may carry sufficient aggregate current to cause, in an absence of mitigation, a wiring harness-induced aggressor magnetic field 910 (corresponding to wiring harness-induced aggressor magnetic field 706) of greater than a threshold level in a region of passenger cabin 224 of vehicle 200. In some disclosed embodiments, the threshold level is associated with a basic restriction and/or reference of a recognized guideline, such as the ICNIRP (1998), ICNIRP (2010), and/or ICNIRP (2020) guidelines for protection against adverse health effects from exposure arising from radio frequency (RF) and electromagnetic field (EMF)-emitting technologies.

In some disclosed embodiments, the bundle of wires includes at least one of a fuse or relay integrated therein A fuse refers to an electrical device that interrupts a flow of electricity in a circuit when the current exceeds a threshold level (e.g., associated with safety). A fuse may be designed to break an electrical connection when a current exceeding a safety threshold is detected to prevent damage to electrical components and/or potential hazards such as fires. A fuse may be associated with an aggressor wire and/or a wire dedicated to carrying a cancellation current (e.g., a wire other than an aggressor wire), and/or any other wire associated with a wiring harness. A relay refers to an electrically controlled switch for opening and/or closing a circuit. A relay may receive a smaller control signal to control the flow of a larger signal, permitting control of a higher-power circuit using a lower-power signal. Operation of one or more fuses and/or relays may generate and/or affect a magnetic and/or electromagnetic field. For example, a fuse and/or relay may break a flow of current when an associated magnetic and/or electromagnetic field exceeds a threshold level.

By way of a non-limiting example, in FIG. 7, bundle of wires 702 may include a wire 708 connected to a relay 710. For example, relay 710 may receive a signal from a sensor 712 to control a flow of current through wire 708. By way of another non-limiting example, in FIG. 8, bundle of wires 702 may include a wire 806 connected to a fuse 808 for stopping a flow of current through wire 806 when a current threshold is reached. By controlling and/or stopping current flowing through wires 708 and/or 806, relay 710 and/or fuse 808 may influence aggressor magnetic field 706.

Some disclosed embodiments involve at least one of a wire loom or sleeve for protecting and organizing the wires within the bundle. A wire loom or sleeve refers to tube and/or conduit for encasing a plurality of wires. A wire loom or sleeve may facilitate in organizing and/or protecting a plurality of wires from damage by preventing the encased wires from being crushed, frayed, and/or cut by vehicle components and/or due to vehicle motion. In some embodiments, a vehicle may include a plurality of wire looms of sleeves to organize differing groups of wires (e.g., for a plurality of wiring harnesses), each group associated with a differing set of features and/or voltage and/or current ratings for vehicle operation. A wire loom or sleeve may be made of flexible durable material such as polyethylene, rubber, polypropylene (PP), fiberglass, and/or vinyl.

By way of a non-limiting example, in FIGS. 7 and 8, vehicle wiring assembly 700 and vehicle wiring assembly 800 may include a sleeve 716 for protecting and organizing the wires within bundle of wires 702. Sleeve 716 may be made of flexible polyethylene material.

Some disclosed embodiments involve a plurality of connectors on ends of the wires in the bundle. A connector refers to a component for providing a physical and electrical connection between two or more sections of an electrical circuit. A connector may permit an electric current to flow between differing sections of a circuit, and may be used to connect two wires and/or cables, and/or to connect one or more wires and/or cables to an electronic device. Examples of connectors include multi-pin connectors for joining multiple wires in one compact housing. (e.g., Delphi GT, TE AMPSEAL, AMP Superseal, TE Connectivity, Molex MX150/500, Yazaki, Sumitomo); coaxial connectors (e.g., FAKRA, HSD); and weather sealed connectors (e.g., Deutsch DT series, Metri-Pack, Weather Pac); Other connector examples include plug or socket, crimp, blade/spade, bullet, inline/butt, ring/fork, OEM, or custom. In some electric vehicles and/or hybrid vehicles, a connector may protect against electromagnetic interference (EMI) and ensure safety. In some embodiments, a connector may be rated to handle higher voltages, such as at least 60 V, at least 400 V, at least 600 V, or at least 1000 V. For instance, a high voltage connector may be used to connect a wire in a wiring harness to one or more of a battery pack, a inverter, a motor, a transformer, and/or an onboard charger. In some embodiments, a connector may include a charging and/or high-speed charging connector (e.g., CCS Combo, CHAdeMO, GB/T), e.g., for connecting one or more wire in a wiring harness to a battery and/or fast charger. A connector may conform with one or more standards, such as TE Connectivity HV, Aptiv High-Voltage Systems, Yazaki YESC, Rosenberger HVS series. In some embodiments, a connector may be rated to handle lower voltages, such as at most 5 V, at most 12 V, or at most 48 V. For instance, a low voltage connector may be used to connect a wire in a wiring harness to one or more of a control unit, a light, a lock, an infotainment system, a climate control system, a power steering system, a power and/or regenerative brake system, windshield wipers, and/or any other electrical component in a vehicle. A connector may be resistant to high temperatures (e.g., up to a threshold level), vibrations, and/or thermal cycling, and may seal an electrical connection from, chemicals, moisture, salt, and/or other environmental conditions. A plurality of connectors on ends of the wires in the bundle refers to at least some wires in a wiring harness being fitted with connectors on at least one end thereof to permit connection to additional wires and/or devices. Wires in a wiring harness rated for higher voltages may be fitted with connectors rated for higher voltages, and wires in the wiring harness rated for lower voltages may be fitted with connectors rated for lower voltages.

In some disclosed embodiments, the plurality of connectors are configured for connecting at least some of the wires in the bundle to electrical components of the vehicle. Electrical components of a vehicle may include one or more of a motor, a battery, an inverter, a rectifier, a transformer, a light, a lock, a climate control system, an infotainment system, a steering system, a braking system, a windshield wiper system, a sensory system (e.g., including one of more of a camera, a microphone, a lidar sensor, a radar sensor, an ultrasound sensor, and/or any other type of sensor), a seat adjustment system, and/or any other element and/or component in a vehicle powered by electrical energy, as described elsewhere herein. A plurality of connectors configured for connecting at least some wires in the bundle to electrical components of a vehicle refers to connectors fitted on at least some of the wires in a wiring harness to permit delivery or conveyance of electrical current flowing through the at least some wires to one or more electrically powered vehicle components. Connectors may connect to ends of wires by inserting stripped ends of the wires into the connectors and securing the ends within the connectors by one or more of crimping the wire ends, heat shrinking the connectors on each wire, using a wire nut, and/or using a screw terminal.

In some disclosed embodiments, the connectors include terminals on the ends of at least some of the wires in the bundle. A terminal (e.g., an electric terminal) refers to an end point of a conducting element and/or an electrical connector. A terminal on an end of a wire may permit electrical connection of the wire to another electronic component and/or circuit. A terminal may be a special type of connector for connecting a wire to a particular element (e.g., a power source and/or a particular piece of equipment and/or circuit). Some example of terminals may include a terminal block, a ring terminal, and a space terminal. In some embodiments, terminals may be used for input/output connections to one or more power source, whereas connectors may be used for additional purposes, such as signal transmission.

By way of a non-limiting example, in FIGS. 7 and 8, vehicle wiring assembly 700 and vehicle wiring assembly 800 may include a plurality of connectors 718 on ends of the wires in bundle of wires 702. Plurality of connectors 718 may connect at least some of the wires in bundle of wires 702 to electrical components of vehicle 200, such as to one or more of battery pack 206, inverter 210, motor 212, alternator 304, and/or motor 306, shown in FIG. 2 and FIG. 3. In some embodiments, at least some of connectors 718 may include terminals on the ends of the wires in bundle of wires 702.

Some disclosed embodiments involve a current sensing probe integrated with the vehicle wiring harness. A current sensing probe refers to a device that detects and/or measures the flow of electric current through a conductor, as described elsewhere herein. A current sensing probe integrated with a vehicle wiring harness may be understood as a current sensing probe connected to affixed to, or otherwise associated with a vehicle wiring harness. A current sensing probe may be integrated to a vehicle wiring harness using an electrically conductive connection (e.g., via soldering and/or an electrically conductive wire connector) and/or using a mechanical connection, such as a clamp, bracket, clasp, tape, wire, and/or tie. In some embodiments, a current sensing probe may include a loop that surrounds a bundle of wires. The loop may be embedded in a clamp or sleeve. Additionally or alternatively, a current sensing probe may be inserted into an opening of a sleeve for a wiring harness for connection to one or more wires encased inside.

In some disclosed embodiments, the current sensing probe is associated with the bundle of wires in a manner enabling the current sensing probe, when in use, to sense at least a portion of the aggregate current. To sense at least a portion of the aggregate current refers to detecting, sampling, and/or measuring at least some of the aggregate current. In some embodiments, at least a portion of an aggregate current includes a current flowing through a particular wire in a wiring harness and may exclude currents flowing through wires other than the particular wire. In some embodiments, a current sensing probe may sense all currents flowing through a wiring harness (e.g., including current flowing through a plurality of aggressor wires and/or one or more cancellation currents flowing through one or more dedicated wires). In some embodiments, a current sensing probe may sense current flowing through a select subset of wires in a wiring harness (e.g., only sense aggressor currents flowing through the aggressor wires). A current sensing probe associated with bundle of wires in a manner enabling the current sensing probe, when in use, to sense the aggregate current may be understood to mean a current sensing probe arranged with a bundle of wires such that while current flows through at least one wire in a wiring harness, the current sensing probe may measure a net current and/or sum of the current passing through at least some of the wires in the wiring harness. In some embodiments, an aggregate current measured by a current sensing probe may include only current flowing through aggressor wires and associated with an aggressor magnetic field. In some embodiments, an aggregate current measured by a current sensing probe may include a cancellation current flowing opposite to one or more currents flowing though aggressor wires of a wiring harness. In some embodiments, an aggregate current measured by a current sensing probe may include a cancellation current combined with current flowing through one or more aggressor wires, such that the cancellation current cancels at least some of the current flowing through the aggressor wires.

Some disclosed embodiments involve a magnetic field sensor integrated with the vehicle wiring harness. A magnetic field sensor refers to a device for detecting and/or measuring a magnitude of a magnetic field. A magnetic field sensor may convert variations in a magnetic field to electrical signals for analysis, e.g., based on principles of electromagnetic induction and/or the Hall effect. Some types of magnetic field sensors may include a Hall effect sensor, a magneto resistive (MR) sensor, a fluxgate magnetometer, and/or an inductive magnetometer. In some embodiments, a current and/or voltage sensor may be used to measure a magnetic field. A measurement of an aggressor magnetic field by a magnetic field sensor may be used to determine a cancelation current for generating a cancelling magnetic field capable of mitigating exposure to above-threshold levels of magnetic radiation in a passenger cabin of a vehicle.

Some disclosed embodiments involve a temperature sensor integrated with the vehicle wiring harness. A temperature sensor refers to a device for detecting and/or measuring average kinetic energy (e.g., heat). Some examples of temperature sensors may include thermocouples, resistance temperature detectors (RTDs), thermometers, infrared sensors, and/or negative temperature coefficient (NTC) thermistors. A temperature sensor may be used to identify one or more malfunctions in a vehicle due to overheating.

In some disclosed embodiments, the current sensing probe has at least one output wire configured for electrical connection to an electronic control unit. In some embodiments, the at least one output wire may include two, three, four, and/or five wires. A current sensing probe having an output wire refers to a wire associated with the current sensing probe for transmitting an electric signal indicative of a measurement made by the current sensing probe. An electronic control unit may be understood as described elsewhere herein. Thus, the current sensing probe may transmit one or more signals indicative of aggregate current sensed by the current sensing probe to an electronic control unit via an output wire.

Some disclosed embodiments involve an electronic control unit for determining a cancellation current sufficient to mitigate causation of at least a portion of the wiring harness-induced aggressor magnetic field in the region of the passenger cabin of the vehicle. A cancellation current refers to a current capable of generating a cancelling magnetic field for cancelling or at least significantly reducing another (e.g., aggressor) magnetic field, as described elsewhere herein. For example, an electronic control unit may receive an indication of aggregate current flowing through a wiring harness of a vehicle and capable of generating an aggressor magnetic field that may radiate into a passenger cabin of a vehicle. The electronic control unit may use the indication to output a cancellation current capable of generating a cancelling magnetic field for annihilating at least some of the aggressor magnetic field, to prevent at least some of the aggressor magnetic field from radiating into a passenger cabin. In some embodiments, an electronic control unit may be calibrated and/or adjusted to annihilate a sufficient amount of an aggressor magnetic field such that any remaining aggressor magnetic field remains below a threshold level, thereby mitigating an aggressor magnetic field of greater than a threshold level in a region of a passenger cabin. The cancellation current may thus reduce exposure of passengers in the passenger cabin to harmful magnetic field radiation. Sufficient to mitigate causation refers to adequate and/or capable of preventing and/or thwarting generation and/or actuation of something. At least a portion of a wiring harness-induced aggressor magnetic field in a region of a passenger cabin of the vehicle refers to at least some of a magnetic field generated by a wiring harness entering a region of the passenger cabin of the vehicle. In some embodiments, at least a portion of a wiring harness-induced aggressor magnetic field is at least 10 G (micro Gauss), at least 15 μG, at least 20 μG, at least 25 μG, at least 30 μG, at least 35 μG, at least 40 G, at least 45 μG, or at least 50 G. In some embodiments, a portion of a wiring harness-induced magnetic field is at least 0.5 milliGauss (mG), at least 1 mG, at least 5 mG, at least 10 mG, at least 20 mG, or at least 100 mG. Thus, a current sensing probe may sense an aggregate current flowing through a wire harness and causing an aggressor magnetic field capable of entering a passenger cabin of a vehicle. The current sensing probe may send a signal indicative of the aggregate current to a control unit. The control unit may use the signal to output a cancellation current capable of generating another magnetic field opposite to the aggressor magnetic field, to cancel at least some of the aggressor magnetic field and thereby prevent the cancelled portion of the aggressor magnetic field from entering the passenger cabin.

In some disclosed embodiments, at least one wire in the bundle of wires forms a plurality of wire turns through the current sensing probe. A plurality of wire turns refers to a wire that is coiled, twisted, and/or arranged in a helical, cylindrical or solenoid shape. Such a wire may have multiple windings and/or loops, as described elsewhere herein. A wire forming a plurality of wire turns through a current sensing probe refers to a wire wound multiple times around or within a current sensing probe, for enabling the current sensing probe to measure a current flowing the wire a plurality of times (e.g., proportional to the number of turns). For instance, if a wire is wound twice around a current sensing probe, the current sensing probe may measure double the current flowing through the wire. A wire forming a plurality of wire turns through a current sensing probe may include an aggressor wire and/or a wire other than an aggressor wire (e.g., a wire dedicated to carry a cancellation current). However, in situations where it may be desirable to output a cancellation current that is lower than an aggregate aggressor current (e.g., three-quarters, four-fifths), looping at least one dedicated wire and/or an aggressor wire around a current sensor multiple times may enable the amplifier to output any fraction of an aggressor current as a cancellation current. For instance, optimal cancellation may involve outputting a cancellation current substantially matching an aggregate aggressor current. However, in some situations optimal cancellation may be unnecessary and may consume more power than needed. For example it may be sufficient to cancel three quarters of an aggressor magnetic field to ensure that any remaining aggressor magnetic field in a passenger cabin remains under a threshold level. Winding an aggressor wire M times around the current sensor such that the control unit receives a reading of an aggressor current M-fold greater than an actual aggressor current and winding a dedicated wire (e.g., for a cancellation current) N times around a current sensor (e.g., the same or different current sensor) such that the control unit receives a reading for a cancellation current N-fold greater than an actual cancellation current may enable the control unit and/or amplifier to output a cancellation current that is M/N times the aggressor current. For example, winding an aggressor wire three times around a current sensor and winding a dedicated wire dedicated to carrying a cancellation current four times around a current sensor, and transmitting the current sensor readings to an amplifier and/or control unit may enable the amplifier to output a cancellation current that is three quarters (¾) the aggressor current.

By way of a non-limiting example, in FIG. 7, vehicle wiring assembly 700 may include a current sensing probe 720 integrated with vehicle wiring harness 740. Current sensing probe 720 may be inserted inside an opening of sleeve 716 of vehicle wiring harness 740 and/or may be affixed to vehicle wiring harness 740 using one or more clips, tape, and/or fasteners. Current sensing probe 720 may correspond to any of sensors 500, 502, 504, 506, and/or 508 shown in FIG. 5. Current sensing probe 720 may be associated with at least some wires of bundle of wires 702 in a manner enabling current sensing probe 720, when in use, to sense at least a portion of the aggregate current flowing through bundle of wires 702. In the example show, current sensing probe 720 is arranged to sense current flowing through only some of the aggressor wires 704 of bundle of wires 702. In some embodiments, current sensing probe 720 may be arranged to sense current flowing through all of the wires of bundle of wires 702. In some embodiments, current sensing probe 720 may be arranged to sense current flowing only through one or more, or all of aggressor wires 704 of bundle of wires 702. In some embodiments, current sensing probe 720 and/or a current sensing probe 738 may be arranged to sense current flowing through at least one dedicated wire 714 of bundle of wires 702. Current sensing probe 720 may have an output wire 722 electrically connected to an electronic control unit 724 for determining a cancellation current 726 sufficient to mitigate causation of at least a portion of wiring harness-induced aggressor magnetic field 706 (corresponding to aggressor magnetic field 910) in the region of the passenger cabin 224 of vehicle 200 (see FIG. 9). For example, control unit 724 may output cancellation current 812 substantially matching aggregate current 736 (e.g., for optimal cancellation) and/or as a fraction of aggregate current 736 (e.g., partial cancellation).

Electronic control unit 724 may include at least an amplifier (e.g., amplifier 410 in FIG. 4), and may connect to a power source (e.g., power source 412). In some embodiments, electronic control unit 724 may include a feedback loop (e.g., feedback loop 418). In some embodiments, electronic control unit 724 may include at least one processor (e.g., processor 102 in FIG. 1), however this is not required. In some embodiments, vehicle wiring assembly 700 may include a magnetic field sensor 728 and/or a temperature sensor 730 integrated therewith. For example, magnetic field sensor 728 and/or temperature sensor 730 may transmit signals indicative of wiring harness-induced aggressor magnetic field 706 and/or a temperature within wiring harness 740 to control unit 724 and/or at least one processor (e.g., processor 102 in FIG. 1), e.g., to adjust cancellation current 726. By way of another non-limiting example, in FIG. 5, at least one wire 512 may correspond to one or more of aggressor wires 704 and/or at least one dedicated wire 714 included in bundle of wires 702, and may form a plurality of wire turns through inductance sensor 504 (e.g., a current sensing probe corresponding to current sensor 720 and/or current sensor 738). Wire 510 may be an aggressor wire or a dedicated wire for carrying a cancellation current.

In FIG. 8, vehicle wiring assembly 800 may include current sensing probe 720 integrated with vehicle wiring harness 740. In some embodiments, at least one dedicated wire 802 may be associated with an additional current sensing probe 814 having an additional output wire 816 connected to control unit 724, permitting control unit 724 to determine an actual cancellation current flowing through at least one dedicated wire 802. In some embodiments, dedicated wire 802 may be wound around current sensing probe 814 a plurality of times, (e.g., dedicated wire 802 may correspond to wire 510 in FIG. 5), as explained above, e.g., permitting control unit 724 to output non-whole multiples of aggregate aggressor current 736.

Some disclosed embodiments involve at least one dedicated wire integrated with and running along the vehicle wiring harness. A dedicated wire refers to a wire reserved for and/or assigned to a specific purpose. A dedicated wire may be used exclusively for a specific purpose during some time periods and may be used for other purposes during other time periods. In some embodiments, a dedicated wire may include a cancellation wire reserved for carrying a cancellation current. The dedicated wire may be selected from a plurality of wires in a wiring harness (e.g., a pre-existing wire included in the wiring harness) or may be added as new wire, in addition and/or external to the plurality of wires of the wiring harness. Running along refers to alongside, parallel, and/or adjacent. A wire running along a vehicle harness may be substantially parallel to or following the shape or contour of the bundle of wires in the wiring harness (e.g., the dedicated wire may not cross the wires in the bundle of wires). A dedicated wire integrated with and running along the vehicle wiring harness refers to a designated wire arranged, assembled, and/or disposed in alignment with the wires of the wiring harness. The dedicated wire may be one of the wires of the bundle of wires included in the wiring harness and selected for carrying a cancellation current. Alternatively, the dedicated wire may be external to the bundle of wires and/or the wiring harness), and affixed thereto, e.g., using tape, one or more clips, ties, clasps, and/or any other type of fastener. Current flowing through the dedicated wire may thus be parallel (e.g., and opposite) to currents flowing in the other (e.g., aggressor) wires of the wiring harness. In some disclosed embodiments, the at least one dedicated wire forms a plurality of wire turns through the current sensing probe. At least one dedicated wire may be wound multiple times around the current sensing probe, causing the current sensing probe to measure current flowing the at least one dedicated wire a plurality of times (e.g., proportional to the number of turns), as described above. An electronic control unit may base an adjustment of a cancellation current for outputting to the at least one dedicated wire on the number of wire turns through the current sensing probe to produce a cancelling magnetic field capable of mitigating an above-threshold level of aggressor magnetic radiation in a passenger cabin. For instance, looping a dedicated wire carrying a cancellation current around a current sensing probe N times may cause the sensor to measure an N-fold increase in the cancellation current. A control unit may output a cancellation current to account for the N-fold increase in the measured cancellation current versus the actual cancellation current, e.g., by decreasing the cancellation current N-fold.

Thus, looping the at least one dedicated wire around the current sensing probe N times may permit a control unit to supply a smaller cancellation current (by a factor of N) for generating a cancelling magnetic field capable of mitigating a wiring harness-induced aggressor magnetic field of greater than a threshold level in the region of the passenger cabin. In some embodiments, at least one aggressor wire may include M wire turns, around a current sensing probe and at least one dedicated wire may include N turns around (e.g., the same or an additional) current sensing probe, to permit cancelling a non-integer multiple of a wiring harness-induced aggressor magnetic field. A control unit may output a cancellation current proportional to M/N to account for the M-fold increase in the aggressor current and the N-fold increase in the cancellation current due to the plurality of wire turns in each of the at least one aggressor wire and the at least one dedicated wire.

In some disclosed embodiments, the at least one dedicated wire is configured for electrical connection to the electronic control unit via at least one of the plurality of connectors, to receive the determined cancellation current. A determined cancellation current refers to a current calibrated and/or adjusted to generate a cancelling magnetic field capable of mitigating an above-threshold level of aggressor magnetic radiation (e.g., in a passenger cabin of a vehicle). For example, a control unit as described elsewhere herein, may determine a cancellation current, and feed the cancellation current through at least one dedicated wire running alongside and/or within a wiring harness to generate a cancelling magnetic field capable of mitigating an above-threshold wiring harness-induced aggressor magnetic field in a passenger cabin. A dedicated wire configured for electrical connection to an electronic control unit via at least one of the connectors to receive a determined cancellation current refers to an end of the dedicated wire adapted for connection to the control unit via a connector (as described above), enabling the control unit to supply the determined cancellation current to the dedicated wire via the connector. Causing the cancellation current to flow through the dedicated wire may generate a cancelling magnetic field capable of mitigating an above-threshold level of aggressor magnetic radiation in the passenger cabin.

Some disclosed embodiments involve mitigating causation of at least the portion of the wiring harness-induced aggressor magnetic field in the region of the passenger cabin of the vehicle. This may refer to eliminating and/or cancelling a sufficient level of the aggressor magnetic field produced by the wiring harness such that any remaining aggressor magnetic field capable of permeating into the passenger cabin remains below a threshold level. Thus, cancellation of the aggressor magnetic field may occur in proximity to the wiring harness, such that any portion of the aggressor magnetic field that remains uncancelled may be below the threshold level.

By way of a non-limiting example, in FIG. 7, vehicle wiring assembly 700 includes at least one dedicated wire 714 integrated with and running along vehicle wiring harness 740. At least one dedicated wire 714 may be included in one or more of bundle of wires 702 if vehicle wiring harness 740. At least one dedicated wire 714 may be electrically connected to electronic control unit 724 via at least one of plurality of connectors 718. At least one dedicated wire 714 may receive determined cancellation current 726, and thereby mitigate causation of at least the portion of the wiring harness-induced aggressor magnetic field 910 in the region of passenger cabin 224 of vehicle 200 (see FIG. 9). For example, control unit 724 may determine cancellation current 726 to have similar attributes (e.g., amplitude, frequency, and/or phase) as aggregate current flowing 736 through aggressor wires 704. Control unit 724 may supply cancellation current 726 to at least one dedicated wire 714 to flow in an opposite direction to aggregate current 736 flowing through aggressor wires 704. Cancellation current 726 flowing through at least one dedicated wire 714 may generate a cancelling magnetic field 734. Cancelling magnetic field 734 may least partially cancel wiring harness-induced aggressor magnetic field 706 (corresponding to wiring harness-induced aggressor magnetic field 910 in FIG. 9) such that any remaining portion of wiring harness-induced aggressor magnetic field 910 may be below a threshold level in passenger cabin 224 of vehicle. Consequently, feeding cancellation current 726 to at least one dedicated wire 714 may mitigate a wiring harness-induced aggressor magnetic field of greater than the threshold level in passenger cabin 224 of vehicle 200. By way of another non-limiting example, in FIG. 5, at least one wire 512 may correspond to at least one dedicated wire 714 and may form a plurality of wire turns through inductance sensor 504 (e.g., a current sensing probe). Control unit 724 may account for the number of wire turns (N) when determining cancellation current 726 for feeding to at least one dedicated wire 714, e.g., by adjusting cancellation current 726 by a factor of N.

By way of another non-limiting example, in FIG. 8, vehicle wiring assembly 800 includes at least one dedicated wire 802 integrated with and running along vehicle wiring harness 740. At least one dedicated wire 802 may be external to bundle of wires 702 of wiring harness 740 and may be affixed to vehicle wiring harness 740 using one or more fasteners 804 to run substantially parallel to bundle of wires 702. At least one dedicated wire 802 may be electrically connected to electronic control unit 724 via at least one of plurality of connectors 718 and receive a determined cancellation current 812 to mitigate causation of at least the portion of the wiring harness-induced aggressor magnetic field 910 in the region of passenger cabin 224 of vehicle 200 (see FIG. 9). By way of another non-limiting example, in FIG. 5, at least one wire 512 may correspond to at least one dedicated wire 802 and may form a plurality of wire turns through a current sensing probe (e.g., inductance sensor 504). Control unit 724 may account for the number of wire turns (N) when determining cancellation current 812 for feeding to at least one dedicated wire 802, e.g., by adjusting cancellation current 812 by a factor of N.

Some disclosed embodiments involve at least one additional dedicated wire for cooperating to cancel a majority of the wiring harness-induced aggressor magnetic field in the region of the passenger cabin caused by the aggressor wires. An additional dedicated wire refers to another, e.g., second wire assigned for a specific purpose. Cooperating refers to collaborating and/or operating in a coherent, consistent, and/or cohesive manner. A majority of the wiring harness-induced aggressor magnetic field refers to at least half of the aggressor magnetic field generated by current flowing through the aggressor wires of the wiring harness. In some embodiments, a majority of the wiring harness-induced aggressor magnetic field refers to at least 60%, at least 70%, at least 75%, at least 80%, at least 85%, at least 90%, or at least 95% of the aggressor magnetic field generated by the wiring harness. In some embodiments, a majority of the wiring harness-induced aggressor magnetic field refers to a sufficient amount of the wiring harness-induced aggressor magnetic field such that removing the majority from the wiring harness-induced aggressor magnetic field causes any remaining aggressor magnetic field to be below the threshold level. To cancel majority of the wiring harness-induced aggressor magnetic field in the region of the passenger cabin caused by the aggressor wires refers to preventing a majority of the aggressor magnetic field generated by current flowing through the aggressor wires of the wiring harness from entering the passenger cabin. Thus, two or more dedicated wires may connect to a control unit for receiving one or more cancellation currents. Each of the dedicated wires may generate a cancelling magnetic field such that the combined cancelling magnetic field mitigates an above-threshold level of wiring harness-induced aggressor magnetic field in the passenger cabin. In some embodiments, the control unit may supply the same cancellation current to the dedicated wire and the additional dedicated wire. In some embodiments, the control unit may supply a first cancellation current to the dedicated wire and a second cancellation current to the additional dedicated wire. In some embodiments, the dedicated wire and/or the additional dedicated wire may include a plurality of turns or loops, and the control unit may adjust the cancellation current provided to the dedicated wire and/or additional dedicated wire based on the number of turns, as described earlier.

By way of a non-limiting example, in FIGS. 7 and 8, vehicle wiring assembly 700 may be combined with vehicle wiring assembly 800 to include at least at least one dedicated wire 714 (included in bundle of wires 702 in wiring harness 740) and at least one additional dedicated wire 802 (external to bundle of wires 702 in wiring harness 740). At least one dedicated wire 714 at least one additional dedicated wire 802 may cooperate to cancel a majority of wiring harness-induced aggressor magnetic field 910 in passenger cabin 224 caused by aggressor wires 704. For example, cancellation current 726 flowing through dedicated wire 714 may generate cancelling magnetic field 734, and cancellation current 812 flowing through dedicated wire 802 may generate an additional cancelling magnetic field 810. A combination of cancelling magnetic field 734 and cancelling magnetic field 810 (e.g., an aggregate cancelling magnetic field) may cancel a majority of wiring harness-induced aggressor magnetic field 910 (corresponding to wiring harness-induced aggressor magnetic field 706) such that any remaining portion of wiring harness-induced aggressor magnetic field 910 after the cancellation is below a threshold level.

In some disclosed embodiments, the bundle of wires includes a two-wire arrangement and wherein the at least one dedicated wire forms at least one loop along positive and negative leads of the vehicle wiring harness. A two-wire arrangement may include a positive designated wire, and a negative designated wire associated with a DC circuit. The positive designated wire may carry current from a power source to one or more electrical components in a circuit and the negative designated wire may complete the circuit by returning the current to the power source. Positive and negative leads of the vehicle wiring harness refers to two connectors (as described earlier) each dedicated for connecting to a positive wire and a negative wire of a circuit. The positive lead may connect a positive wire to a power source, permitting a current to flow from the power source to a circuit component via the positive wire. The negative lead may connect a negative wire to the power source, permitting current to return from the circuit component to the power source via the second connector. A loop along positive and negative leads of a vehicle wiring harness may refers to an (e.g., closed) circuit formed from two dedicated wires including a positive wire for supplying a current from a current source and a negative wire for returning the current to the current source. In some embodiments, the current source may include an amplifier and/or a control unit for outputting a cancellation current.

By way of a non-limiting example, in FIG. 5, wire 512 may be included in bundle of wires 702. Wire 512 may include a two-wire arrangement (e.g., with positive and negative leads). In FIG. 7, at least one dedicated wire 714 may form at least one loop along positive and negative leads of the vehicle wiring harness. For example, in FIG. 8, bundle of wires 702 of wiring harness 740 may be considered as a single aggregate aggressor wire, and at least one dedicated wire 802 may be aligned alongside at least a portion of the single aggregate aggressor wire, e.g., as shown in FIG. 4. At least one dedicated wire 802 may form a loop (e.g., an AC cancellation loop) permitting a cancellation current to circulate through the loop for continual cancellation of an aggressor magnetic field generated by the single aggregate aggressor wire.

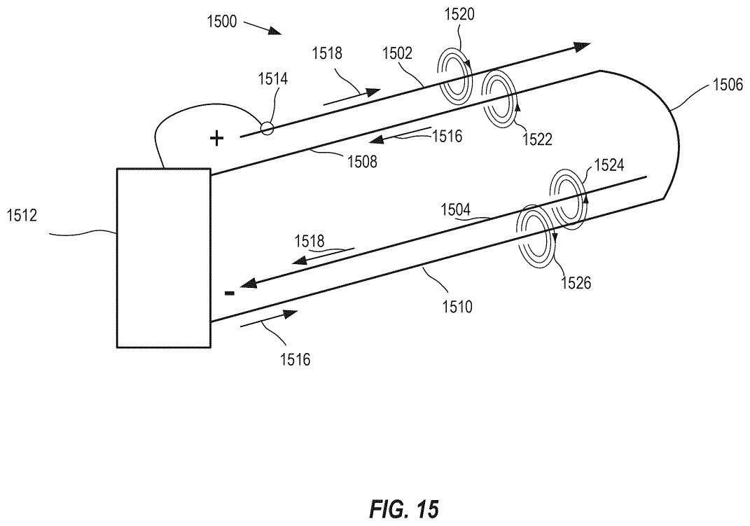

By way of another non-limiting example, reference is made FIG. 15, which illustrates an exemplary cancellation system 1500 for a vehicle wiring assembly, consistent with some disclosed embodiments. System 1500 includes a two wire arrangement including a first aggressor wire 1502 associated with a positive lead and a second aggressor wire 1504 associated with a negative lead. First aggressor wire 1502 and second aggressor wire 1504 may be included in a vehicle wiring harness (e.g., wiring harness 740 of FIG. 7) and may carry an aggressor current 1518 to power one or more vehicle components. Aggressor current 1518 may flow through first wire 1502 in a first direction, and may flow through second wire 1504 in a second direction opposite to the first direction. System 1500 may additionally include a cancellation loop 1506 including a first leg 1508 and a second leg 1510 (indicated with dotted lines) connected to a control unit 1512 (e.g., corresponding to control unit 724). First leg 1508 of cancellation loop 1506 may be aligned with at least a portion of first aggressor wire 1502 and second leg 1510 of cancellation loop 1506 may be aligned with at least a portion of second aggressor wire 1504. In response to receiving an indication of aggressor current 1518 flowing through first wire 1502 and/or through second wire 1504 from at least one sensor 1514, control unit 1512 may output a cancellation current 1516 to cancellation loop 1506 such that aggressor current 1518 flowing in first aggressor wire 1502 flows opposite to cancellation current 1516 flowing in first leg 1508 aligned with first aggressor wire 1502. Similarly, aggressor current 1518 flowing in second aggressor wire 1504 may flow opposite to cancellation current 1516 flowing in second leg 1510 aligned with second aggressor wire 1504. Consequently, a first aggressor magnetic field 1520 generated by aggressor current 1518 flowing through first aggressor wire 1502 may be at least partially cancelled by a first cancelling magnetic field 1522 generated by cancellation current 1516 flowing in first leg 1508 of cancellation loop 1506. Similarly, a second aggressor magnetic field 1524 generated by aggressor current 1518 flowing through second aggressor wire 1504 may be at least partially cancelled by a second cancelling magnetic field 1526 generated by cancellation current 1516 flowing in second leg 1510 of cancellation loop 1506

In some disclosed embodiments, the bundle of wires includes a three-phase electrical wiring including a first wire, a second wire, and a third wire. A three-phase electrical wiring refers to three wires, each dedicated to carrying one phase of a three-phase signal, as described elsewhere herein. Thus, a three-phase electrical wiring may carry three AC signals (e.g., Iₐ, I_{b}, and I_{c}), each AC signal shifted in phase from the other two AC signals. For example, the three-phase electrical wiring may be associated with a motor of an electrical and/or hybrid vehicle and may be rated for higher voltages and/or currents. At least a portion of the three-phase electrical wiring may be located, for example, along a vehicle chassis (e.g., beneath a passenger compartment), in a rear, front, top, bottom, side of a vehicle, beneath and/or alongside a passenger seat, beneath a passenger compartment floor, and/or in any other region of the vehicle. A first wire, a second wire, and a third wire refers to a wire dedicated to carrying a first phase (e.g., Iₐ) of a three phase signal, an additional wire dedicated to carrying a second phase (e.g., I_{b}) of the three phase signal, and another additional wire dedicated to carrying a third phase (e.g., I_{c}) of the three phase signal. When the vehicle is in operation (e.g., in use), three phase-shifted AC signals flowing through each of the first wire, the second wire, and the third wire may generate an aggressor magnetic field that may radiate into the passenger compartment of the vehicle. The aggressor magnetic field may include three aggressor magnetic fields phase shifted from each other.

In some disclosed embodiments, the at least one dedicated wire includes a first dedicated wire forming a first cancellation loop and a second dedicated wire forming a second cancellation loop. A first dedicated wire forming a first cancellation loop and a second dedicated wire forming a second cancellation loop refers to a first dedicated wire arranged in a first closed geometric shape (e.g., round, oval, square, rectangular, or any other closed geometric shape) and a second dedicated wire arranged in a second closed geometric shape, such that the two dedicated wires complete two closed geometric shapes. Each cancellation loop may include one or more substantially straight sections permitting to align each substantially straight section with a portion of one of the wires of the three-phase electrical wiring. In some embodiments, the first cancellation loop may be connected to a first power supply and the second cancellation loop may be connected to a second power supply. Each of the first cancellation loop and the second cancellation loop may include a first portion permitting current to flow in a first direction and a second portion permitting current to flow in a second direction opposite to the first direction (e.g., as a return path).

In some disclosed embodiments, the first cancellation loop includes a first non-overlapping section along at least a portion of the first wire. Non-overlapping refers to not sharing a common area or not interfering with one another. A non-overlapping section of the first cancellation loop along a portion of the first wire refers to an arrangement where a portion (e.g., a leg) of the first cancellation loop is aligned along the first wire, however, the second cancellation loop does not include any portions aligned with the first wire, e.g., such that the first wire is only aligned with a portion of the first cancellation loop, but is not aligned with any portions of the second cancellation loop. Thus a first (e.g., substantially straight) section of the first cancellation loop may be aligned with a portion of the first wire carrying the first phase (Iₐ) of the three-phase signal. A control unit may feed a first cancellation current through the first section of the first cancellation loop aligned with the first wire to flow opposite to the first phase (Iₐ) of the aggressor current flowing through the first wire. Consequently, a cancelling magnetic field generated by the first cancellation current flowing in the first cancellation loop aligned along the first wire at least partially cancels an aggressor magnetic field generated by the first phase (la) of the three-phase signal flowing in the first wire.

In some disclosed embodiments, the second cancellation loop includes a second non-overlapping section along at least a portion of the third wire. A non-overlapping section of the second cancellation loop along a portion of the third wire refers to an arrangement where a portion (e.g., a leg) of the second cancellation loop is aligned along the third wire, however, the first cancellation loop may not include any portions aligned with the third wire, e.g., such that the third wired is only aligned with a portion of the second cancellation loop, but is not aligned with any portions of the first cancellation loop. Thus a second (e.g., substantially straight) section of the second cancellation loop may be aligned with a portion of the third wire carrying the third phase (I_{c}) of the three-phase signal. A control unit may feed a second cancellation current through the second section of the second cancellation loop aligned with the third wire to flow opposite to the third phase (I_{c}) of the aggressor current flowing through the third wire. Consequently, a cancelling magnetic field generated by the second cancellation current flowing in the second cancellation loop aligned along the third wire at least partially cancels an aggressor magnetic field generated by the third phase (I_{c}) of the three-phase signal flowing in the third wire. In some embodiments, a common control unit may feed a first cancellation current to the first cancellation loop and a second cancellation current to the second cancellation loop via separate channels. In some embodiments, a first control unit may feed a first cancellation current to the first cancellation loop and a second control unit may feed a second cancellation current to the second cancellation loop.

In some disclosed embodiments, the first cancellation loop and the second cancellation loop partially overlap along at least a portion of the second wire. To partially overlap refers to coinciding, overlaying, and/or lying adjacent each other. For example, sections of the first and second cancellation loops may abut and/or align flush and/or adjacent to each other. In some embodiments, an external coating of a section of the first cancellation loop may touch an external coating of a section of the second cancellation loop in the partially overlapping region. Thus, the first and second cancellation loops may be arranged to partially overlap along the second wire of the three-phase wiring. A control unit may feed the first cancellation current to the first cancellation loop and the second cancellation current to the second cancellation loop such that, at the partially overlapping region of the first and second cancellation loops, a cancelling magnetic field generated by the combination of the first and second cancellation currents in the overlapping section at least partially cancels an aggressor magnetic field generated by the second phase (I_{b}) of the three-phase signal flowing in the second wire.

For example, without loss of generality, a three-phase signal flowing through three wires of a three-phase wiring may be described as:

$${I}_{a} = {I}_{0} cos ( 2 π ft - 120 ° )$$

$${I}_{b} = {I}_{0} cos ( 2 π ft )$$

$${I}_{c} = {I}_{0} cos ( 2 π ft + 120 ° )$$

Where f is the frequency of the current, I₀ is the amplitude, and either may vary in time (t). A three-phase signal may be described as a sum of sine and/or cosine functions (e.g., Fourier sum) and frequency of the alternative current may change in time as is used in various electrical motors.

At least one control unit may feed first and second cancellation currents I₁ and I₂ respectively, to the first and second cancellation loops based on a signal indicative of the three-phase current flowing through the three-phase electrical wiring. Thus, the control unit may feed first cancellation current of I₁=−Iₐ to the first cancellation loop, such that first cancellation current I₁ flows opposite to the first phase Iₐ of the three-phase signal flowing in the first wire of the three-phase wiring. The control unit may feed a second cancellation current of I₂=−I_{c} to the second cancellation loop, such that second cancellation current I₂ flows opposite to the third phase/c of the three-phase signal flowing in the third wire of the three-phase wiring. The combination of first and second cancellation currents I₁ and I₂ transmitted through both the first and second cancellation loops aligned and overlapping with the second wire of the three-phase wiring may flow opposite to the second phase I_{b} of the three-phase signal flowing the second wire of the three-phase wiring, e.g.,

$$- ( I 1 + I 2 ) = {I}_{a} + {I}_{c} = {I}_{0} cos ( 2 π ft - 120 ° ) + {I}_{0} cos ( 2 π ft + 120 ° ) = 2 {I}_{0} cos ( \frac{2 π ft - 120 ° + 2 π ft + 120 °}{2} ) cos ( \frac{2 π ft - 120 ° - 2 π ft - 120 °}{2} ) = 2 {I}_{0} cos ( 2 π ft ) cos ( - 120 ° ) = - {I}_{0} cos ( 2 π ft ) = - {I}_{b}$$

Where f is the frequency of the current, I₀ is the amplitude, and either may vary in time (t). Thus, the partially overlapping arrangement of first and second cancellation loops on the three-phase wiring may permit cancellation of all three phases of an aggressor magnetic field generated by the three-phase signal.

In some disclosed embodiments, at least one of the first cancellation loop or the second cancellation loop includes a plurality of wire turns. A plurality of wire turns may be understood as described elsewhere herein. The plurality of wire turns may not be wound around the current sensor (e.g., as shown in FIG. 5), but may form a plurality of wire turns in alignment and/or adjacent to a portion of the wiring harness to generate an N-fold increase in the cancelling magnetic field, without having to increase the cancellation current by N-fold (e.g., as shown in FIG. 6). A control unit may adjust a cancellation current supplied to a cancellation loop including a plurality of wire turns in proportion to the number of wire turns. For example, if a cancellation loop includes N turns, a cancellation magnetic field generated by the N wire turns may increase N-fold. This may permit a control unit to decrease an amplitude of a cancellation current supplied to the cancellation loop by a factor of N, e.g., to conserve energy.

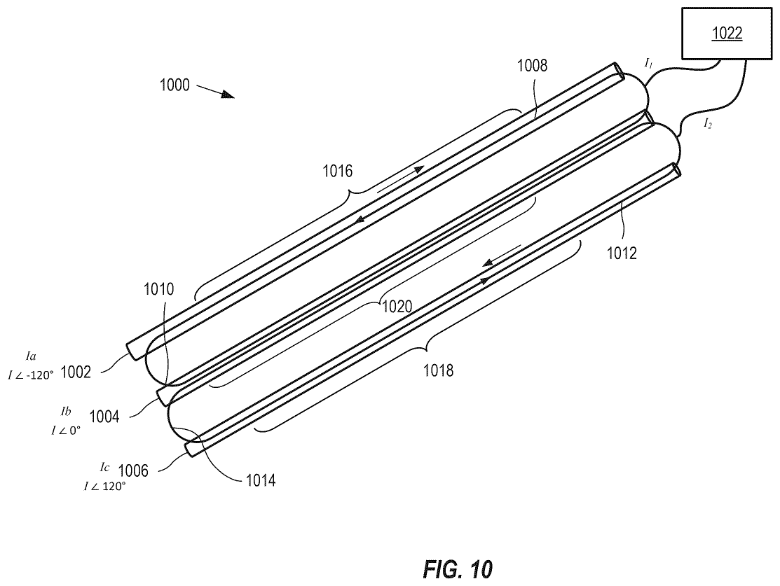

By way of a non-limiting example, reference is made to FIG. 10 a three-phase electrical wiring 1000, consistent with some disclosed embodiments. Three-phase electrical wiring 1000 may be included in wiring harness 740 of vehicle wiring assembly 700 shown in FIG. 7, and may correspond to one or more of aggressor wires 704. Three-phase electrical wiring 1000 may include a first wire 1002 carrying a first phase (Iₐ), a second wire 1004 carrying a second phase (I_{b}), and a third wire 1006 carrying a third phase (I_{c}) of a three-phase signal. At least one dedicated wire 714 may include a first dedicated wire 1008 forming a first cancellation loop 1010 and a second dedicated wire 1012 forming a second cancellation loop 1014. First cancellation loop 1010 includes a first non-overlapping section 1016 along at least a portion of the first wire 1002, e.g., such that only section 1016 of first dedicated wire 1008 is aligned with first wire 1002 carrying the first phase of the three phase aggressor signal, and second dedicated wire 1012 does not include any sections overlapping first wire 1002 carrying the first phase of the three phase aggressor signal. Second cancellation loop 1014 may include a second non-overlapping section 1018 along at least a portion of third wire 1006, e.g., such that only section 1018 of second dedicated wire 1012 is aligned with third wire 1006 carrying the third phase of the three phase aggressor signal, and first dedicated wire 1008 does not include any sections overlapping third wire 1006 carrying the third phase of the three phase aggressor signal. First cancellation loop 1010 and second cancellation loop 1014 may partially overlap along at least a portion 1020 of second wire 1004. At least one control unit 1022 may feed a first cancellation current I₁ to first cancellation loop 1010 such that a cancelling magnetic field generated by first cancellation current I₁ at least partially cancels a first phase of an aggressor magnetic field generated by the first phase Iₐ of a three-phase aggressor current flowing in first wire 1002. Similarly, control unit 1022 may feed second cancellation current I₂ to second cancellation loop 1014 such that a cancelling magnetic field generated by second cancellation current I₂ at least partially cancels a third phase of an aggressor magnetic field generated by I_{c} of a three-phase aggressor current flowing in third wire 1006. In addition, a cancelling magnetic field generated by the combination of I₁ and I₂ may at least partially cancel a second phase of an aggressor magnetic field generated by the second phase I_{b} of the three-phase aggressor current flowing in second wire 1004. In some embodiments, control unit 1022 may be a single control unit having a different dedicated channel for first cancellation loop 1010 and second cancellation loop 1014. In some embodiments, control unit 1022 may include two control units for each of first cancellation loop 1010 and second cancellation loop 1014. By way of another non-limiting example, in FIG. 6, first cancellation loop 1010 and/or second cancellation loop 1014 may be arranged similar to wire 602 including a plurality of wire turns.

In some embodiments, at least one processor may control an amplifier and/or an associated electronic control unit supplying a cancellation current to at least one dedicated wire, however this is not required. For example, at least one processor may receive signals indicative of the aggressor magnetic field and/or an aggressor (e.g., aggregate) current associated therewith and use the signals to modify an AC cancellation current (e.g., by modifying a DC current for conversion to an AC cancellation current via an inverter). This may permit the at least one processor to control attributes of the cancellation magnetic field generated by the AC cancellation current. As another example, at least one processor may be used to test, tune, calibrate and/or troubleshoot one or more magnetic field cancellation components integrated and/or associated with a vehicle wiring assembly.

Some disclosed embodiments involve a system for powering a cancelling field in a passenger cabin of a vehicle. A passenger cabin of a vehicle may be understood as described elsewhere herein. A cancelling field refers to a magnetic field and/or an electromagnetic field, that when combined with another magnetic and/or electromagnetic field, at least partially eliminates the other magnetic and/or electromagnetic field, resulting in a reduction in intensity (e.g., amplitude) of the other magnetic and/or electromagnetic field. Powering refers to providing and/or supplying energy to permit a device and/or apparatus to operate. For example, a system for powering a cancelling field in a passenger cabin of a vehicle may generate electrical energy to operate circuitry and/or supply a current (e.g., a cancellation current) for generating a cancelling field. Powering a cancelling field in a passenger cabin of a vehicle may involve generating a cancelling magnetic field external to the passenger cabin such to at least reduce magnetic field radiation in the passenger cabin.

Some disclosed embodiments involve an AC aggressor loop configured to generate an aggressor magnetic field in the passenger cabin of the vehicle. An AC current and a passenger cabin of a vehicle may be understood as describe elsewhere herein. An AC aggressor loop may include DC components (e.g., one or more DC signals) such that current flowing through the AC aggressor loop may include a combination of AC and DC signals. Aggressor and an aggressor magnetic field may be understood as described elsewhere herein. In some disclosed embodiments, the aggressor magnetic field is an electromagnetic field. An electromagnetic field is a region of space wherein force created by moving electrical charges, such as a wire, can act, for example, on objects. For instance, electrical charges in an electric motor can create an electromagnetic field. By way of another example, one or more electrical components for operating a vehicle may cause rapid changes in current due to sudden braking, acceleration, and/or overheating. This may cause one or more circuits to rapidly switch on/off and produce an aggressor electromagnetic field, as described elsewhere herein (e.g., in addition to an aggressor magnetic field). A loop refers to a closed geometric form and/or a closed path where a beginning point, and an end point coincide. A path formed by a loop may return to a starting point, permitting a current to circulate through the loop. An AC aggressor loop refers to a conductive structure (e.g., a wire cable as described elsewhere herein) shaped as a closed path for carrying an AC current to operate one or more features of a vehicle. For example, an AC aggressor may include a wire loop connected to a 12 V battery to operate one or more lights, windshield wipers, infotainment systems, fans, seat adjustment system, and/or climate control systems of a vehicle. As another example, an AC aggressor may include a wire loop for operating a power steering and/or automated braking (e.g., regenerative braking) systems for a vehicle. Causing an AC current to circulate in an AC aggressor loop (e.g., as an aggressor current) may generate a potentially harmful magnetic field (e.g., an aggressor magnetic field) due to electromagnetic induction, according to Ampere's law. An AC aggressor loop may carry AC current to operate one or more electrically controlled components of a vehicle, as described elsewhere herein. AC current flowing through an AC aggressor loop may generate an aggressor magnetic field, which may radiate into the passenger cabin and expose one or more to potentially harmful magnetic radiation. In some embodiments, an AC aggressor loop may include DC and AC components. One or more DC components may power one or more electrical components of a vehicle, and the AC components may be associated with switching, modifying, and/or turning on/off the one or more DC components.

Some disclosed embodiments involve an AC cancellation loop configured to generate a cancellation magnetic field at least partially cancelling the aggressor magnetic field. To generate refers to produce, induce, cause, and/or emit. A cancellation magnetic field refers to a magnetic field generated to oppose and reduce or eliminate another magnetic field. Thus, a cancellation magnetic field may be capable of cancelling or at least significantly reducing an aggressor magnetic field. Attributes of a cancellation magnetic field (e.g., amplitude, frequency, and/or phase, may be substantially similar to attributes of an aggressor magnetic field however a cancellation magnetic field may be oriented in an opposite direction to the aggressor magnetic field. In other words, if lines of an aggressor magnetic field point from north to south, lines of a cancellation magnetic field may point from south to north, and the reverse. Consequently, combining a cancellation magnetic field with an aggressor magnetic field may lead to at least partial cancellation of the aggressor magnetic field. An AC cancellation loop refers to a cancellation wire, as described elsewhere herein, shaped in a closed or at least partially closed form and configured to carry an AC current. AC current may circulate through the AC cancellation loop and generate a magnetic field capable of cancelling or at least partially reducing an aggressor magnetic field. An AC cancellation loop may include DC components (e.g., one or more DC signals) such that current flowing through the AC cancellation loop includes a combination of AC and DC signals. At least partially cancelling the aggressor magnetic field refers to at least partially reducing and/or diminishing an aggressor magnetic field through cancellation, e.g., as opposed to fully preventing magnetic field radiation. At least partially cancelling an aggressor magnetic field may include cancelling at least 30%, at least 40%, at least 50%, at least 60%, at least 65%, at least 70%, at least 75%, at least 80%, at least 85%, at least 90%, or at least 95% of an aggressor magnetic field. Reducing a magnetic field may include reducing a field strength, field intensity, and/or a flux density.

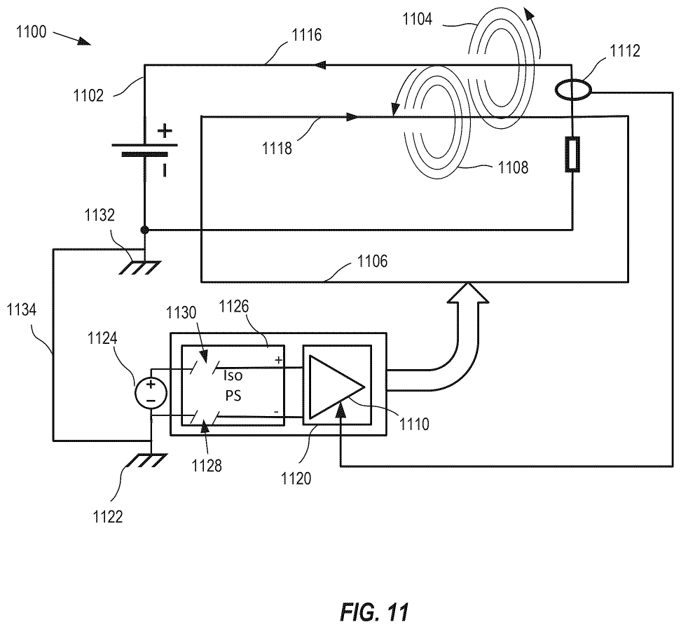

By way of a non-limiting example, FIG. 11, illustrating an exemplary system 1100 for powering a cancelling field in a passenger cabin of a vehicle, consistent with some disclosed embodiments. System 1100 includes an AC aggressor loop 1102 generating an aggressor magnetic field 1104 that may radiate into a passenger cabin of a vehicle (e.g., see FIG. 2B showing an aggressor magnetic field 220 radiating into passenger cabin 224 of vehicle 200). For example, AC aggressor loop 1102 may carry an aggressor current 1116 (e.g., including AC and/or DC components) to power motor 212 and/or additional electrical features of vehicle 200. The flow of aggressor current 1116 through AC aggressor loop 1102 may generate aggressor magnetic field 1104. System additionally includes an AC cancellation loop 1106 for generating a cancellation magnetic field 1108 at least partially cancelling aggressor magnetic field 1104. For example, a cancellation current 1118 (e.g., including AC and/or DC components) may flow in AC cancellation loop 1106 opposite to aggressor current 1116 such that field lines of cancellation magnetic field 1108 may be oriented opposite to field lines of aggressor magnetic field 1104, leading to at least partial cancellation of aggressor magnetic field 1104.

Some disclosed embodiments involve an amplifier for supplying the alternating current to power the AC cancellation loop. An amplifier and an alternating current (AC) may be understood as described elsewhere herein. Supplying refers to providing, feeding, outputting, and/or delivering. To power may include driving, electrifying, operating, and/or feeding (e.g., an electrical signal). An amplifier for supplying an alternating current refers to an amplifier connectable to a power supply for outputting an AC current. Powering an AC cancellation loop refers to supplying current to an AC cancellation loop to generate a cancelling magnetic field capable of at least reducing an aggressor magnetic field in a passenger cabin of a vehicle (e.g., to mitigate an above-threshold aggressor magnetic field in the passenger cabin). For example, an amplifier may receive a signal from at least one sensor indicating a current flowing through the AC aggressor loop. The amplifier may receive power from a power supply and use the power to produce a cancelation current corresponding to the current indicated by the received signal. The amplifier may supply the cancellation current to the AC cancellation loop to generate a cancelling magnetic field at least partially cancelling the aggressor magnetic field. The at least partial cancellation may prevent the cancelled portion of the aggressor magnetic field from entering the passenger cabin, and may facilitate in mitigating an above-threshold level of aggressor magnetic field in the passenger cabin.

Some disclosed embodiments further comprise a control unit for regulating the amplifier. A control unit may be understood as described elsewhere herein. For example, a control unit may include one or more processors, however this is not required. Additionally, a control unit may incorporate a sensor, a feedback loop, and/or a current source, or may be electrically connectable to such components. Regulating refers to controlling, modifying, tuning, and/or adjusting. For example, an amplifier may receive signals from a current sensor indicative of current flowing through an AC aggressor loop (e.g., an aggressor current). The control unit may apply the signals to adjust the amplification of the current received from the current source by the amplifier to output a current (e.g., a cancellation current) for generating a cancelling magnetic field capable of cancelling at least a portion of the aggressor magnetic field. The control unit may include and/or may otherwise be associated with a feedback loop providing a corrective signal to further adjust the amplification by the amplifier until the cancellation current matches a targeted output current (e.g., a setpoint). For instance, the targeted output current may match the aggressor current or may be proportional to the aggressor current, accounting for one or more wire turns of the AC aggressor loop and/or the AC cancellation loop, e.g., around a sensor measuring an indication of current.

In some embodiments, an AC signal for powering an AC cancellation loop may be generated using an inverter (e.g., a DC-AC converter) connected to a DC source (e.g., a battery and/or a capacitor). An input of an inverter may connect to an output of a DC source (e.g., a battery), and an output of the inverter may be fed to an AC cancellation loop, causing the AC signal outputted from the inverter to circulate through the AC cancellation loop. For instance, the amplitude and direction of the AC output may correspond to the amplitude and direction of the DC input, and the phase and/or frequency of the AC output may correspond to a switching frequency and/or phase of the inverter, and may be modified using Pulse Wave Modulation (PWM), by changing a frequency of the oscillator).

By way of a non-limiting example, in FIG. 11, an amplifier 1110 may supply a current (e.g., AC cancellation current 1118) to power AC cancellation loop 1106. AC cancellation current 1118 may include AC and/or DC components. For example, a current sensor 1112 arranged with AC aggressor loop 1102 may transmit a signal indicative of AC aggressor current 1116 (e.g., including AC and/or DC components) flowing through AC aggressor loop 1102 to amplifier 1110. Amplifier 1110 may receive an input current from a power supply 1126 and use the signal from current sensor 1112 to output AC cancellation current 1118 corresponding to AC aggressor current 1116. AC cancellation current 1118 may be substantially the same as AC aggressor current 1116 to achieve approximately 100% cancellation. Alternatively, AC cancellation current 1118 may be proportional to AC aggressor current 1116 to achieve proportional cancellation (e.g., partial or less than 100% cancellation). In some embodiments, system 1100 may include a control unit 1120 for regulating amplifier 1110. Control unit 1120 may include a feedback loop and/or a PID controller to adjust an output of amplifier 1110 (e.g., see FIG. 6.)

In some disclosed embodiments, the amplifier is electrically isolated from an electrical ground associated with the vehicle. A vehicle (as described elsewhere herein) may include one or more electric circuits to operate one or more electrically controlled components, as described elsewhere herein. An electrical ground refers to a reference point in an electrical circuit for measuring voltages. It may serve as a reference for “zero volts” (0 V) within a circuit and may or may not be zero relative to the Earth (e.g., an absolute ground). An electrical ground for a vehicle may be non-zero relative to the Earth, and may permit current to flow back to a power source, e.g., as a return path, and/or a safety path for excess current. A system may include more than one electrical ground, for instance to isolate two or more electrical systems for safety, to prevent interference (e.g., for sensitive electronics), and/or to permit independent operation for differing electrical sub-systems. An electrical ground associated with a vehicle (e.g., a vehicle ground) refers to a reference point (e.g., a relative zero voltage point) for one or more electrically controlled components of a vehicle, as referred to above. An AC aggressor loop carrying current for operating a vehicle may be associated with an electrical ground of the vehicle such that current flowing through the AC aggressor loop flows towards the electrical ground of the vehicle. A component that is electrically isolated may be insulated, disconnected, decoupled, and/or otherwise separate from another electrical component to block a flow of electric current between the components. The electrical isolation may permit transfer of electrical energy and/or an electrical signal via one of the components while avoiding creation of a direct and/or indirect conductive path to the other component, e.g., for safety, signal integrity, and/or functional separation. Two electrically isolated components may lack any shared connection point and/or lack a common ground to prevent current from flowing therebetween. By way of example, lower voltage control circuitry may be electrically isolated from higher voltage power signals (e.g., using an optocoupler and/or a transformer) to prevent interference and/or prevent damage to the lower voltage control circuitry. An amplifier electrically isolated from an electrical ground associated with an electrical ground of a vehicle refers to decoupling and/or insulating the amplifier from the vehicle ground. For example, an amplifier outputting a cancellation current may be electrically isolated from a vehicle ground by electrically isolating a power supply feeding a current to the amplifier from the vehicle ground. The electrical isolation may prevent current from the power source and/or the amplifier from leaking to wires associated with operating the vehicle, and thereby prevent generation of non-desirable and/or aggressor magnetic field (e.g., a non-cancelling magnetic field). Absent electrical isolation from the vehicle ground, current from the power supply and/or amplifier may flow towards the vehicle ground (e.g., opposite to the cancellation current) and leak into additional wires, cable, and/or components in the vehicle, leading to generation of undesirable magnetic fields (e.g., non-cancelling magnetic fields). Similarly, lack of electrical isolation of the amplifier from the vehicle ground may cause formation of one or more parasitic loops associated with one or more wires and/or a chassis of the vehicle, and generate undesired (e.g., aggressor) magnetic fields. Electrically isolating the amplifier and/or a power source feeding the amplifier (e.g., by arranging a transformer, an insulator, and/or an optocoupler between the amplifier and/or power supply and the vehicle ground) may thus prevent formation of parasitic loops and/or current leakage.

Some disclosed embodiments involve reducing generation of non-cancelling magnetic field radiation. Reducing may include diminishing, decreasing, and/or attenuating. Non-cancelling magnetic field radiation refers to aggressor magnetic field radiation and/or magnetic field radiation lacking attributes for cancelling aggressor magnetic field radiation. Non-cancelling magnetic field radiation may have field lines substantially aligned and in the same direction as an aggressor magnetic field, and/or otherwise non-opposite to an aggressor magnetic field. Combining non-cancelling magnetic field radiation with an aggressor magnetic field may fail to cancel and/or reduce an aggressor magnetic field and may even lead to amplification and/or increase of aggressor magnetic field radiation. Non-cancelling magnetic field radiation may be generated, for example, by another AC current flowing in a similar direction as an aggressor current flowing in an AC aggressor loop. This may be due to absence of electrical isolation of a power supply and/or amplifier outputting a cancellation current from a vehicle ground associated with an AC aggressor loop, permitting leakage of some of the cancellation current into other wires and/or vehicle components which may generate non-cancelling magnetic field radiation. Electrically isolating the amplifier and/or power source feeding the amplifier from the electrical ground of the vehicle may prevent such leakage, e.g., by preventing formation of a common ground, and may thus reduce generation of non-cancelling magnetic field radiation to facilitate in reducing aggressor magnetic field radiation in the passenger cabin.

In some embodiments, a system for powering a cancelling field in a passenger cabin of a vehicle may exclusively include analog components, and may lack a processor. In some embodiments, at least one processor may control an amplifier and/or an associated control unit supplying an alternating current to an AC cancellation loop, however this is not required. For example, at least one processor may modulate a DC current fed to an inverter for producing an AC current supplied to an AC cancellation loop. In some embodiments, the at least one processor may receive signals indicative of the aggressor magnetic field and/or a current associated therewith and use the signals to control to modify a DC current for conversion to an AC cancellation current. This may permit the at least one processor to control attributes of the cancellation magnetic field generated by the AC cancellation current. As another example, at least one processor may be used to test, tune, calibrate and/or troubleshoot components associated with supplying an alternating current to an AC cancellation loop.

By way of a non-limiting example, in FIG. 11, amplifier 1110 may be electrically isolated from an electrical ground 1122 of a vehicle (e.g., corresponding to electrical ground 232 of vehicle 200 in FIG. 2A). For example, a power source 1124 (e.g., corresponding to battery pack 206) may be electrically connected to electrical ground 1122 of the vehicle. An isolated power supply 1126 may receive power from power source 1124. In some embodiments, isolated power supply 1126 may receive power from power source 1124 directly. The isolated power supply 1126 may electrically isolate power received from power source 1124 via an input of isolated power supply 1126 from one or more outputs of isolated power supply 1126 in a manner isolating the output of isolated power supply 1126 from electrical ground 1122 (e.g., the isolation may be indicated by gaps 1128 and 1130). For example, gaps 1128 and 1130 may be associated with a transformer and/or an optocoupler included within isolated power supply 1126. In some embodiments, power source 1124 may output a DC current to isolated power supply 1126 and isolated power supply 1126 may convert the DC current to an AC current. Consequently, current fed from isolated power supply 1126 to amplifier 1110 may be prevented from leaking to other wires and/or components of the vehicle connected to electrical ground 1122. Similarly, current flowing in other wires and/or components of vehicle 200 may be prevented from leaking into amplifier 1110. Electrically isolating amplifier 1110 and/or a current outputted by isolated power supply 1126 from ground 1122 may reduce generation of non-cancelling magnetic field radiation. For example, absent electrical isolation (e.g., absent gaps 1130 and/1128), current could potentially flow from isolated power supply 1126 and/or from amplifier 1110 (and/or control unit 1120) towards vehicle ground 1122, and continue via a path 1134 towards another vehicle ground 1132, where the current may enter AC aggressor loop 1102, potentially generating non-cancelling magnetic field radiation.

In some disclosed embodiments, the electrically isolated amplifier is electrically isolated from a vehicle chassis. A vehicle chassis (as described elsewhere herein) may serve as an electrical ground for a vehicle. For instance, a vehicle chassis may be made of electrically conductive material (e.g., metal) and may function as a return path for an AC aggressor loop. Thus, current flowing for operating a vehicle may flow through a vehicle chassis and may generate an aggressor magnetic field, which absent cancellation may radiate into a passenger cabin of the vehicle. Electrically isolating an AC cancellation loop from the vehicle chassis may electrically isolate the AC cancellation loop from the AC aggressor loop. This may prevent and/or reduce leakage of cancellation current from entering the AC aggressor loop and/or additional vehicle wires and/or cables, which may prevent generation of and/or reducing non-cancelling magnetic field radiation. Thus, electrically isolating an AC cancellation loop from the vehicle chassis may further facilitate in cancelling and/or reducing an aggressor magnetic field in a passenger cabin of a vehicle. In some disclosed embodiments, a portion of the AC aggressor loop includes a vehicle chassis. A portion of an AC aggressor loop including a vehicle chassis may refer to an AC aggressor loop connected or otherwise electrically associated with the vehicle chassis, a cable and/or wire of the AC aggressor loop routed in proximity and/or along the vehicle chassis, and/or a portion of the vehicle chassis (e.g., made of electrically conductive material such as metal) serving as a return path for current flowing in the AC aggressor loop. For example, a lower voltage system in a vehicle (e.g., up to 12 V) for operating one or more fans, lights, an infotainment system, one or more seat heaters, door locks, and/or windows may route current in a return path through a vehicle chassis. In some embodiments, higher voltage system in a vehicle (e.g., associated with operating a motor) may be electrically isolated from a vehicle chassis.

By way of a non-limiting example, in FIG. 11, vehicle ground 1122 may include a vehicle chassis (e.g., corresponding to chassis 202 in FIGS. 2A-2B), and amplifier 1110 may be electrically isolated from chassis 202. In some embodiments, a portion of AC aggressor loop 1102 may include a portion of vehicle chassis 202. Vehicle chassis 202 may be sufficiently large so as to dissipate any currents flowing therethrough to prevent leakage.

In some disclosed embodiments, the electrically isolated amplifier is associated with a floating ground. A floating ground refers to a reference voltage in a circuit that is independent of and/or lacks an electrical connection to another ground (e.g., another reference voltage), such as an electrical ground of a vehicle, or the Earth. When a reference voltage is not tethered to a known voltage potential (like a vehicle chassis or the Earth), it may drift and/or vary (e.g., “float”), for instance due to leakage currents, capacitive coupling, and/or external fields. In some embodiments, decoupling a power supply and/or an amplifier from a vehicle ground (e.g., by electrically isolating the power supply and/or the amplifier) may permit the electrically isolated power supply to operate and/or serve as a floating ground. Since an AC aggressor loop carrying AC current for powering a vehicle may be associated with the vehicle ground, associating the amplifier and/or power supply with a floating ground may contribute to electrically isolating the amplifier from the vehicle ground. This may prevent and/or reduce current leakage from and/or to the power supply and/or amplifier via a common ground, thereby preventing and/or reducing generation of a non-cancelling magnetic field, and facilitating in cancelling and/or reducing aggressor magnetic field radiation in the passenger cabin.

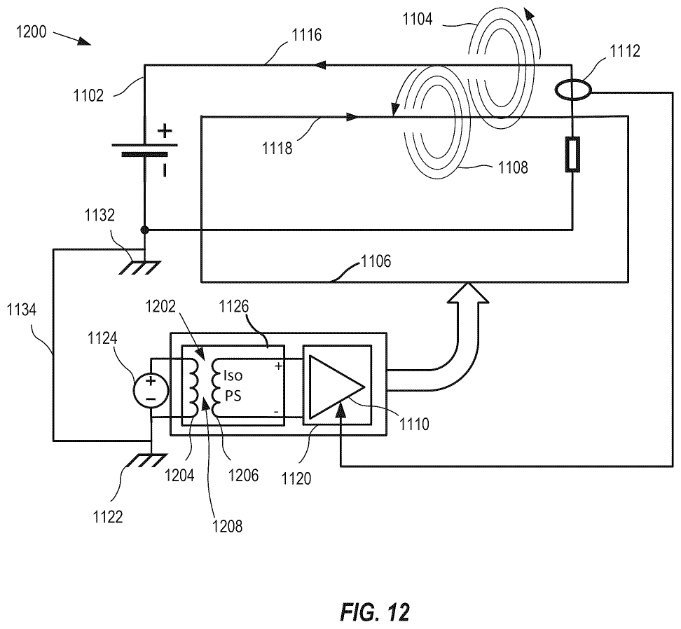

By way of another non-limiting example, reference is made to FIG. 12, illustrating another exemplary system 1200 for powering a cancelling field in a passenger cabin of a vehicle, consistent with some disclosed embodiments. System 1200 is substantially similar to system 1100 with the notable difference of at least one isolation transformer 1202 associated with gaps 1130 and 1128 of FIG. 11. At least one isolation transformer 1202 may electrically isolate an output of isolated power supply 1126 and/or isolate amplifier 1110 from power source 1124 connected to electrical ground 1122 of vehicle 200. Power source 1124 may output a DC current to isolated power supply 1126. Isolated power supply 1126 may convert the DC current to an AC current. The AC current may flow towards a first coil 1204 of at least one isolation transformer 1202. The AC current may generate a magnetic field in a gap 1208 separating first coil 1204 from a second coil 1206. The magnetic field in gap 1208 may induce another AC current in second coil 1206, electrically isolated from first coil 1204. The AC current in second coil 1206 may be fed to isolated power supply 1126, which may modify the current before feeding the current to amplifier 1110. Absent a connection to vehicle ground 1122, isolated power supply 1126 and/or amplifier 1110 (and/or control unit 1120) may be connected to a floating ground.

In some disclosed embodiments, electrically isolating the amplifier is configured to reduce parasitic current leakage. Parasitic current leakage refers to current that may unintentionally escape from a conducting element of an electrical circuit and/or device to another conductor. It may occur due to imperfections in insulation, electrical isolation, improper grounding, corroded terminals, faulty wiring and/or relays, induction, and/or presence of any other unintended conductive path. For instance, parasitic current leakage may occur if two wires and/or circuits share a common ground, a common contact, and/or due to lack of sufficient insulation. Absent electrical isolation, some current flowing to and/or from the amplifier may leak to other wires, circuits and/or electrical components of the vehicle and generated an (e.g., parasitic) magnetic field. The magnetic field generated by parasitic leakage may be substantially aligned and in the same direction as an aggressor magnetic field, and/or non-opposite to an aggressor magnetic field, as discussed earlier. Electrically isolating the amplifier and/or the power supply feeding the amplifier may prevent occurrence of paths for parasitic leakage and thereby prevent generation of non-cancelling magnetic field radiation.

In some disclosed embodiments, electrically isolating the amplifier prevents formation of a ground loop configured to generate non-cancelling magnetic field radiation. A ground loop may refer to a difference in potential between two different grounds in an electrical system, permitting current to flow from a ground at a higher potential to a ground at a lower potential. Additionally or alternatively, a ground loop may refer to one or more circulating currents that may arise when a plurality of grounding points (grounds) produce a difference in potential. Formation of a ground loop refers to introduction of two different non-electrically isolated grounds in an electrical system, causing current to flow from one ground to the other. This current may generate a magnetic field. If the current in the ground loop flows in the same direction as current in an AC aggressor loop, a magnetic field generated by the ground loop may have the same direction as an aggressor magnetic field and contribute to non-cancelling magnetic field radiation. Electrically isolating an amplifier feeding an AC cancellation loop may isolate a ground for the amplifier from a ground for the AC aggressor loop (e.g., the vehicle ground). This may prevent formation of a ground loop permitting current to flow between the vehicle ground and the ground for the amplifier and prevent generation of non-cancelling magnetic field radiation, and may contributed to mitigating an above-threshold level of aggressor magnetic field radiation in the passenger cabin of the vehicle.

By way of a non-limiting example, in FIG. 11 or 12, electrically isolating amplifier 1110 and/or power supply 1126 from vehicle ground 1122 may reduce parasitic leakage, e.g., by preventing current associated with power supply 1126 from travelling via path 1134 towards AC aggressor loop 1102. In some embodiments, electrically isolating amplifier 1110 may prevent formation of a ground loop (e.g., path 1134 connecting vehicle ground 1122 with vehicle ground 1132) which, absent the electrical isolation, may generate non-cancelling magnetic field radiation, e.g., due to AC current from power supply 1126 escaping via path 1134 towards AC aggressor loop 1102.

Some disclosed embodiments involve ferromagnetic shielding material between the AC aggressor loop and the passenger cabin for attenuating the aggressor magnetic field generated by the AC aggressor loop. Ferromagnetic shielding material may be understood as described elsewhere herein. Placing a layer of ferromagnetic material (e.g., passive magnetic field cancellation) interposed between an AC aggressor loop and the passenger cabin may block and/or otherwise prevent at least some of the AC aggressor magnetic field from entering the passenger cabin, e.g., by absorbing and/or deflecting some of the aggressor magnetic field radiating. The ferromagnetic shielding may further reduce a residual magnetic radiation remaining after cancellation by the AC cancellation loop (e.g., active magnetic field cancellation). For example, if (e.g., active) cancellation by the AC cancellation loop reduces the AC aggressor magnetic field by 75%, leaving 25% of the AC aggressor magnetic field, ferromagnetic shielding passively blocking 70% of a magnetic field may permit only 7.5% of the AC aggressor magnetic field to enter the passenger cabin. Ferromagnetic shielding between the AC aggressor loop and the passenger cabin may compensate for a mismatch between the cancellation magnetic field and the aggressor magnetic field and may ensure that magnetic field radiation inside the passenger cabin remains below a threshold value. In some embodiments, cancellation of the AC aggressor magnetic field using an AC cancellation loop (e.g., active cancellation) may ensure that magnetic radiation within the passenger cabin remains below a threshold value using less ferromagnetic shielding (e.g., less passive cancellation) than absent the AC cancellation loop. This may reduce the weight of the vehicle and improve fuel efficiency without exceeding safety thresholds for magnetic field radiation in a passenger vehicle.

By way of a non-limiting example, in FIGS. 2A-2B and FIG. 11, ferromagnetic shielding material 240 may be inserted between AC aggressor loop 1102 (e.g., corresponding to one or more of wire cables 216, 218, 238, and/or 230) and passenger cabin 224 to attenuate aggressor magnetic field 1104 (corresponding to aggressor magnetic field 220). Ferromagnetic shielding material 240 may block and/or absorb at least some of aggressor magnetic field 1104. In some embodiments, cancellation magnetic field 1108 may cancel a first portion of aggressor magnetic field 1104 and ferromagnetic shielding material 240 may block an additional portion of aggressor magnetic field 1104 such that any remaining aggressor magnetic radiation entering passenger cabin 224 may remain below a threshold level.

In some disclosed embodiments, at least partially cancelling the aggressor magnetic field includes mitigating an above threshold level of aggressor magnetic field in the passenger cabin. An above threshold level of aggressor magnetic field in a passenger cabin may refer to an aggressor magnetic field excessing and/or surpassing a threshold level, as described elsewhere herein. Mitigating an above threshold level of aggressor magnetic field in a passenger cabin refers to preventing and/or reducing an aggressor magnetic field inside a passenger cabin from exceeding and/or surpasses a threshold level, as described elsewhere herein. For example, absent at least partial cancellation, an aggressor magnetic field above a threshold level may radiate into the passenger cabin and pose a safety hazard to any passengers residing therein. At least partially cancelling the aggressor magnetic field may remove a sufficient amount of the aggressor magnetic field such that any remaining aggressor magnetic field permitted to radiate into the passenger cabin may be below a threshold level. In some disclosed embodiments, the threshold level is set to conform to a safety guideline for radiation exposure. To conform refers to comply, satisfy, and/or uphold. A safety guideline (e.g., a recognized guideline) for radiation exposure may refer to an accepted standard and/or recommendation for protecting humans from adverse health effects caused by immersion and/or contact with potentially hazardous levels of magnetic radiation. For example, a safety guideline may include one or more of the ICNIRP (1998), ICNIRP (2010), and/or ICNIRP (2020) guidelines.

By way of a non-limiting example, in FIG. 11, at least partially cancelling aggressor magnetic field 1104 (e.g., by generating cancellation magnetic field 1108) may mitigate an above threshold level of aggressor magnetic field in passenger cabin 224 (see FIG. 2B). The threshold level may be set to conform with any of ICNIRP (1998), ICNIRP (2010), and/or ICNIRP (2020). For example, cancelling 70% of aggressor magnetic field 1104 may be sufficient to conform with ICNIRP (1998). Thus, amplifier 1110 may output cancellation current 1118 to generate cancellation magnetic field 1108 to cancel 70% of aggressor magnetic field 1104. In some embodiments, cancelation of more than 70% of aggressor magnetic field 1104 may be unnecessary and may consume more power than needed.

Some disclosed embodiments involve an isolation transformer including a first coil, a second coil, and a dielectric barrier electrically isolating the second coil from the first coil. A coil (of an isolation transformer) refers to a winding of wire. It may include, for example, a conductive wire twisted into a helical shape, including a plurality of loops and/or turns. In some embodiments, a coil may include only one (e.g., a single) loop or turn. Causing an AC current to flow through a conductive coil may induce a fluctuating magnetic field. A coil of a transformer may be referred to as an inductor. A transformer refers to a device that transfers electric energy as an alternating-current circuit from a first conducting wire to second conducting wire via electromagnetic induction. A transformer may include two inductors (e.g., a first or primary coil and a second or secondary coil) galvanically isolated from each other. A first AC current at a first voltage flowing through the first coil may generate a fluctuating magnetic field. An (e.g., magnetic) core located between the two inductors may concentrate and/or guide the magnetic field generated by the first coil to permit interaction of the magnetic field with the second coil. The interaction may induce a second AC current in the second coil at a second voltage, while avoiding electrically conductive contact between the first coil and the second coil (e.g., current does not directly flow between the first coil and the second coil). The ratio between the first voltage and the second voltage may correspond to the ratio of the number of turns in the first coil versus the number of turns in the second coil (e.g., in a step up or a step down transformer). If the number of turns in the first coil and the second coil are the same, the ratio between the first voltage and the second voltage may be one to one (1:1). A dielectric barrier refers to an insulating material for preventing and/or limiting flow of electric current. Inserting a dielectric barrier between two electrical conductors may prevent current flowing through one of the electrical conductors from flowing in the other one of the electrical conductors (e.g., via arcing or sparking). A dielectric barrier may be made from silicone, mylar tape, glass, ceramics, or polymers, and/or any other insulating material. An isolation transformer refers to a transformer that electrically separates an input current from an output current by providing galvanic isolation between the first (e.g., primary) coil and the second (e.g., secondary) coil. An isolation transformer may transfer electrical power through magnetic induction (e.g., based on Faraday's law of induction), absent a direct conductive path and/or electrical contact between the first coil and the second coil and may permit transfer of electrical energy between two electrically isolated circuits and/or systems. For example, a core of an insulation transformer may be made of laminated sheets of silicon steel and may be coated with an insulating material such as epoxy, lacquer, enamel, and/or insulating varnish and/or tape to prevent an electrical current from flowing through the core. Electrical insulation between the first coil and the second coil of an isolation transformer may prevent formation of a direct conductive path between the first coil and the second coil and may ensure that current flowing in the second coil is attributable to induction by the fluctuating magnetic field, and not to electric conduction. An isolation transformer may thus facilitate insulation from noise, transient signals, and current leakage (e.g., via a common ground). In some embodiments, an isolation transformer may not change a voltage, e.g., the isolation transformer may not step up or step down the signal, but may solely electrically isolate an aggressor current associated with a vehicle ground from a cancellation current fed to an AC cancellation loop. In some embodiments, an isolation transformer step up or step down a voltage in addition to electrically isolating an aggressor current associated with a vehicle ground from a cancellation current fed to an AC cancellation loop.

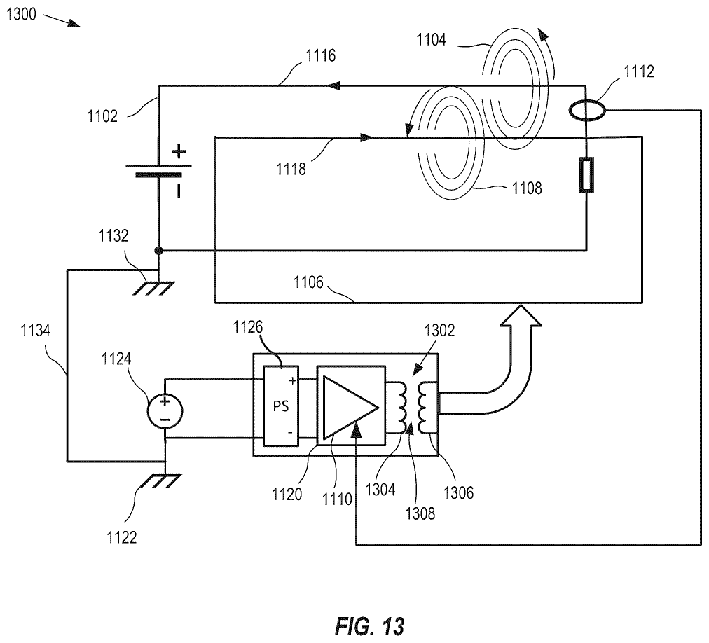

By way of a non-limiting example, reference is made to FIG. 13 illustrating another exemplary system 1300 for powering a cancelling field in a passenger cabin of a vehicle using an isolation transformer, consistent with some disclosed embodiments. System 1300 may be substantially similar to system 1100 and system 1200 illustrated in FIGS. 11 and 12 with the noted difference of an isolation transformer 1302 located between amplifier 1110 and AC cancellation loop. Isolation transformer 1302 may include a first coil 1304, a second coil 1306, and a dielectric barrier 1308 electrically isolating second coil 1306 from first coil 1304.

Some disclosed embodiments involve an amplifier configured for electrical connection to an electrical ground associated with the vehicle and to the first coil of the isolation transformer and to supply a first AC current to the first coil. A first coil of an isolation transformer may refer to a primary coil, as described above. An amplifier configured for electrical connection to an electrical ground associated with the vehicle refers to a wire and/or electrical contact connecting the amplifier to an electrical ground of the vehicle (as described earlier). An amplifier configured for electrical connection to the first coil of the isolation transformer and to supply a first AC current to the first coil refers to a wire and/or electrical contact connecting an output of the amplifier to an input of the first coil, such that an AC current outputted by the amplifier flows through the first coil of the isolation transformer. In some embodiments, the AC aggressor loop may also be associated with the electrical ground of a vehicle as well.

By way of a non-limiting example, in FIG. 13, amplifier 1110 may be electrically connected to electrical ground 1122 associated with the vehicle (e.g., vehicle 200 in FIG. 2) and to first coil 1304 of isolation transformer 1302. Amplifier 1110 may receive a current from power supply 1126 and may supply a first AC current to first coil 1304, e.g., based on signals received from sensor 1112 indicative of AC aggressor current 1116.

In some disclosed embodiments, the electrically isolated second coil is configured to conduct a second AC current induced from the first AC current via the isolation transformer and supply the second AC current to power the AC cancellation loop. An electrically isolated second coil (e.g., of an isolation transformer) may refer to a secondary coil, as described above. An electrically isolated second coil configured to conduct a second AC current induced from the first AC current via the isolation transformer refers to a core of the isolation transformer guiding a fluctuating magnetic field cause by the first AC current flowing through the primary coil towards the secondary coil. The fluctuating magnetic field may induce a second AC current in the secondary coil corresponding to the first AC current, but electrically isolated therefrom. This may prevent current associated with the AC aggressor loop from seeping or leaking into the AC cancellation loop, which may lead to non-cancelling magnetic field radiation, as described earlier. In some embodiments, this may prevent at least some AC cancellation current from leaking into parasitic paths and/or loops and becoming an AC aggressor current and/or otherwise interfere with mitigation of aggressor magnetic field radiation in a passenger cabin.

In some disclosed embodiments, the amplifier is electrically isolated from the electrical ground associated with the vehicle to reduce generation of non-cancelling magnetic field radiation. Electrically isolating an amplifier from the electrical ground of the vehicle may prevent formation of one or more unintended conductive paths (e.g., via a common ground). Such unintended paths may conduct undesired currents and generate undesired magnetic fields (e.g., additional aggressor magnetic fields and/or other non-cancelling magnetic fields), as discussed earlier.

In some disclosed embodiments, the electrical ground associated with the vehicle includes a vehicle chassis. An electrical ground associated with a vehicle chassis refers to an electrical ground electrically connected to a vehicle chassis, such that the vehicle chassis may serve as a return path and/or ground for electrical components in the vehicle. For example, an aggressor loop, vehicle power supply, and/or other electrical components of a vehicle may be electrically connected to the vehicle chassis. In some embodiments, a portion of the AC aggressor loop includes a vehicle chassis, as described earlier.

By way of a non-limiting example, in FIG. 13, electrically isolated second coil 1306 may conduct a second AC current induced from the first AC current flowing in first coil 1304 via isolation transformer 1302. The first AC current flowing through first coil 1304 may generate a fluctuating magnetic field in the space between first coil 1304 and second coil 1306. The fluctuating magnetic field may induce AC cancellation current 1118 in second coil 1306, which may supply AC cancellation current 1118 to power AC cancellation loop 1106. In this manner, AC cancellation loop 1106 may be electrically isolated from electrical ground 1122 and/or ground 1132 of vehicle 200 to reduce generation of non-cancelling magnetic field radiation, as described earlier. For instance, electrically isolating AC cancellation loop 1106 may prevent portions of cancelation current 1118 from leaking to other wires, circuits and/or components and generating a non-cancelling magnetic field, and may similarly prevent portions of AC aggressor current 1116 from leaking into AC cancellation loop 1106. In some disclosed embodiments, electrical ground 1122 and/or ground 1132 may be associated with vehicle chassis 202 of FIG. 2A. In some disclosed embodiments, a portion of AC aggressor loop 1102 may include vehicle chassis 202.

In some disclosed embodiments, the AC cancellation loop includes a plurality of wire turns. A plurality of wire turns refers to a coiled, twisted, and/or solenoid shaped wire having multiple windings and/or loops arranged in a helical and/or cylindrical shaped, as described elsewhere herein. In some embodiments, an AC cancellation loop including a plurality of turns may refer to one or more wires associated with the AC cancellation loop wound N times around a sensor measuring an indication of a cancellation current. Such an arrangement may result in an indication for a cancellation current having an amplitude that is N-times larger than the actual amplitude of the cancellation current flowing through the one or more wires associated with the AC cancellation loop. In other words, the actual amplitude of the cancellation current may be a factor of N less than the measured amplitude of the cancellation current, due to the sensor measuring the same cancellation current N times (e.g., one measurement per turn around the sensor). To achieve a target cancelling magnetic field for at least partially cancelling an aggressor magnetic field, an amplifier outputting the AC cancellation current may account for the N-fold discrepancy, e.g., by increasing the outputted cancelling current N-fold. Additionally or alternatively, in some embodiments, an AC cancellation loop including a plurality of turns may refer to one or more wires associated with the AC cancellation loop forming M loops, each loop generating a cancelling magnetic field corresponding to the cancellation current flowing therethrough, such that a net cancelling magnetic field generated by the AC cancellation loop may be M-fold greater than a cancelling magnetic field generated by an AC cancellation loop having only one wire turn (e.g., a single loop) with the same cancellation current flowing therethrough. To produce a target cancelling magnetic field for at least partially cancelling an aggressor magnetic field, an amplifier outputting the AC cancellation current may account for the M-fold discrepancy, e.g., by decreasing the outputted cancelling current by a factor of 1/M, e.g., thereby achieving substantially the same effective magnetic field cancellation using less current to conserve power. In some embodiments, an amplifier may be calibrated in advance to account for N wire turns of a portion of an AC cancellation loop around a sensor, and/or M wire turns of a portion of the AC cancellation loop, each generating a corresponding cancelling magnetic field, e.g., by outputting a cancellation current having an amplitude that is a factor of N/M times the amplitude of the cancellation current indicated by the sensor.

In some disclosed embodiments, the AC aggressor loop includes a plurality of wire turns. In some embodiments, an AC cancellation loop including a plurality of turns (as described elsewhere herein) may refer to one or more wires associated with the AC aggressor loop wound X times around a sensor measuring an indication of an aggressor current associated with vehicle operation. Such an arrangement may result in an indication for an amplitude of the aggressor current that is X-times greater than the actual amplitude of the aggressor current. In other words, the actual amplitude of the aggressor current flowing in the AC aggressor loop may be a factor of X less than the amplitude of the aggressor current measured by the sensor due to the sensor measuring the same aggressor current X times (e.g., one measurement per turn around the sensor). An amplifier outputting a cancellation current to generate a cancelling magnetic field at least partially cancelling an aggressor magnetic field generated by the measure aggressor current may account for the X-fold discrepancy, e.g., by outputting a cancelling current greater by a factor of X than the aggressor current flowing in the AC aggressor loop. In some embodiments, an amplifier may be calibrated in advance to account for X wire turns of a portion of an AC aggressor loop around a sensor, e.g., by outputting a cancellation current having an amplitude that is a factor of 1/X times the amplitude of the aggressor current indicated by the sensor, e.g., and corresponding to the actual amplitude of the aggressor current flowing the AC aggressor loop.

By way of a non-limiting example, FIG. 5 illustrates a wire 512 forming a plurality of wire turns around a sensor 504. In some embodiments, wire 512 may be associated with AC cancellation loop 1106 of any of FIGS. 11-13. For instance, AC cancellation loop 1106 may form a plurality (e.g., N) of wire turns around a sensor. Consequently, the cancellation current measured by sensor 504 may be N times the actual amplitude of the cancellation current 1118 flowing through AC cancellation loop 1106 (e.g., the actual amplitude of cancellation current 1118 may be less than the measured amplitude by a factor of 1/N). Amplifier 1110 may adjust the amplitude of output cancellation current 1118 to account for the discrepancy, e.g., by increasing any adjustment to cancellation current 1118 by a factor of N.

In some embodiments, wire 512 may be associated with AC aggressor loop 1102 of any of FIGS. 11-13. For instance, AC aggressor loop 1102 may form a plurality (e.g., X) of wire turns around sensor 504 and/or sensor 1112. Consequently, the aggressor current measured by sensor 504 may be X times greater than the actual AC aggressor current 1116 flowing through AC aggressor loop 1102 (e.g., the actual amplitude of aggressor current 1116 may be less than the measured amplitude by a factor of 1/X). In some embodiments, amplifier 1110 may be calibrated to adjust an amplitude of cancellation current 1118 corresponding to aggressor current 1116 to account for the discrepancy caused by the plurality of wire turns of AC aggressor loop 1102 around the sensor, e.g., by decreasing any adjustment to cancellation current 1118 by a factor of 1/X.

In some embodiments, a portion of AC aggressor loop 1102 and/or a portion of AC cancellation loop 1106 may be wound around one or more sensors 504 such that the ratio of the number of wire turns of each AC aggressor loop 1102 and AC cancellation loop 1106 around one or more of sensors 504 corresponds to a desired percent cancellation of aggressor magnetic field 1104 (e.g., 50%, 55%, 60%, 65%, 70%, 75%, 80%, 85%, 90%, or 95% cancellation). For instance, winding a portion of AC aggressor loop 1102 four (4) times around a first one of sensor 504 and winding a portion of AC cancellation loop 1106 five (5) times around a second one of sensor 504 may permit amplifier 1110 to output cancellation current 1118 at a level causing cancelling magnetic field 1108 to cancel approximately four fifths (⅘) (e.g., 80%) of aggressor magnetic field 1104. Similarly, any other fraction of cancellation may be achieved by winding a portion of the AC aggressor loop a first plurality of turns around at least one sensor and winding a portion of the AC cancellation loop a second plurality of turns around the at least one sensor, where the fraction of cancellation may be proportional to a ratio between the first plurality of turns and the second plurality of turns. This may be achieved without use of one or more processors to control the output of amplifier 1110 (e.g., using purely analog components), which may reduce response times and/or eliminate one or more latencies.

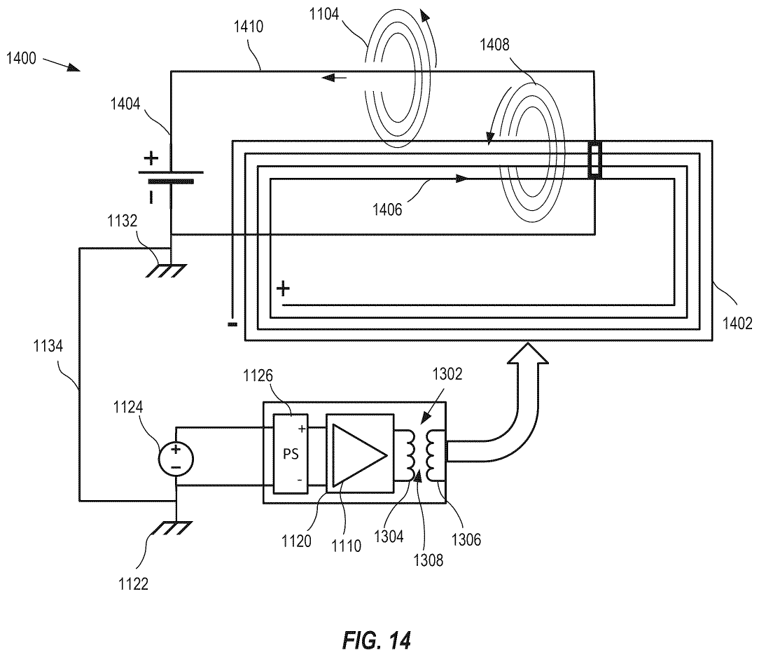

By way of another non-limiting example, reference is made to FIG. 14 which illustrates a system 1400 for powering a cancelling field in a passenger cabin of a vehicle including a plurality of wire turns, consistent with some disclosed embodiments. System 1400 is substantially similar to system 1300 of FIG. 13, with the noted difference of an AC cancellation loop 1402 (corresponding to AC cancellation loop 1106) including a plurality (e.g., four) of wire turns. Consequently, an AC cancellation current 1406 flowing through AC cancellation loop 1402 that is substantially similar to AC cancellation current 1118 may generate a cancelling magnetic field 1408 having a magnitude four times as large as the magnitude of cancelling magnetic field 1108. Amplifier 1110 may output cancellation current 1406 to account for the plurality of wire turns of AC cancellation loop 1402.

Some disclosed embodiments involve a juvenile car seat. A juvenile car seat refers to a child safety seat designed to protect infants and young children during vehicle travel. By way of example, a juvenile car seat may include a child restraint system, or CRS that supports and/or restrains a child in a vehicle, e.g., to protect the child from injury due to vehicle motion and/or collision. A juvenile car seat may be integrated into a vehicle as sold, or may be manufactured separately from a vehicle and installed temporarily or permanently after the vehicle is purchased. A juvenile car seat may be secured to a seat of a vehicle using a vehicle safety belt system, a Lower Anchors and Tethers for Children (LATCH) system, and/or any other fastener suitable for securing a juvenile car seat to a seat of a vehicle. In some embodiments, a juvenile car seat may include a detachable base (e.g., a click-in base) that may be installed in a car, separate from a main body of the car seat. The detachable base may remain fastened to a seat of the car, permitting to detach and re-attach a portable main body of the juvenile car seat. Some types of juvenile car seats may include a rear-facing car seat, a forward-facing car seat, a convertible car seat, a booster seat, and/or any other type of portable mechanism for securing a child in a vehicle. A rear-facing car seat may include a basin for supporting and/or restraining a newborn and/or infant, and may cradle a child within a cavity of the basin in a reclining position and distribute crash forces across the back side of the car seat. A forward-facing car seat may include an upright seat for supporting and/or restraining a toddler and/or pre-school child, e.g., after a child outgrows a rear-facing car seat. A convertible car seat may include an adjustable basin that may be installed in a rear-facing reclining position to accommodate an infant and/or a front-facing upright position to accommodate a toddler, and may permit transitioning from the rear-facing installation to the front-facing installation. A forward-facing, rear-facing, and/or convertible car seat may include a five-point harness for securing a child within the seat at the shoulders, hips, and between the legs. A booster seat may elevate a child in a seated position to permit correct and/or secure fitting of a safety belt of a vehicle over the shoulder and lap of the child. In some embodiments, a booster seat may include metal reinforcements, such as a metallic base plate. Some juvenile car seats may include a handle for portability. In some embodiments, a booster seat may lack metallic reinforcements.

Some disclosed embodiments involve a main body. A main body of a juvenile car seat refers to a rigid structure for at least partially encasing, surrounding, or cradling an infant or child. The main body may include a rigid shell made of durable, lightweight, and high-density, impact-resistant plastic, such as high-density polyethylene or polypropene) for absorbing crash forces in case of a collision. Any other suitable material may be used. Suitable materials include any material that balances impact resistance, strength, durability, and manufacturing feasibility. Non-limiting examples of suitable materials for making more rigid portions of a juvenile car seat (such as the main body) include polypropylene, ABS (acrylonitrile butadiene styrene), polycarbonate, high-density polyethylene (HDPE), glass-fiber reinforced plastics such as reinforced polypropylene or nylon, and metals like steel or aluminum for internal reinforcements.

In the case of a rear-facing, front-facing, and/or convertible car seat, a main body may include a rigid shell molded to form a concave, cocoon-like bucket and/or basin for holding an infant, and/or a seat for holding a toddler. A main body of a rear-facing, front-facing, and/or convertible car seat may include one or more of a seat bottom, wings located on the sides and/or upper region for supporting a child's head, and/or a seat back to support a child in a seated and/or reclined position. In the case of a booster seat, a main body main include a base and/or platform for elevating a child in a seated position, and side wings and/or a back wing to secure the child on the base. A main body may additionally include one or more metallic reinforcing components made of durable metal such as steel and/or reinforced metal alloys. The metallic reinforcing components may include an internal metal frame (e.g., a subframe), one or more support bars embedded in and/or otherwise attached to the rigid shell to reinforce the structural integrity of the shell and enhance crash protection, and/or one or more metal (e.g., steel) plates embedded under the shell. Additional metallic components included in a juvenile car seat may include one or more buckles for a harness system, metallic components associated with a reclining mechanism, and/or one or more connectors (e.g., LATCH connectors) for securing a juvenile car seat to a seat of a vehicle. In some embodiments, a main body may be covered with one or more layers of padding and/or fabric for comfort.

Some disclosed embodiments involve a side wing extending from a side of the main body. Extending refers to projecting, protruding, and/or overhanging. A side of a main body refers to an edge and/or border of a main body of a car seat. The main body may include a basin and/or concave central region, and raised edges and/or sides peripheral to the central region for securing a child within the central region. Thus, sides of a main body may align at least partially with the external surfaces of the arms and/or legs of a child when the child is secured within the juvenile car seat. A side wing refers to an appendage and/or a protrusion jutting out from, lengthening and/or widen a side of a main body of a juvenile car seat. A side wing may provide lateral body support and prevent sideward movement of an occupant of a juvenile car seat. In some embodiments, a side wing may be adjustable to permit adjustment of a space enclosed by one or more side wings and a seat bottom and/or seat back (e.g., backrest). A side wing may be made of any suitable material, such as a high-density, impact-resistant plastic and may include one or more metallic support bars, plates, sheets, mesh, and/or any other metallic reinforcement embedded therein. In some embodiments, a main body and side wings may be integrally formed of molded high-density, impact-resistant plastic.

Some embodiments involve a first side wing extending from a right side of the main body and a second side wing extending from a left side of the main body. A side wing extending from a right side of a main body may be understood to mean a side wing attached to or integral with a right edge or right region of the main body. In some examples, an internal face of the side wing is flush against an external surface of a right arm, a right leg, and/or a right side of a torso of a child seated in the juvenile car seat. A side wing extending from a left side of a main body may be understood to mean a side wing integral with or attached to a left edge portion of the main body. In some embodiments, an internal face of the side wing is flush against an external surface of a left arm, a left leg, and/or a left side of a torso of a child seated in the juvenile car seat. A right side wing and a left side wing extending from sides of a main body may enclose a space defined by a bottom and/or back of the car seat and the side wings for securing a child. When a child is secured in the juvenile car seat, a right side of the child may be restrained by the first side wing, and the left side of the child may be restrained by the left side wing, preventing the child from exiting the enclosed space, e.g., due to a collision, sudden vehicular motion, and/or attempt by the child to stand or roll out. In some embodiments, a side wing may include one or more layers of foam, padding and/or fabric for comfort.

Some disclosed embodiments involve a headrest area extending from a top portion of the main body between upper portions of the first side wing and the second side wing. A top portion of a main body of a juvenile car seat refers to an upper section of the car seat when the car seat is in an upright orientation. A top portion of the main body may align with an upper torso, shoulders, and/or head of a child when the child is secured in the car seat. The top portion may be made of durable high density plastic or other suitable material, may include an internal metal frame, as described above, and may be covered with one or more layers of padding and/or fabric for comfort. A headrest area (e.g., a head restraint area) of a juvenile car seat refers to a upper region for restraining or limiting head motion of an occupant of the car seat. A headrest may be integrated with and/or attached to a top portion of a car seat to limit head and/or neck motion, for preventing whiplash, head injuries, and/or spinal injuries due to vehicle motion and/or collisions. A headrest may prevent rearward and/or sideward motion of a head in a front-facing car seat and/or sideward motion of a head in a rear-facing car side. In some embodiments, a headrest may include one or more head wings protruding from the main body (and/or the headrest) to enclose a space for a child's head thereby preventing or limiting sideward motion of the head. A head rest may be made of durable high density plastic or any other suitable material, and may include an internal metal frame and/or reinforcing metal bars, as described above. A headrest area may include energy-absorbing foam to protect the head during an impact (e.g., front impact, rear impact, and/or side impact).

In some disclosed embodiments, the main body, the first side wing, the second side wing, and the headrest area form a child-holding concavity. Concavity refers to a basin, hollow, and/or recess. It may refer to a shape or a surface that curves inward rather than outward. For example, a concavity may refer to a surface or object that bends or curves inward to form a hollow or recessed area. A child-holding concavity refers to a basin and/or hollow shaped and/or sized to fit or secure a child. For example, a child-holding concavity may be a recessed or inwardly curved structure that is shaped to accommodate or support an object-potentially a child, but not necessarily. Differing juvenile car seats may have differing child-holding concavities depending on an age, size, and/or development category of the car seat. A child-holding concavity may be formed by one or more of a seat back (e.g., a backrest), a seat bottom, a headrest and/or head wings, sides and/or side wings of the car seat, such that a child secured within the child-holding concavity of a juvenile car seat may be at least partially surrounded and/or enclosed by portions of the juvenile car seat. In other words, portions of a juvenile car seat (e.g., one or more of a seat back, seat bottom, headrest, and/or side wings) may form a physical barrier at least partially separating a child encased in a child-holding concavity of the car seat from areas in a passenger cabin external to the child-holding concavity.

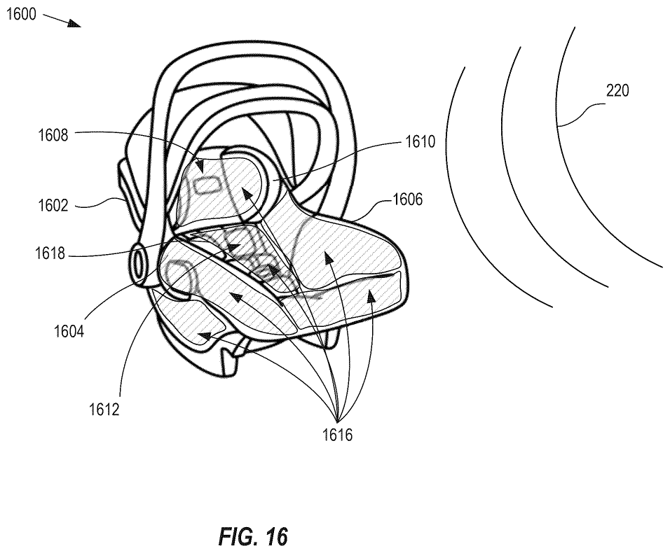

By way of a non-limiting example, reference is made to FIG. 16 illustrating an exemplary juvenile car seat 1600, consistent with some disclosed embodiments. For example, juvenile car seat 1600 may be suitable for securing an infant in vehicle 200. Juvenile car seat 1600 includes a main body 1602, a first side wing 1604 extending from a right side of main body 1602 and a second side wing 1606 extending from a left side of main body 1602. Juvenile car seat 1600 includes a headrest area 1608 extending from a top portion of main body 1602 between upper portions of first side wing 1604 and second side wing 1606. Headrest area 1608 may include one or more head wings 1610. Main body 1602, first side wing 1604, second side wing 1606, head rest area 1608, and/or head wings 1610 may be made of a hard plastic resin, and may be covered by one or more layers of foam and/or cushioning material. Main body 1602, first side wing 1604, second side wing 1606, and headrest area 1608 may form a child-holding concavity 1612.

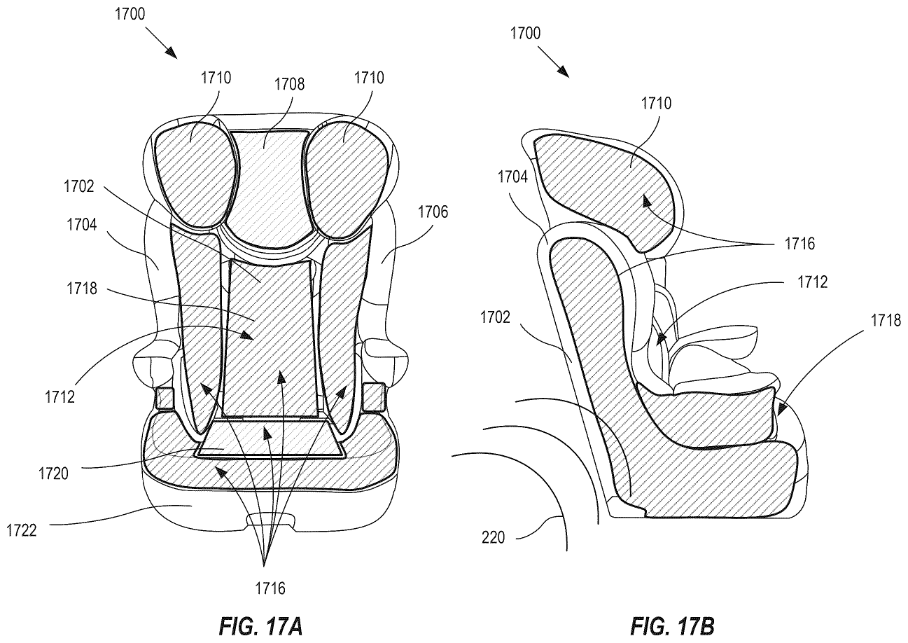

By way of a non-limiting example, reference is made to FIGS. 17A-17B illustrating front and side views of another exemplary juvenile car seat 1700, consistent with some disclosed embodiments. For example, juvenile car seat 1700 may be suitable for babies, toddlers, and/or may be a convertible car seat. Juvenile car seat 1700 includes a main body 1702, a first side wing 1704 extending from a right side of main body 1702 and a second side wing 1706 extending from a left side of main body 1702. Juvenile car seat 1700 includes a headrest area 1708 extending from a top portion of main body 1702 between upper portions of first side wing 1704 and second side wing 1706. Headrest area 1708 may include one or more head wings 1710. Main body 1702, first side wing 1704, second side wing 1706, head rest area 1708, and/or head wings 1710 may be made of a hard plastic resin, and may be covered by one or more layers of foam and/or cushioning material. Main body 1702, first side wing 1704, second side wing 1706, and headrest area 1708 may form a child-holding concavity 1712.

Some disclosed embodiments involve magnetic field shielding material associated with the child-holding concavity in a manner for rerouting magnetic field radiation away from the child-holding concavity. Magnetic field shielding material refer to materials for completely or at least partially protecting from magnetic fields. Such shielding materials may include substances capable of redirecting and/or containing magnetic fields, as described elsewhere herein. Some exemplary forms for magnetic field shielding material may include a thin sheet and/or roll of metal (e.g., foil) that can be cut and/or shaped and used to line an enclosure, cavity, or a rigid or semi-rigid body or housing (e.g., a cylinder, box, concavity and/or cannister). The material may be in the form of a single sheet, a laminated stack of layered ferromagnetic sheets, flexible adhesive tape including high-permeable foil and/or fabric, woven and/or braded wire mesh and/or fabric, a powdered and/or granular composite, a tube, a cylinder, and/or a rigid and/or flexible panel. In some disclosed embodiments, the magnetic shielding material includes at least one of Mu-Metal, Permalloy, soft iron, silicon steel, silicon steel GO (Grain Oriented), silicon steel NGO (Non Grain Oriented), electrical steel, transformer steel, ferrites, and/or Metglas, as described elsewhere herein. Magnetic field shielding material associated with the child-holding concavity refers to magnetic field shielding material located in a manner to at least partially block magnetic field radiation from entering the child-holding concavity or to otherwise protect the child in the child-holding cavity. Ferromagnetic material associated with a child-holding concavity of a juvenile car seat may be detachable from a hard shell of a car seat and/or permanently affixed thereto. Rerouting refers to diverting, redirecting, deflecting and/or reflecting. Away may be understood to mean in a different and/or opposite direction from a reference. For example, repelling and/or deflecting a magnetic field from a reference area may reroute the magnetic field away from the reference area. Rerouting magnetic field radiation away from a child-holding concavity may be understood to mean deflecting and/or repelling magnetic field radiation such that at least some or all of the magnetic field radiation does not enter the child-holding concavity. It may involve preventing and/or mitigating a substantial amount of magnetic field radiation present in a passenger cabin from entering the child-holding concavity, thereby completely or partially insulating a child secured within the concavity from magnetic field radiation present in the passenger cabin. Consequently, a child-holding concavity associated with magnetic field shielding material may define an insulated space (e.g., a bubble and/or cocoon) inside the passenger cabin where magnetic field radiation caused by vehicle operation is substantially mitigated. In some disclosed embodiments, the magnetic field radiation is electromagnetic field radiation, as described elsewhere herein.

For example, a resin and/or plastic used to manufacture one or more rigid sections of a juvenile car seat, such as a main body, one or more side wings and/or head wings may be mixed and/or infused with ferromagnetic granules. The manufacturing process may include injection molding, over-molding, and/or cast molding. Additionally or alternatively, ferromagnetic and/or magnetic field shielding material may cover and/or combined with one or more metallic frames and/or bars internal to a main body, one or more side wings and/or head wings (e.g., ferromagnetic material may be infused with the metal forming the frame and/or bars, one or more bars may be inserted into ferromagnetic tubes, and/or coated with ferromagnetic coating (e.g., paint, tape, foil, fabric, and/or mesh). Additionally or alternatively, at least part of a surface (e.g., including an upper, lower, inner, outer, and/or side surface) of a main body, side wings, head wings, and/or any other portion of a juvenile car seat may be coated with ferromagnetic paint, foil, mesh, tape, and/or fabric, e.g., using heat, pressure, and/or an adhesive.

Additionally or alternatively, ferromagnetic and/or magnetic field shielding material (e.g., a plate, mat, and/or sheet) may be associated with a base, a backrest and/or headrest of a juvenile car seat (e.g., a ferromagnetic mat and/or plate may be positioned above and/or below a car seat base, and/or in front and/or behind a car seat backrest and/or headrest such that a ferromagnetic layer is located between a child-holding concavity of the juvenile car seat and a back and/or bottom of a passenger seat of a vehicle). For instance, when installed on a passenger seat of a vehicle, a juvenile car seat may rest on and/or against a ferromagnetic mat, plate, and/or sheet. In some embodiments, a relatively thick sheet/layer of a ferromagnetic material may be used to shield a child-holding concavity from magnetic field radiation. For example, a relatively thick metallic (e.g., steel) layer man be manufactured using one or more of: stamping, bending, die forming, folding, shearing, press braking, roll forming, extrusion, forging, casting, punching, welding, cutting (laser, water, etc.), ironing, spinning, shaping, extrusion, sintering, injection/sand/wax molding, stretch forming, and/or any other process of manufacturing for metal. The relatively thick metallic layer may be integrated into a juvenile seat using mechanical fasteners (e.g., screws, rivets, plastic press-fit anchors, snap-in bosses molded into the plastic). Additionally or alternatively, a metallic layer may be integrated into a juvenile car seat via insert molding, where a metallic layer may be placed inside a mold, and plastic may be injected into the mold around the metallic layer. Additionally or alternatively, adhesive bonding may be used to integrate a metallic layer into a juvenile car seat.

Additionally or alternatively, ferromagnetic and/or magnetic field shielding material may be integrated and/or associated with an (e.g., metallic and/or detachable) base for a car seat. Additionally or alternatively, ferromagnetic and/or magnetic field shielding material (e.g., granules, mesh, foil and/or fabric) may be integrated with a foam and/or cushion layer of a juvenile car seat. These examples are provided for conceptual purposes only and are not intended to limit this disclosure, and any other technique for associating ferromagnetic and/or magnetic field shielding material with a child-holding concavity of a juvenile car seat may be similarly used. Associating magnetic field shielding material with a child-holding concavity may position magnetic field shielding material between a child located in the child-holding concavity and regions in the passenger cabin external to the child-holding concavity. For example, magnetic field shielding material may be positioned between a head, neck, torso, arms, and/or legs of a child seated in a child-holding concavity and regions in a passenger cabin external to the child-holding concavity.

By way of a non-limiting example, in FIGS. 16, juvenile car seat 1600 may include magnetic field shielding material 1616 associated with child-holding concavity 1612 in a manner for rerouting magnetic field radiation 220 away from child-holding concavity 1612. Magnetic field shielding material 1616 may reroute at least a portion of magnetic field radiation 220, thereby preventing and/or blocking the at least portion from entering child-holding concavity 1612. For example, magnetic field shielding material 1616 may coat (e.g., as paint and/or foil), cover (e.g., as one or more insert panels and/or mesh), and/or may be embedded within one or more hard plastic shell portions forming child-holding concavity 1612. Magnetic field shielding material 1616 may cover the shell portions on a side internal and/or external to child-holding concavity 1612. Consequently, magnetic field shielding material 1616 may substantially insulating child-holding concavity 1612 from magnetic field radiation 220. Magnetic field shielding material 1616 may include a single piece and/or a plurality of pieces of shielding material.

By way of another non-limiting example, in FIGS. 17A-17B, juvenile car seat 1700 may include magnetic field shielding material 1716 associated with child-holding concavity 1712 in a manner for rerouting magnetic field radiation 220 away from child-holding concavity 1712. Magnetic field shielding material 1716 may be associated with one or more of wings 1704 and 1706, headrest 1708, head wings 1710, a cushion 1718 associated with a back rest, a seat bottom 1720, and/or a car seat base 1722 of juvenile car seat 1700. Magnetic field shielding material 1716 may include one or more (e.g., stiff plates and/or mesh) panels, foil, paint, and/or may be infused in a hard plastic shell of juvenile car seat 1700. The magnetic field shielding material may reroute at least a portion of magnetic field radiation 220, thereby preventing and/or blocking the at least portion from entering child-holding concavity 1712. Magnetic shielding material 1616 and/or 1716 may include at least one of Mu-Metal, Permalloy, soft iron, silicon steel, silicon steel GO (Grain Oriented), silicon steel NGO (Non Grain Oriented), electrical steel, transformer steel, ferrites, and/or Metglas. In some embodiments, magnetic field radiation 220 may include electromagnetic field radiation. Magnetic field shielding material 1716 may include a single piece of shielding material (e.g., molded and/or shaped to conform to a shape of juvenile car seat 1700) and/or may include a plurality of pieces of shielding material.

Magnetic field shielding material may be inserted into a juvenile car seat at any stage of manufacturing. For example, magnetic field shielding material may be infused into one or more raw materials used to manufacture one or more sections of juvenile car seat for subsequent assembly, such as foam, fabric, plastic, resin, and/or metal. Magnetic field shielding material may be added to one or more manufactured sections of a juvenile car seat (e.g., a hard shell, one or more wings, a base, a backrest) for subsequent assembly as a coating (e.g., a paint, mesh, and/or foil coating). Magnetic field shielding material may be added to an assembled juvenile car seat, e.g., as an insert beneath one or more cushions, beneath a car seat base, and/or behind a car seat back.

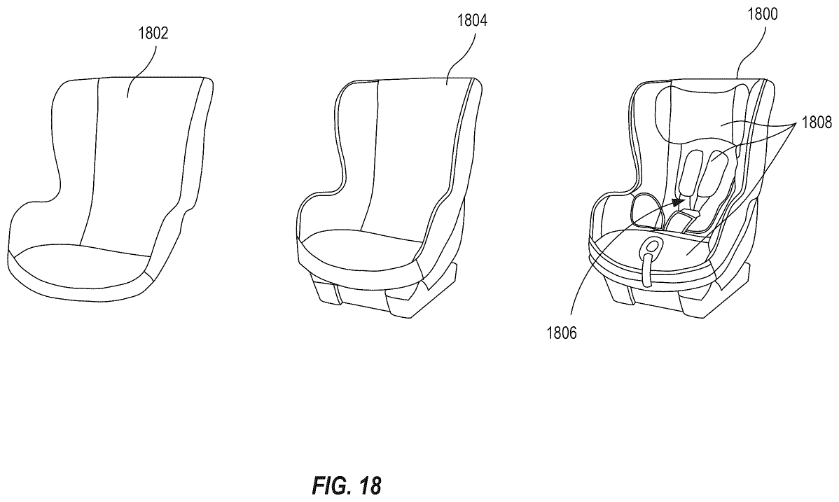

By way of a non-limiting example, reference is made to FIG. 18 illustrates an exploded view of another exemplary juvenile car seat 1800, consistent with some disclosed embodiments. Juvenile car seat 1800 may include a ferromagnetic shield 1802 made of ferromagnetic shielding material shaped to fit and/or drape over a rigid shell 1804 of juvenile car seat 1800 such that one or more cushions and/or padding 1808 may cover ferromagnetic shield 1802. For example, ferromagnetic shield 1802 may include ferromagnetic paint coating rigid shell 1804, and/or one or more layers of ferromagnetic foil and/or ferromagnetic mesh covering rigid shell 1804. Ferromagnetic shield 1802 may be associated with a child-holding concavity 1612 in a manner for rerouting magnetic field radiation 220 away from a child-holding concavity 1806.

In some disclosed embodiments, the shielding material is flexible. Flexible refers to pliable, bendable, and/or malleable. Shielding material that is flexible may be bendable, pliable, elastic, and/or otherwise adaptable to take on a variety of contoured and/or convoluted forms without breakage and/or cracking. For example, flexible may refer to the ability to bend, adapt, or change without breaking or losing functionality. Flexible ferromagnetic shielding material may include ferromagnetic foil, paint, mesh, fibers (e.g., wires), and/or fabric, as described above. In some embodiments, ferromagnetic shielding material may be infused into a flexible material included in a juvenile car seat, such as (e.g., energy-absorbing) foam and/or fabric. For example, ferromagnetic granules and/or powder may be mixed with Expanded Polystyrene (EPS) foam beads, and/or mixed with Expanded Polypropylene (EPP) foam configured to be formed into one or more foam panels and/or layers associated with a rigid shell of a juvenile car seat, e.g., using steam, pressure, and/or compression molding. Ferromagnetic wires and/or mesh may be woven into one or more foam inserts and/or one or more fabric covers of a juvenile car seat, and/or into webbing of one or more harness straps and/or belts.

By way of a non-limiting example, in FIGS. 16, and 17A-17B, one or more portions of magnetic field shielding material 1616 and/or 1716 may be flexible. For instance, magnetic field shielding material 1616 and/or 1716 may include a wire mesh and/or fabric wrapped over and/or covering portions of juvenile car seat 1600 and/or 1700, and/or infused into a foam material included in juvenile car seat 1600 and/or 1700.

In some disclosed embodiments, the shielding material is a ferromagnetic foil. Ferromagnetic foil refers to a thin sheet, film, and/or membrane of magnetic field shielding material. A material that is ferro magnetic may have a high susceptibility to magnetization, meaning they can become strongly magnetized when exposed to an external magnetic field. Often, they retain that magnetization even after the field is removed Ferromagnetic foil may include ferromagnetic mesh, ferromagnetic fabric, and/or a coating of ferro magnetic paint. Ferromagnetic foil may be sufficiently flexible for coating and/or covering one or more objects (e.g., as a foil blanket). Ferro magnetic foil may be applied to coat an object using a hot stamping process using heat and/or pressure to transfer the foil onto a surface, using one or more adhesives, by painting ferromagnetic paint onto a surface, and/or using any other process to apply a layer of ferromagnetic material onto a surface. In some disclosed embodiments, the ferromagnetic foil is at least 18 microns thick. A micron is a unit of measurement equivalent to one-millionth of a meter, or one thousandths of a millimeter. A micron may be used to measure very small objects. For example, a diameter of a human hair may be approximately 70 microns. At least 18 microns thick may be understood to mean that a depth and/or height measurement of a sheet of ferro magnetic foil may be 18 microns or greater. In some embodiments, the ferromagnetic foil may be at least 20 microns, at least 25 microns, at least 30 microns, at least 40 microns, or at least 50 microns thick. In some embodiments, a sheet of ferro magnetic foil may be less than 18 microns thick (e.g., less than 17 microns, less than 16 microns, or less than 15 microns thick). In some disclosed embodiments, the ferromagnetic foil includes at least two layers. At least two layers refers to at least two sheets, films, and/or plies. The ferromagnetic shielding material may include two or more sheets and/or plies of ferro magnetic foil, layered on top of each other. For example, each layer of ferromagnetic foil may be applied to coat one or more portions of a juvenile car seat in a separate heat and/or adhesive process, such that multiple layers of ferromagnetic foil coat the portions of the car seat. In some embodiments, each layer of ferromagnetic foil may be at least 18 microns thick. In some embodiments, a combined thickness of two or more layers of ferro magnetic foil may be at least 18 microns thick.

In some disclosed embodiments, the juvenile seat further includes a cushion thereon, and wherein the ferromagnetic foil is under the cushion. A cushion refers to an object or region filled with padding, stuffing, foam, and/or wadding. A cushion for a juvenile car seat may be designed to properly position a child in a car seat by ensuring a snug fit to prevent motion, and provide support and/or comfort. A cushion may provide a softer surface than a hard, plastic shell of a juvenile car seat and may insulate the child from vibrations and/or bumps. A juvenile seat including a cushion thereon refers to one or more cushions placed on a surface of a juvenile seat, and/or wrapped around an accessory of the juvenile car seat to prevent motion and/or absorb impact forces. For example, a head insert cushion may cover an (e.g., rigid) head wing and/or headrest of a car seat, a body cushion may cover a child-holding concavity to prevent bodily motion of a child, side wing cushions covering (e.g., rigid) side wings, seat padding located at a bottom of the car seat, one or more harness pads wrapped around one or more harness straps securing a child, and/or any other cushion and/or removeable padded insert included in a juvenile car seat. A cushion for a juvenile car seat may include expanded polystyrene (EPS) foam, expanded polypropylene (EPP) foam, and/or polyurethane foam, viscoelastic (e.g., memory) foam, one or more gel layers for cooling and/or comfort, one or more mesh panels to enhance airflow, one or more fabric covers (e.g., made from polyester knit, bamboo, and/or cotton blend fabric). A cushion may be placed directly on a hard shell of a car seat and/or or on another cushion placed directly on a hard shell. For example, a head rest cushion may be layered atop a body cushion which may rest on a hard plastic shell of the car seat, and one or more cushions may be wrapped on one or more straps for placing over the shoulders, across the torso, and/or between the legs of a child. Foil under a cushion refers to one or more layers of ferromagnetic material placed beneath a surface of a cushion of a juvenile car seat. For example, one or more layers of ferromagnetic foil may be placed on one or more non-cushioned surfaces (e.g., hard shell) of a car seat such that the foil may be sandwiched between the non-cushioned surface and one or more cushions resting thereon. As another example, one or more layers of ferromagnetic foil may be inserted between two or more cushion layers of a car seat, such that at least one cushion layer covers the ferromagnetic foil. As a further example, ferromagnetic foil may be wrapped around one or more nylon and/or polyester webbing harness straps of a car seat, and covered with one or more harness cushions, e.g., without interfering with a buckle mechanism to secure the child in the car seat. A child sitting on a cushion covering one or more layers of ferromagnetic foil in a juvenile car seat may not have direct contact with the ferromagnetic foil (e.g., for comfort), and the foil may at least partially intercept a magnetic field permeating into the passenger cabin, e.g., via the cabin floor, sides, front, and/or rear walls. For example, ferromagnetic foil may cover a surface of a plastic shell and/or wings defining a child-holding concavity of a car seat, such that the foil surrounds the head, back and/or sides of a child seated and/or reclined on one or more cushions covering the foil. The foil may thus prevent a magnetic field radiating into a passenger cabin through a vehicle floor and/or a passenger seat from entering the child-holding concavity. Similarly, one or more layers of foil may be inserted into a back and/or bottom of a car seat beneath a body cushion. In some embodiments, one or more layers of ferromagnetic foil may cover a removeable base connected to a seat of a vehicle, such that the ferromagnetic foil remains in the vehicle as a portable main body is detached and re-attached from the removeable base.

By way of a non-limiting example, in FIGS. 16, and 17A-17B, one or more portions of magnetic field shielding material 1616 and/or 1716 may include ferromagnetic foil. The ferromagnetic foil may include two or more layers of foil. Each sheet of foil may be less than 18 microns thick, e.g., such that magnetic field shielding material 1616 and/or 1716 may not add significant weight to juvenile car seat 1600 and/or 1700. In some embodiments, juvenile car seat 1600 and/or 1700 may include one or more cushions 1618 and 1718, respectively, and the ferromagnetic foil may be under one or more cushions 1618 and 1718.

In some disclosed embodiments, the main body, the first side wing, the second side wing and the headrest are molded with the shielding material therein. Molded refers to shaped, formed, and/or cast. Molded with shielding material therein may refer to combining and/or infusing material for forming a main body, side wings, and/or a head rest of a juvenile car seat with ferromagnetic shielding material such that the ferromagnetic shielding material is at least partially embedded within the main body, side wings, and/or a head rest. For example, ferromagnetic shielding material may be added and/or otherwise included in one or more metallic components of the main body, side wings, and/or a head rest, such as one or more reinforcement bars, plates, and/or frames, and/or one or more attachment buckles, latches, and/or hooks. In some disclosed embodiments, the main body, the first side wing, the second side wing and the headrest are molded of plastic with the shielding material embedded therein. Plastic refers to a petroleum based resin that may be shaped into a variety of differing forms. For example, plastic may be shaped to form a main body, side wings, and/or a headrest of a juvenile car seat using injection molding, steam and/or pressure molding, cast and/or die molding, and/or any other type of molding process for plastic. Plastic with shielding material embedded therein refers to plastic infused, mixed, and/or otherwise combined with ferromagnetic shielding material. For example, ferromagnetic shielding material may be added to (e.g., raw) plastic pellets and/or beads used to manufacture portions (e.g., a main body, side wings, and/or head rest) of a car seat prior to molding, such that following the molding process, the portions of the car seat include (e.g., are infused with) ferromagnetic shielding material. A mesh of ferromagnetic material, strips of ferromagnetic material, one or more sheets of ferromagnetic material (with our without perforations therein may be embedded in the plastic to imbue the resulting structure with ferromagnetic shielding capabilities.

By way of a non-limiting example, in FIG. 16, main body 1602, first side wing 1604, second side wing 1606, and headrest 1608 may be molded with ferromagnetic shielding material 1616. For example, ferromagnetic mesh may be added to a molding cast for one or more of main body 1602, first side wing 1604, second side wing 1606, and/or headrest 1608, such that the ferromagnetic mesh is embedded therein. In some embodiments, main body 1602, first side wing 1604, second side wing 1606, and headrest 1608 may be molded of plastic with embedded shielding material therein. For example, ferromagnetic powder may be added to a plastic beads used to manufacture one or more of main body 1602, first side wing 1604, second side wing 1606, and/or headrest 1608. In some embodiments, shielding 1616 may provide more than a four time improvement in magnetic field amplitude reduction in child-holding concavity 1612 than in an absence of shielding 1616. For example, an amplitude of magnetic field radiation 220 that may penetrate child-holding concavity 1612 (e.g., circumventing ferromagnetic field shielding material 1616) may be at least a quarter of the amplitude of magnetic field radiation 220 external to child-holding concavity 1612.

In some disclosed embodiments, the shielding is configured to provide more than a 4× improvement in magnetic field amplitude reduction in the child holding concavity than in an absence of the shielding. To provide refers to supply, furnish, permit, and/or enable. Magnetic field amplitude reduction in a child holding concavity refers to mitigation and/or attenuation of a strength, intensity and/or magnitude of a magnetic field within the child holding concavity. A four-time (4×) improvement in magnetic field amplitude reduction refers to a decrease in intensity of a magnetic field by a factor of at least four. In absence of the shielding refers to a situation where a juvenile car seat lacks ferromagnetic shielding material. For example, a first juvenile car seat having magnetic shielding material associated with a first child-holding concavity may be installed in a first vehicle and a second juvenile car seat lacking magnetic shielding material associated with a second child-holding concavity may be installed in a second vehicle, substantially similar to the first vehicle. During operation of the first and second vehicles, an amplitude of a first magnetic field associated with the first vehicle operation inside the first child-holding concavity may be four times lower than an amplitude of a second magnetic field associated with the second vehicle operation inside the second child-holding concavity. Consequently, a second child secured in the second child-holding concavity may be exposed to four times as much magnetic field radiation as a first child secured in the first child-holding concavity. In some embodiments, the shielding is configured to provide at least, as high as, and/or below a two-times (2×), three-times (3×), five-times (5×), or six-times (6×) improvement in magnetic field amplitude reduction in the child holding concavity than in an absence of the shielding.

Similarly, in FIGS. 17A-17B, main body 1702, first side wing 1704, second side wing 1706, and headrest 1708 may be molded with ferromagnetic shielding material 1716. For example, ferromagnetic shielding material 1716 may be included in one more support bars and/or a supporting frame embedded within a plastic mold for main body 1702, first side wing 1704, second side wing 1706, and headrest 1708. Additionally or alternatively, ferromagnetic shielding material 1716 may be added as a powder to a plastic resin used to manufacture main body 1702, first side wing 1704, second side wing 1706, and headrest 1708. Additionally or alternatively, cushion 1718 (e.g., associated with a back rest), seat bottom 1720, and/or seat base 1722 may be molded with ferromagnetic shielding material 1716. Shielding 1716 may provide more than a four time improvement in magnetic field amplitude reduction in child-holding concavity 1712 than in an absence of shielding 1716.

In some disclosed embodiments, the shielding material extends over edges of the side wings in a manner away from the child-holding concavity to thereby channel magnetic field radiation away from the child holding concavity. An edge of a side wing refers to a brim, lip, periphery, and/or rim of a side wing. Shielding material extending over an edge of a side wing refers to shielding material covering a side wing and reaching beyond the outermost rim of the side wing. When embedded in a plastic wing, extending over refers to shielding material reaching beyond the outermost rim, from embedded locations. Away from the child holding concavity refers to a direction oriented opposite to the child holding concavity. For example, the shielding material may have a larger surface area than a side wing such that a first portion of the shielding material may cover a side wing, and a second portion of the shielding material may extend past the edge of the side wing. The second portion may be bent and/or contoured to direct a magnetic field in a direction opposite from the child-holding concavity. To channel refers to direct, convey, and/or transfer.

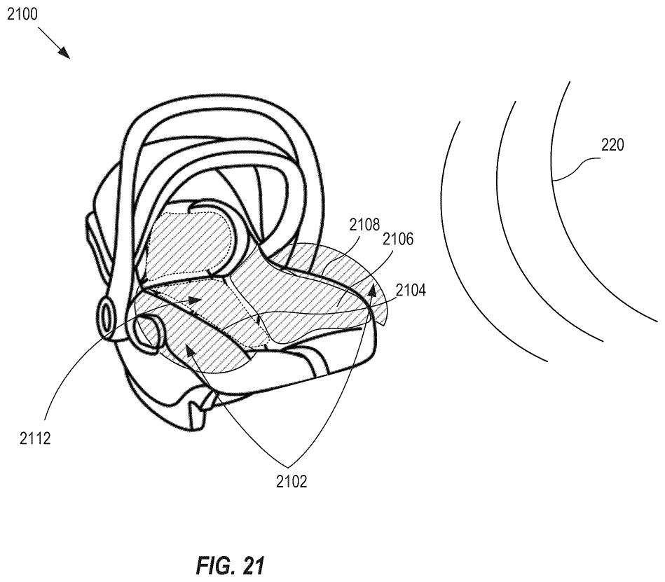

By way of a non-limiting example, reference is made to FIG. 21 illustrating another exemplary juvenile car seat 2100, consistent with some disclosed embodiments. Juvenile car seat 2100 may be substantially similar to juvenile car seat 1600 of FIG. 16 with the noted difference that shielding material 2102 may extend over edges 2108 of side wings 2104 and 2106 (corresponding to side wings 1604 and 1606) in a manner away from a child-holding concavity 2112 (corresponding to child-holding concavity 1612) to thereby channel magnetic field radiation 220 away from the child holding concavity 2110.

Some disclosed embodiments involve a juvenile car seat, comprising: a main body; a first side wing extending from a right side of the main body; a second side wing extending from a left side of the main body; wherein the main body, the first side wing, and the second side wing form a child-holding concavity, and magnetic field shielding material associated with a child-holding concavity in a manner for rerouting magnetic field radiation away from the child-holding concavity A juvenile car seat comprising a main body, a first side wing extending from a right side of the main body, a second side wing extending from a left side of the main body may refer to a juvenile car seat as describe above, lacking a back and/or head rest. For example, the juvenile car seat may be a child booster seat. The juvenile car seat may consist of a raised platform and/or side lips and/or rims configured to catch a safety belt of a vehicle and position the safety belt at a height for comfortably securing a child in a moving vehicle. A child-holding concavity of booster seat may include a shallow bucket formed by a seat bottom and raised rims at the sides (e.g., side wings), and/or back. Magnetic field shielding material associated with a child-holding concavity for a child booster seat may include plastic infused with ferromagnetic material forming a hard shell of the booster seat, a coating of paint, foil, fabric, and/or mesh on or within a hard shell portion of the booster seat, a plate and/or mat of ferromagnetic material placed under the booster seat (e.g., atop a passenger seat), and/or between a plastic shell and a booster seat cushion, and/or any other technique for associating magnetic field shielding material with a child-holding concavity of a juvenile car seat.

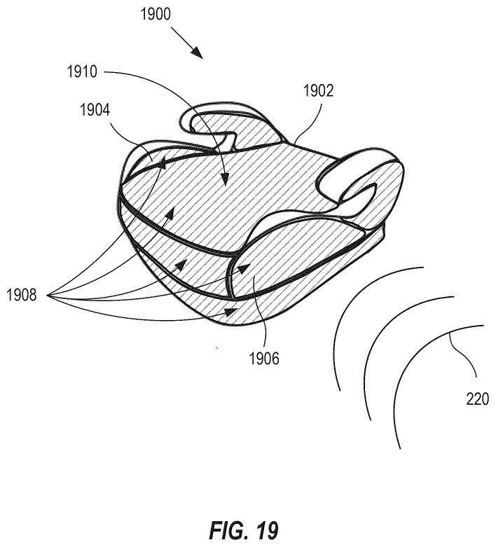

By way of another non-limiting example, reference is made to FIG. 19 illustrating another exemplary juvenile car seat 1900, consistent with some disclosed embodiments. For example, juvenile car seat 1900 may be a child booster seat. Juvenile car seat 1900 may be substantially similar to any of juvenile car seats 1600, 1700, and/or 1800 with the notable difference that juvenile car seat 1900 may lack a backrest and/or a head rest. Juvenile car seat 1900 may include a main body 1902, a first side wing 1904 extending from a right side of main body 1902, a second side wing 1906 extending from a left side of main body 1902, and magnetic field shielding material 1908 associated with a child-holding concavity 1910 in a manner for rerouting magnetic field radiation 220 away from child-holding concavity 1910. Magnetic field shielding material 1908 may include a single piece of shielding material (e.g., molded and/or shaped to conform to a shape of juvenile car seat 1900) or a plurality of pieces of shielding material.

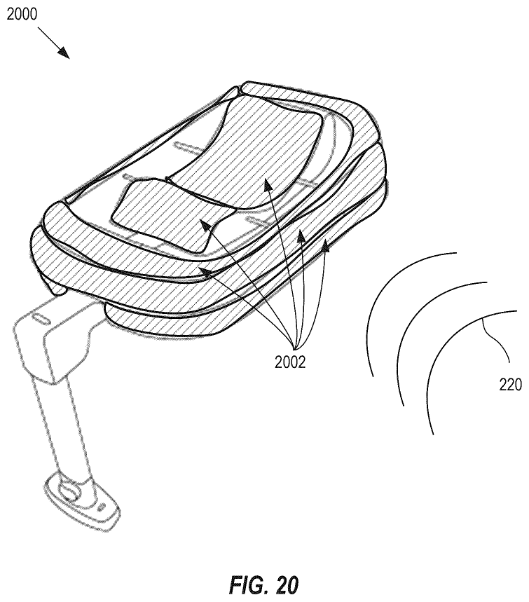

By way of another non-limiting example, reference is made to FIG. 20 which illustrates an exemplary detachable base 2000 for supporting a juvenile car seat, consistent with some disclose embodiments. Detachable base 2000 may be installed in a passenger vehicle in a manner permitting to attach and/or detach a juvenile car seat. In some embodiments, one or more of juvenile car seats 1600, 1700, and/or 1800 may be attached to detachable base 2000. Detachable base 2000 may include a ferromagnetic shield 2002 associated therewith. Ferromagnetic shield 2002 may be included in a bottom and/or top surface of detachable base 2000, and/or may be embedded in material forming detachable base 2000. For example, ferromagnetic shield 2002 may include one or more plates, panels, and/or mats on which detachable base 2000 may rest. Ferromagnetic shield 2002 may include a single piece of shielding material molded and/or shaped to conform to a shape of detachable base 2000, or multiple pieces of shielding material. Additionally or alternatively, ferromagnetic shield 2002 may include a ferromagnetic coating (e.g., ferromagnetic paint, foil, and/or mesh) on one or more portions of detachable base 2000. Additionally or alternatively, ferromagnetic shield 2002 may be made of plastic embedded with ferromagnetic material (e.g., as metal bars, mesh, and/or as ferromagnetic granules and/or powder added to plastic pellets used to manufacture one or more rigid portions of a juvenile car seat). Ferromagnetic shield 2002 may reroute magnetic field radiation 220 away from a child-holding concavity of a juvenile car seat attached to detachable base 2000.

Examples of inventive concepts are contained in the following clauses which are an integral part of this disclosure.

Clause 1. A system for protecting vehicle passengers from magnetic field radiation, the system comprising:
a passenger cabin;
a wire cable configured to carry electricity during vehicle operation thereby generating a primary magnetic field that, in an absence of cancellation, would radiate into the passenger cabin;
a current sensor associated with the wire cable, for sensing current passing through the wire cable;
a cancellation wire, running along at least a portion of the wire cable; and
an amplifier configured to receive a signal indicative of current running through the wire cable and for generating, within 1500 microseconds of the signal, a cancellation current for application to the cancellation wire, the cancellation current is within 30% of the current passing through the wire cable in order to cause a cancelling magnetic field thereby at least partially eliminating magnetic radiation from the wire cable to the passenger cabin.

Clause 2. The system of clause 1, wherein, in use, the current is continuously varying and wherein the amplifier is configured to generate a continuously varying cancellation current.

Clause 3. The system of any of clauses 1-2, wherein the current sensor includes a current clamp.

Clause 4. The system of any of clauses 1-3, wherein the current sensor is one of a Hall sensor, an inductance sensor, a field probe, or a Rogowski coil.

Clause 5. The system of any of clauses 1-4, wherein the wire cable connects an inverter to a motor.

Clause 6. The system of any of clauses 1-5, wherein the wire cable connects a rectifier to a battery.

Clause 7. The system of any of clauses 1-6, wherein a portion of the wire cable extends through a chassis of the vehicle.

Clause 8. The system of any of clauses 1-7, wherein the amplifier is set to produce a current matching the signal indicative of current running through the wire cable.

Clause 9. The system of any of clauses 1-8, wherein the cancellation wire includes a plurality of wire turns, and wherein the amplifier is set to produce a current inversely proportional to a number of the plurality of wire turns.

Clause 10. The system of any of clauses 1-9, further comprising ferromagnetic shielding material between the wire cable and the passenger cabin for attenuating the primary magnetic field radiating from the wire cable.

Clause 11. The system of any of clauses 1-10, wherein the primary magnetic field is an electromagnetic field.

Clause 12. A vehicle wiring assembly having integrated magnetic field cancellation components associated therewith, the vehicle wiring assembly comprising:
a vehicle wiring harness including a bundle of wires, at least some of the bundle of wires being aggressor wires configured such that when in use, the aggressor wires carry sufficient aggregate current to cause, in an absence of mitigation, a wiring harness-induced aggressor magnetic field of greater than a threshold level in a region of a passenger cabin of an associated vehicle;
a plurality of connectors on ends of the wires in the bundle, the plurality of connectors being configured for connecting at least some of the wires in the bundle to electrical components of the vehicle;
a current sensing probe integrated with the vehicle wiring harness, the current sensing probe being associated with the bundle of wires in a manner enabling the current sensing probe, when in use, to sense at least a portion of the aggregate current, the current sensing probe having an output wire configured for electrical connection to an electronic control unit for determining a cancellation current sufficient to mitigate causation of at least a portion of the wiring harness-induced aggressor magnetic field in the region of the passenger cabin of the vehicle; and at least one dedicated wire integrated with and running along the vehicle wiring harness, the at least one dedicated wire being configured for electrical connection to the electronic control unit via at least one of the plurality of connectors, to receive the determined cancellation current, and to thereby mitigate causation of at least the portion of the wiring harness-induced aggressor magnetic field in the region of the passenger cabin of the vehicle.

Clause 13. The vehicle wiring assembly of any of clauses 1-12, further comprising at least one additional dedicated wire for cooperating to cancel a majority of the wiring harness-induced aggressor magnetic field in the region of the passenger cabin caused by the aggressor wires.

Clause 14. The vehicle wiring assembly of any of clauses 1-13, further comprising fasteners for securing the wiring harness to a body of the vehicle at predefined locations associated with the region of the passenger cabin of the vehicle.

Clause 15. The vehicle wiring assembly of any of clauses 1-14, wherein the connectors include terminals on the ends of at least some of the wires in the bundle.

Clause 16. The vehicle wiring assembly of any of clauses 1-15, wherein the bundle of wires includes at least one of a fuse or relay integrated therein.

Clause 17. The vehicle wiring assembly of any of clauses 1-16, further comprising at least one of a wire loom or sleeve for protecting and organizing the wires within the bundle.

Clause 18. The vehicle wiring assembly of any of clauses 1-17, wherein the threshold level is associated with a reference level of a recognized guideline.

Clause 19. The vehicle wiring assembly of any of clauses 1-18, wherein the threshold level is associated with a basic restriction of a recognized guideline.

Clause 20. The vehicle wiring assembly of any of clauses 1-19, wherein the bundle of wires includes a two-wire arrangement and wherein the at least one dedicated wire forms at least one loop along positive and negative leads of the vehicle wiring harness.

Clause 21. The vehicle wiring assembly of any of clauses 1-20, wherein the bundle of wires includes a three-phase electrical wiring including a first wire, a second wire, and a third wire, and wherein the at least one dedicated wire includes a first dedicated wire forming a first cancellation loop and a second dedicated wire forming a second cancellation loop, wherein the first cancellation loop includes a first non-overlapping section along at least a portion of the first wire, wherein the second cancellation loop includes a second non-overlapping section along at least a portion of the third wire, and wherein the first cancellation loop and the second cancellation loop partially overlap along at least a portion of the second wire.

Clause 22. The vehicle wiring assembly of any of clauses 1-21, wherein at least one of the first cancellation loop or the second cancellation loop includes a plurality of wire turns.

Clause 23. The vehicle wiring assembly of any of clauses 1-22, wherein at least one wire in the bundle of wires forms a plurality of wire turns through the current sensing probe.

Clause 24. The vehicle wiring assembly of any of clauses 1-23, wherein the at least one dedicated wire forms a plurality of wire turns through the current sensing probe.

Clause 25. The vehicle wiring assembly of any of clauses 1-25, further comprising a magnetic field sensor integrated with the vehicle wiring harness.

Clause 26. The vehicle wiring assembly of any of clauses 1-26, further comprising a temperature sensor integrated with the vehicle wiring harness.

Clause 27. The vehicle wiring assembly of any of clauses 1-27, wherein the threshold level is 1 mG.

Clause 28. A system for powering a cancelling field in a passenger cabin of a vehicle, the system comprising:
an AC aggressor loop configured to generate an aggressor magnetic field in the passenger cabin of the vehicle;
an AC cancellation loop configured to generate a cancellation magnetic field at least partially cancelling the aggressor magnetic field; and
an amplifier for supplying alternating current to power the AC cancellation loop, wherein the amplifier is electrically isolated from an electrical ground associated with the vehicle, to thereby reduce generation of non-cancelling magnetic field radiation.

Clause 29. The system of any of clauses 1-28, wherein the electrically isolated amplifier is electrically isolated from a vehicle chassis.

Clause 30. The system of any of clauses 1-30, wherein the electrically isolated amplifier is associated with a floating ground.

Clause 31. The system of any of clauses 1-31, wherein electrically isolating the amplifier is configured to reduce parasitic current leakage.

Clause 32. The system of any of clauses 1-32, wherein electrically isolating the amplifier prevents formation of a ground loop configured to generate non-cancelling magnetic field radiation.

Clause 33. The system of any of clauses 1-33, further comprising ferromagnetic shielding material between the AC aggressor loop and the passenger cabin for attenuating the aggressor magnetic field generated by the AC aggressor loop.

Clause 34. The system of any of clauses 1-34, wherein the aggressor magnetic field is an electromagnetic field.

Clause 35. The system of any of clauses 1-35, further comprising a control unit for regulating the amplifier.

Clause 36. The system of clauses 1-35, wherein at least partially cancelling the aggressor magnetic field includes mitigating an above threshold level of aggressor magnetic field in the passenger cabin.

Clause 37. The system of clauses 1-36, wherein a portion of the AC aggressor loop include a vehicle chassis.

Clause 38. The system of claim 36, wherein the threshold level is set to conform to a safety guideline for radiation exposure.

Clause 39. A system for powering a cancelling field in a passenger cabin of a vehicle, the system comprising:
an AC aggressor loop configured to generate an aggressor magnetic field in the passenger cabin of the vehicle;
an AC cancellation loop configured to generate a cancellation magnetic field at least partially cancelling the aggressor magnetic field;
an isolation transformer including a first coil, a second coil, and a dielectric barrier electrically isolating the second coil from the first coil; and
an amplifier configured for electrical connection to an electrical ground associated with the vehicle and to the first coil of the isolation transformer and to supply a first AC current to the first coil, and wherein the electrically isolated second coil is configured to conduct a second AC current induced from the first AC current via the isolation transformer and supply the second AC current to power the AC cancellation loop, wherein the amplifier is electrically isolated from the electrical ground associated with the vehicle to reduce generation of non-cancelling magnetic field radiation.

Clause 40. The system of any of clauses 1-39, wherein the electrical ground associated with the vehicle includes a vehicle chassis.

Clause 41. The system of any of clauses 1-40, wherein a portion of the AC aggressor loop include a vehicle chassis.

Clause 42. The system of any of clauses 1-41, wherein the AC cancellation loop includes a plurality of wire turns.

Clause 43. The system of any of clauses 1-42, wherein the AC aggressor loop includes a plurality of wire turns.

Clause 44. The system of any of clauses 1-43, further comprising a control unit for regulating the amplifier.

Clause 45. A juvenile car seat, comprising:
a main body;
a first side wing extending from a right side of the main body;
a second side wing extending from a left side of the main body;
a headrest area extending from a top portion of the main body between upper portions of the first side wing and the second side wing, wherein the main body, the first side wing, the second side wing, and the headrest area form a child-holding concavity; and
magnetic field shielding material associated with the child-holding concavity in a manner for rerouting magnetic field radiation away from the child-holding concavity.

Clause 46. The juvenile car seat of any of clauses 1-45, wherein the shielding material is a ferro magnetic foil.

Clause 47. The juvenile car seat of any of clauses 1-46, wherein the ferro magnetic foil is at least 18 microns thick.

Clause 48. The juvenile car seat of any of clauses 1-47, wherein the ferro magnetic foil includes at least two layers.

Clause 49. The juvenile car seat of any of clauses 1-48, wherein the shielding material is flexible.

Clause 50. The juvenile car seat of any of clauses 1-49, wherein the juvenile seat further includes a cushion thereon, and wherein the foil is under the cushion.

Clause 51. The juvenile car seat of any of clauses 1-50, wherein the main body, the first side wing, the second side wing and the headrest are molded with the shielding material therein.

Clause 52. The juvenile car seat of any of clauses 1-51, wherein the main body, the first side wing, the second side wing and the headrest are molded of plastic with the shielding material embedded therein.

Clause 53. The juvenile car seat of any of clauses 1-52, wherein the shielding is configured to provide more than a 4× improvement in magnetic field amplitude reduction in the child holding concavity than in an absence of the shielding.

Clause 54. The juvenile car seat of any of clauses 1-53, wherein the shielding material extends over edges of the side wings in a manner away from the child-holding concavity to thereby channel magnetic field radiation away from the child holding concavity.

Clause 55. The juvenile car seat of any of clauses 1-54, wherein the magnetic field radiation is electromagnetic field radiation.

Clause 56. The juvenile car seat of any of clauses 1-55, wherein the magnetic shielding material includes at least one of Mu-Metal, Permalloy, soft iron, silicon steel, silicon steel GO (Grain Oriented), silicon steel NGO (Non Grain Oriented), electrical steel, transformer steel, ferrites, and/or Metglas.

Clause 57. A juvenile car seat, comprising:
a main body;
a first side wing extending from a right side of the main body;
a second side wing extending from a left side of the main body wherein the main body, the first side wing, and the second side wing form a child-holding concavity; and
magnetic field shielding material associated with the child-holding concavity in a manner for rerouting magnetic field radiation away from the child-holding concavity.

Disclosed embodiments may include any one of the following bullet-pointed features alone or in combination with one or more other bullet-pointed features, whether implemented as a system and/or method, by one or more hardware components disclosed herein, as well as by at least one processor or circuitry, and/or stored as executable instructions on non-transitory computer readable media or computer readable media.
protecting vehicle passengers from magnetic field radiation.
a passenger cabin.
a wire cable configured to carry electricity during vehicle operation.
generating a primary magnetic field that, in an absence of cancellation, would radiate into the passenger cabin.
a current sensor associated with a wire cable, for sensing current passing through the wire cable.
a cancellation wire, running along at least a portion of a wire cable.
an amplifier configured to receive a signal indicative of current running through a wire cable.
generating, within 1500 microseconds of a signal, a cancellation current for application to a cancellation wire.
a cancellation current is within 30% of the current passing through a wire cable in order to cause a cancelling magnetic field thereby at least partially eliminating magnetic radiation from the wire cable to the passenger cabin.
in use, a current is continuously varying.
an amplifier is configured to generate a continuously varying cancellation current.
a current sensor includes a current clamp.
a current sensor is one of a Hall sensor, an inductance sensor, a field probe, or a Rogowski coil.
a wire cable connects an inverter to a motor.
a wire cable connects a rectifier to a battery.
a portion of a wire cable extends through a chassis of a vehicle.
an amplifier is set to produce a current matching a signal indicative of current running through a wire cable.
a cancellation wire includes a plurality of wire turns.
an amplifier is set to produce a current inversely proportional to a number of a plurality of wire turns.
ferromagnetic shielding material between a wire cable and a passenger cabin for attenuating a primary magnetic field radiating from a wire cable.
a primary magnetic field is an electromagnetic field.
a vehicle wiring assembly having integrated magnetic field cancellation components associated therewith.
a vehicle wiring harness including a bundle of wires.
at least some of a bundle of wires being aggressor wires configured such that when in use, the aggressor wires carry sufficient aggregate current to cause, in an absence of mitigation, a wiring harness-induced aggressor magnetic field of greater than a threshold level in a region of a passenger cabin of an associated vehicle.
a plurality of connectors on ends of wires in a bundle.
a plurality of connectors being configured for connecting at least some wires in a bundle to electrical components of a vehicle.
a current sensing probe integrated with the vehicle wiring harness.
a current sensing probe being associated with a bundle of wires in a manner enabling the current sensing probe, when in use, to sense at least a portion of an aggregate current.
a current sensing probe having an output wire configured for electrical connection to an electronic control unit for determining a cancellation current sufficient to mitigate causation of at least a portion of a wiring harness-induced aggressor magnetic field in a region of the passenger cabin of a vehicle.
at least one dedicated wire integrated with and running along a vehicle wiring harness.
at least one dedicated wire being configured for electrical connection to an electronic control unit via at least one of a plurality of connectors, to receive a determined cancellation current, and to thereby mitigate causation of at least a portion of a wiring harness-induced aggressor magnetic field in a region of a passenger cabin of the vehicle.
at least one additional dedicated wire for cooperating to cancel a majority of a wiring harness-induced aggressor magnetic field in a region of a passenger cabin caused by aggressor wires.
fasteners for securing a wiring harness to a body of a vehicle at predefined locations associated with a region of a passenger cabin of the vehicle.
connectors including terminals on ends of at least some of wires in a bundle.
a bundle of wires includes at least one of a fuse or relay integrated therein.
at least one of a wire loom or sleeve for protecting and organizing wires within a bundle.
a threshold level is associated with a reference level of a recognized guideline.
a threshold level is associated with a basic restriction of a recognized guideline.
a bundle of wires includes a two-wire arrangement.
at least one dedicated wire forms at least one loop along positive and negative leads of a vehicle wiring harness.
a bundle of wires includes a three-phase electrical wiring including a first wire, a second wire, and a third wire.
at least one dedicated wire includes a first dedicated wire forming a first cancellation loop and a second dedicated wire forming a second cancellation loop.
a first cancellation loop includes a first non-overlapping section along at least a portion of the first wire.
a second cancellation loop includes a second non-overlapping section along at least a portion of a third wire.
a first cancellation loop and a second cancellation loop partially overlap along at least a portion of a second wire.
at least one of a first cancellation loop or a second cancellation loop includes a plurality of wire turns.
at least one wire in a bundle of wires forms a plurality of wire turns through a current sensing probe.
at least one dedicated wire forms a plurality of wire turns through a current sensing probe.
a magnetic field sensor integrated with a vehicle wiring harness.
a temperature sensor integrated with a vehicle wiring harness.
a threshold level of 1 mG.
a system for powering a cancelling field in a passenger cabin of a vehicle.
an AC aggressor loop configured to generate an aggressor magnetic field in a passenger cabin of a vehicle.
an AC cancellation loop configured to generate a cancellation magnetic field at least partially cancelling an aggressor magnetic field.
an amplifier for supplying alternating current to power an AC cancellation loop.
an amplifier is electrically isolated from an electrical ground associated with a vehicle, to thereby reduce generation of non-cancelling magnetic field radiation.
an electrically isolated amplifier is electrically isolated from a vehicle chassis.
an electrically isolated amplifier is associated with a floating ground.
electrically isolating an amplifier is configured to reduce parasitic current leakage.
electrically isolating an amplifier prevents formation of a ground loop configured to generate non-cancelling magnetic field radiation.
ferromagnetic shielding material between an AC aggressor loop and a passenger cabin.
attenuating the aggressor magnetic field generated by an AC aggressor loop.
an aggressor magnetic field is an electromagnetic field.
a control unit for regulating an amplifier.
at least partially cancelling an aggressor magnetic field includes mitigating an above threshold level of aggressor magnetic field in a passenger cabin.
a portion of the AC aggressor loop include a vehicle chassis.
a threshold level is set to conform to a safety guideline for radiation exposure.
an isolation transformer including a first coil, a second coil, and a dielectric barrier electrically isolating the second coil from the first coil.
an amplifier configured for electrical connection to an electrical ground associated with a vehicle and to a first coil of an isolation transformer and to supply a first AC current to the first coil.
an electrically isolated second coil is configured to conduct a second AC current induced from a first AC current via an isolation transformer and supply the second AC current to power an AC cancellation loop.
an amplifier is electrically isolated from an electrical ground associated with a vehicle to reduce generation of non-cancelling magnetic field radiation.
an electrical ground associated with a vehicle includes a vehicle chassis.
a portion of an AC aggressor loop include a vehicle chassis.
an AC cancellation loop includes a plurality of wire turns.
an AC aggressor loop includes a plurality of wire turns.
a juvenile car seat.
a main body.
a first side wing extending from a right side of the main body.
a second side wing extending from a left side of the main body.
a headrest area extending from a top portion of a main body between upper portions of a first side wing and a second side wing.
a main body, a first side wing, a second side wing, and a headrest area form a child-holding concavity.
magnetic field shielding material associated with a child-holding concavity in a manner for rerouting magnetic field radiation away from the child-holding concavity.
shielding material is a ferro magnetic foil.
ferro magnetic foil is at least 18 microns thick.
ferro magnetic foil includes at least two layers.
shielding material is flexible.
a juvenile seat further includes a cushion thereon, and wherein foil is under the cushion.
a main body, a first side wing, a second side wing and a headrest are molded with the shielding material therein.
a main body, a first side wing, a second side wing and a headrest are molded of plastic with shielding material embedded therein.
shielding is configured to provide more than a 4× improvement in magnetic field amplitude reduction in a child holding concavity than in an absence of the shielding.
shielding material extends over edges of side wings in a manner away from a child-holding concavity to thereby channel magnetic field radiation away from the child holding concavity.
magnetic field radiation is electromagnetic field radiation . . . magnetic shielding material includes at least one of Mu-Metal, Permalloy, soft iron, silicon steel, silicon steel GO (Grain Oriented), silicon steel NGO (Non Grain Oriented), electrical steel, transformer steel, ferrites, and/or Metglas.

The embodiments disclosed herein are exemplary and any other means for performing and facilitating display navigation operations may be consistent with this disclosure.

The foregoing description has been presented for purposes of illustration. It is not exhaustive and is not limited to the precise forms or embodiments disclosed. Modifications and adaptations will be apparent to those skilled in the art from consideration of the specification and practice of the disclosed embodiments.

Moreover, while illustrative embodiments have been described herein, the scope of any and all embodiments having equivalent elements, modifications, omissions, combinations (e.g., of aspects across various embodiments), adaptations and/or alterations as would be appreciated by those skilled in the art based on the present disclosure. The limitations in the claims are to be interpreted broadly based on the language employed in the claims and not limited to examples described in the present specification or during the prosecution of the application. The examples are to be construed as non-exclusive. Furthermore, the steps of the disclosed methods may be modified in any manner, including by reordering steps and/or inserting or deleting steps. It is intended, therefore, that the specification and examples be considered as illustrative only, with a true scope and spirit being indicated by the following claims and their full scope of equivalents.

Unless otherwise defined, all technical and scientific terms used herein have the same meaning as commonly understood by one of ordinary skill in the art. The materials, methods, and examples provided herein are illustrative only and not intended to be limiting.

Implementation of the method and system of the present disclosure may involve performing or completing certain selected tasks or steps manually, automatically, or a combination thereof. Moreover, according to actual instrumentation and equipment of preferred embodiments of the method and system of the present disclosure, several selected steps may be implemented by hardware (HW) or by software (SW) on any operating system of any firmware, or by a combination thereof. For example, as hardware, selected steps of the disclosure could be implemented as a chip or a circuit. As software or algorithm, selected steps of the disclosure could be implemented as a plurality of software instructions being executed by a computer using any suitable operating system. In any case, selected steps of the method and system of the disclosure could be described as being performed by a data processor, such as a computing device for executing a plurality of instructions.

As used herein, the terms “machine-readable medium” and “computer-readable medium” refers to any computer program product, apparatus and/or device (e.g., magnetic discs, optical disks, memory, Programmable Logic Devices (PLDs)) used to provide machine instructions and/or data to a programmable processor, including a machine-readable medium that receives machine instructions as a machine-readable signal. The term “machine-readable signal” refers to any signal used to provide machine instructions and/or data to a programmable processor.

Various implementations of the systems and techniques described here can be realized in digital electronic circuitry, integrated circuitry, specially designed ASICs (application-specific integrated circuits), computer hardware, firmware, software, and/or combinations thereof. These various implementations can include implementation in one or more computer programs that are executable and/or interpretable on a programmable system including at least one programmable processor, which may be special or general purpose, coupled to receive data and instructions from and to transmit data and instructions to, a storage system, at least one input device, and at least one output device.

Although the present disclosure is described with regard to a “computing device”, a “computer”, or a “mobile device”, it should be noted that optionally any device featuring a data processor and the ability to execute one or more instructions may be described as a computing device, including but not limited to any type of personal computer (PC), a server, a distributed server, a virtual server, a cloud computing platform, a cellular telephone, an IP telephone, a smartphone, a smartwatch or a PDA (personal digital assistant). Any two or more of such devices in communication with each other may optionally include a “network” or a “computer network”.

To provide for interaction with a user, the systems and techniques described here can be implemented on a computer having a display device (a LED (light-emitting diode), OLED (organic LED), or LCD (liquid crystal display) monitor/screen) for displaying information to the user and a touch-sensitive layer such as a touchscreen, or keyboard and a pointing device (e.g., a mouse or a trackball), by which the user can provide input to the computer. Other kinds of devices can be used to provide for interaction with a user as well; for example, feedback provided to the user can be any form of sensory feedback (e.g., visual feedback, auditory feedback, or tactile feedback); and input from the user can be received in any form, including acoustic, speech, or tactile input.

The systems and techniques described here can be implemented in a computing system that includes a back-end component (e.g., as a data server), or that includes a middleware component (e.g., an application server), or that includes a front-end component (e.g., a client computer having a graphical user interface or a Web browser through which a user can interact with an implementation of the systems and techniques described here), or any combination of such back end, middleware, or front end components. The components of the system can be interconnected by any form or medium of digital data communication (e.g., a communication network). Examples of communication networks include a local area network (“LAN”), a wide area network (“WAN”), and the Internet.

The computing system can include clients and servers. A client and server are generally remote from each other and typically interact through a communication network. The relationship of client and server arises by virtue of computer programs running on the respective computers and having a client-server relationship to each other.

It should be appreciated that the above-described methods and apparatus may be varied in many ways, including omitting or adding steps, changing the order of steps and the type of devices used. It should be appreciated that different features may be combined in different ways. In particular, not all the features shown above in a particular embodiment or implementation are necessary in every embodiment or implementation of the invention. Further combinations of the above features and implementations are also considered to be within the scope of some embodiments or implementations of the invention.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

Systems and methods disclosed herein involve unconventional improvements over conventional approaches. Descriptions of the disclosed embodiments are not exhaustive and are not limited to the precise forms or embodiments disclosed. Modifications and adaptations of the embodiments will be apparent from consideration of the specification and practice of the disclosed embodiments. Additionally, the disclosed embodiments are not limited to the examples discussed herein.

The foregoing description has been presented for purposes of illustration. It is not exhaustive and is not limited to the precise forms or embodiments disclosed. Modifications and adaptations of the embodiments will be apparent from consideration of the specification and practice of the disclosed embodiments. For example, the described implementations include hardware and software, but systems and methods consistent with the present disclosure may be implemented as hardware alone.

It is appreciated that the above-described embodiments can be implemented by hardware, software (program codes), or a combination of hardware and software. If implemented by software, it can be stored in the above-described computer-readable media. The software, when executed by the processor can perform the disclosed methods. The computing units and other functional units described in the present disclosure can be implemented by hardware, software, or a combination of hardware and software. One of ordinary skill in the art will also understand that multiple ones of the above-described modules/units can be combined as one module or unit, and each of the above-described modules/units can be further divided into a plurality of sub-modules or sub-units.

The block diagrams in the figures illustrate the architecture, functionality, and operation of possible implementations of systems, methods, and computer hardware or software products according to various example embodiments of the present disclosure. In this regard, each block in a flowchart or block diagram may represent a module, segment, or portion of code, which includes one or more executable instructions for implementing the specified logical functions. It should be understood that in some alternative implementations, functions indicated in a block may occur out of order noted in the figures. For example, two blocks shown in succession may be executed or implemented substantially concurrently, or two blocks may sometimes be executed in reverse order, depending upon the functionality involved. Some blocks may also be omitted. It should also be understood that each block of the block diagrams, and combination of the blocks, may be implemented by special purpose hardware-based systems that perform the specified functions or acts, or by combinations of special purpose hardware and computer instructions.

In the foregoing specification, embodiments have been described with reference to numerous specific details that can vary from implementation to implementation. Certain adaptations and modifications of the described embodiments can be made. Other embodiments can be apparent to those skilled in the art from consideration of the specification and practice of the invention disclosed herein. It is intended that the specification and examples be considered as examples only, with a true scope and spirit of the invention being indicated by the following claims. It is also intended that the sequence of steps shown in figures are only for illustrative purposes and are not intended to be limited to any particular sequence of steps. As such, those skilled in the art can appreciate that these steps can be performed in a different order while implementing the same method.

It will be appreciated that the embodiments of the present disclosure are not limited to the exact construction that has been described above and illustrated in the accompanying drawings, and that various modifications and changes may be made without departing from the scope thereof.

Other embodiments will be apparent to those skilled in the art from consideration of the specification and practice of the disclosed embodiments disclosed herein. It is intended that the specification and examples be considered as exemplary only, with a true scope and spirit of the disclosed embodiments being indicated by the following claims.

Computer programs based on the written description and methods of this specification are within the skill of a software developer. The various programs or program modules can be created using a variety of programming techniques. One or more of such software sections or modules can be integrated into a computer system, non-transitory computer readable media, or existing software.

This disclosure employs open-ended permissive language, indicating for example, that some embodiments “may” employ, involve, or include specific features. The use of the term “may” and other open-ended terminology is intended to indicate that although not every embodiment may employ the specific disclosed feature, at least one embodiment employs the specific disclosed feature.

Various terms used in the specification and claims may be defined or summarized differently when discussed in connection with differing disclosed embodiments. It is to be understood that the definitions, summaries and explanations of terminology in each instance apply to all instances, even when not repeated, unless the transitive definition, explanation or summary would result in inoperability of an embodiment.

Moreover, while illustrative embodiments have been described herein, the scope includes any and all embodiments having equivalent elements, modifications, omissions, combinations (e.g., of aspects across various embodiments), adaptations or alterations based on the present disclosure. The elements in the claims are to be interpreted broadly based on the language employed in the claims and not limited to examples described in the present specification or during the prosecution of the application. These examples are to be construed as non-exclusive. Further, the steps of the disclosed methods can be modified in any manner, including by reordering steps or inserting or deleting steps. It is intended, therefore, that the specification and examples be considered as exemplary only, with a true scope and spirit being indicated by the following claims and their full scope of equivalents.

1-11. (canceled)

12. A vehicle wiring assembly having integrated magnetic field cancellation components associated therewith, the vehicle wiring assembly comprising:
a vehicle wiring harness including a bundle of wires, at least some of the bundle of wires being aggressor wires configured such that when in use, the aggressor wires carry sufficient aggregate current to cause, in an absence of mitigation, a wiring harness-induced aggressor magnetic field of greater than a threshold level in a region of a passenger cabin of an associated vehicle;
a plurality of connectors on ends of the wires in the bundle, the plurality of connectors being configured for connecting at least some of the wires in the bundle to electrical components of the vehicle;
a current sensing probe integrated with the vehicle wiring harness, the current sensing probe being associated with the bundle of wires in a manner enabling the current sensing probe, when in use, to sense at least a portion of the aggregate current, the current sensing probe having an output wire configured for electrical connection to an electronic control unit for determining a cancellation current sufficient to mitigate causation of at least a portion of the wiring harness-induced aggressor magnetic field in the region of the passenger cabin of the vehicle; and
at least one dedicated wire integrated with and running along the vehicle wiring harness, the at least one dedicated wire being configured for electrical connection to the electronic control unit via at least one of the plurality of connectors, to receive the determined cancellation current, and to thereby mitigate causation of at least the portion of the wiring harness-induced aggressor magnetic field in the region of the passenger cabin of the vehicle.

13. The vehicle wiring assembly of claim 12, further comprising at least one additional dedicated wire for cooperating to cancel a majority of the wiring harness-induced aggressor magnetic field in the region of the passenger cabin caused by the aggressor wires.

14. The vehicle wiring assembly of claim 12, further comprising fasteners for securing the wiring harness to a body of the vehicle at predefined locations associated with the region of the passenger cabin of the vehicle.

15. The vehicle wiring assembly of claim 12, wherein the connectors include terminals on the ends of at least some of the wires in the bundle.

16. The vehicle wiring assembly of claim 12, wherein the bundle of wires includes at least one of a fuse or relay integrated therein.

17. The vehicle wiring assembly of claim 12, further comprising at least one of a wire loom or sleeve for protecting and organizing the wires within the bundle.

18. The vehicle wiring assembly of claim 12, wherein the threshold level is associated with a reference level of a recognized guideline.

19. The vehicle wiring assembly of claim 12, wherein the threshold level is associated with a basic restriction of a recognized guideline.

20. The vehicle wiring assembly of claim 12, wherein the bundle of wires includes a two-wire arrangement and wherein the at least one dedicated wire forms at least one loop along positive and negative leads of the vehicle wiring harness.

21. The vehicle wiring assembly of claim 12, wherein the bundle of wires includes a three-phase electrical wiring including a first wire, a second wire, and a third wire, and wherein the at least one dedicated wire includes a first dedicated wire forming a first cancellation loop and a second dedicated wire forming a second cancellation loop, wherein the first cancellation loop includes a first non-overlapping section along at least a portion of the first wire, wherein the second cancellation loop includes a second non-overlapping section along at least a portion of the third wire, and wherein the first cancellation loop and the second cancellation loop partially overlap along at least a portion of the second wire.

22. The vehicle wiring assembly of claim 21, wherein at least one of the first cancellation loop or the second cancellation loop includes a plurality of wire turns.

23. The vehicle wiring assembly of claim 12, wherein at least one wire in the bundle of wires forms a plurality of wire turns through the current sensing probe.

24. The vehicle wiring assembly of claim 12, wherein the at least one dedicated wire forms a plurality of wire turns through the current sensing probe.

25. The vehicle wiring assembly of claim 12, further comprising a magnetic field sensor integrated with the vehicle wiring harness.

26. The vehicle wiring assembly of claim 12, further comprising a temperature sensor integrated with the vehicle wiring harness.

27. The vehicle wiring assembly of claim 12, wherein the threshold level is 1 mG.

28-57. (canceled)
